(19) United States
(12) Patent Application Publication
(10) Pub. No.: US 2007/0128814 A1
(43) Pub. Date: Jun. 7, 2007

(54) SEMICONDUCTOR DEVICE

(75) Inventor: Koichi FUKUDA, Tokyo (JP)

Correspondence Address: GLOBAL IP COUNSELORS, LLP, 1233 20TH STREET, NW, SUITE 700, WASHINGTON, DC, 20036-2680, US

(73) Assignee: OKI ELECTRIC INDUSTRY CO., LTD., Tokyo (JP)

(21) Appl. No.: 11/550,416

(22) Filed: Oct. 18, 2006

(30) Foreign Application Priority Data
Dec. 7, 2005 (JP) 2005-353124

(51) Int. Cl. H01L 29/76; H01L 21/336

(52) U.S. Cl. 438/297; 257/288

(57) ABSTRACT

A semiconductor device of the present invention includes a source region, a drain region, a gate having a first sidewall, a first insulating sidewall structure disposed to contact the first sidewall of the gate, and a first conductive sidewall structure that is electrically isolated from the gate through the first insulating sidewall structure and electrically coupled to a first region that is one of the source region or the drain region. According to this semiconductor device, the first conductive sidewall structure has an electric potential that is substantially the same as that of the first region. Therefore, steep band bending is not generated in a portion of the first region that is disposed in the vicinity of a gate insulation film. Because of this, the first sidewall structure makes it possible to inhibit the band-to-band tunneling current.

This application claims priority to Japanese Patent Application No. 2005-353124. This entire disclosure of Japanese Patent Application No. 2005-353124 is hereby incorporated herein by reference.

### BACKGROUND OF THE INVENTION

### Field of the Invention

The present invention relates to a semiconductor device, and in particular, relates to a field effect transistor (FET) that includes an effective structure for inhibiting off-leak current due to band-to-band tunneling current.

A FET represented as metal insulator semiconductor field effect transistor (MISFET) and a metal oxide semiconductor field effect transistor (MOSFET) is integrated on a semiconductor integrated circuit (semiconductor IC) such as a large-scale integration circuit (LSI circuit). Miniaturization of the FET is required for realizing improvements of the integration degree and the operation speed of the semiconductor IC, and the reduction of the power consumption thereof. With miniaturization of the FET, the thickness of a gate insulation film thereof is formed to be thin, and at the same time as this, the contact depth of source/drain thereof is formed to be shallow.

For example, Japan Patent Application Publication JP-A-06-196689 (especially, paragraphs 0011 to 0013 and FIG. 1) discloses a FET comprising a main gate that is comprised of a metal or a metal silicide and auxiliary gates that are electrically coupled to the main gate and comprised of polysilicon. The main gate and the auxiliary gates are separated from each other through an oxide tungsten film. A gate electrode is formed to be disposed on the auxiliary gates, and the main gate and the auxiliary gates are electrically coupled to the gate electrode. Accordingly, the main gate and the auxiliary gates are electrically coupled to each other. The main gate and the auxiliary gates are electrically isolated from a source and a drain through a gate insulation film and an oxide silicon film. Furthermore, the impurity concentration of a channel region immediately below the auxiliary gates is set to be higher than that of a channel region immediately below the main gate. With this configuration, it is possible to optimally design the impurity concentration of the channel region immediately below the main gate with low resistance so that the transistor can have a high driving force without considering the threshold of the transistor. At the same time as this, it is possible to set a low threshold voltage to the transistor due to the auxiliary gates that are electrically coupled to the main gate. Because of this, it is possible to set the impurity concentration of the channel region immediately below the auxiliary gates to be high, and thus it is possible to reduce the extension of a depletion layer that covers the source and drain regions.

However, reduction of the thickness of the gate insulation film and reduction of the contact depth of the source/drain, both of which are caused by miniaturization of the FET, generate a strong electric field between the gate and the drain. As a result, off leak current increases due to the band-to-band tunneling current. This phenomenon is hereinafter explained in detail. If the strong electric field is generated between the gate and the drain, the tunneling current is generated between the substrate and the drain. The tunneling current is the inter-band tunnel in which the electrons in the valence band go through the conductive band and pairs of electrons and holes are produced. The tunneling current corresponds to the leak current in an off-state of the FET. The leak current increases standby power consumption of the semiconductor IC.

The above described band-to-band tunneling current must be inhibited in order to inhibit the standby consumption current. For the purpose of inhibiting the band-to-band tunneling current, it is suggested that the FET is configured to comprise a source/drain extension whose impurity concentration is lower than that of the source/drain. However, if the impurity concentration of the source/drain extension is decreased, the parasitic resistance between the source and the drain is increased. Furthermore, an increase of the parasitic resistance reduces the driving current and the operation speed of the FET.

It is therefore an object of the present invention to provide a semiconductor device that reduces the leak current without increasing the parasitic resistance between the source and the drain.

### SUMMARY OF THE INVENTION

It is the main aspect of the present invention to provide a semiconductor device that comprises a source region, a drain region, a gate having a first sidewall, a first insulating sidewall structure disposed to contact the first sidewall of the gate, and a first conductive sidewall structure that is electrically isolated from the gate through the first insulating sidewall structure and electrically coupled to a first region that is one of the source region or the drain region.

According to the main aspect of the present invention, the first conductive sidewall structure is electrically isolated from the gate through the first insulating sidewall structure, and electrically coupled to the first region (i.e., one of the source region or the drain region). Therefore, the first conductive sidewall structure has an electric potential that is substantially the same as that of the first region. Therefore, not only an electric field that runs from one of the source region or the drain region to the gate structure through a gate insulation film will be produced, but an electric field that runs from the first conductive sidewall structure to the gate structure through the first insulating sidewall structure will also be produced. In other words, an electric field that runs from the first conductive sidewall structure to the gate structure through the first insulating sidewall structure will be produced, and accordingly the concentration of the electric field that runs from the first region to the gate structure through the gate insulation film will be reduced. In other words, the concentration of the electric field between the gate and the drain or that of the electric field between the gate and the source will be reduced by the existence of the first sidewall structure that includes the first conductive sidewall structure. The band-to-band tunneling current is generated due to the steep band bending that is produced in a portion of the first region that is disposed in the vicinity of the gate insulation film by the concentration of the electric field between the gate and the drain or that of the electric field between the gate and the source. However, the above described first sidewall structure includes the first conductive sidewall structure whose electric potential is substantially the same as that of the first region. Therefore, the above described steep band bending will not be caused. Because of this, the above described first sidewall structure makes it possible to inhibit the band-to-band tunneling current.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a partial vertical cross-sectional view of a transistor configuration in accordance with a first embodiment of the present invention;

FIG. 2 is a partial vertical cross-sectional view showing the electric field in the vicinity of a gate of the transistor shown in FIG. 1;

FIGS. 3A to 3D are partial vertical cross-sectional views showing a step of a manufacturing process of the transistor in accordance with the first embodiment of the present invention;

FIGS. 4A to 4D are partial vertical cross-sectional views showing a step of a manufacturing process of the transistor in accordance with the first embodiment of the present invention;

FIGS. 5A to 5D are partial vertical cross-sectional views showing a step of a manufacturing process of the transistor in accordance with the first embodiment of the present invention;

FIGS. 6A to 6D are partial vertical cross-sectional views showing a step of a manufacturing process of the transistor in accordance with the first embodiment of the present invention;

FIGS. 7A to 7D are partial vertical cross-sectional views showing a step of a manufacturing process of the transistor in accordance with the first embodiment of the present invention;

FIGS. 8A and 8B are partial vertical cross-sectional views showing a step of a manufacturing process of the transistor in accordance with the first embodiment of the present invention;

FIG. 9 is a partial vertical cross-sectional view showing a transistor configuration in accordance with a first alternative to the first embodiment of the present invention;

FIG. 10 is a partial vertical cross-sectional view showing a transistor configuration in accordance with a second alternative to the first embodiment of the present invention;

FIG. 11 is a partial vertical cross-sectional view showing a transistor configuration in accordance with a third alternative to the first embodiment of the present invention;

FIG. 12 is a partial vertical cross-sectional view showing a transistor configuration in accordance with a fourth alternative to the first embodiment of the present invention;

FIG. 13 is a partial vertical cross-sectional view of a transistor configuration in accordance with a second embodiment of the present invention;

FIG. 14 is a partial vertical cross-sectional view showing the electric field in the vicinity of a gate of the transistor shown in FIG. 13;

FIGS. 15A to 15D are partial vertical cross-sectional views showing a step of a manufacturing process of the transistor in accordance with the second embodiment of the present invention;

FIGS. 16A to 16D are partial vertical cross-sectional views showing a step of a manufacturing process of the transistor in accordance with the second embodiment of the present invention;

FIGS. 17A to 17D are partial vertical cross-sectional views showing a step of a manufacturing process of the transistor in accordance with the second embodiment of the present invention;

FIGS. 18A to 18D are partial vertical cross-sectional views showing a step of a manufacturing process of the transistor in accordance with the second embodiment of the present invention;

FIGS. 19A to 19D are partial vertical cross-sectional views showing a step of a manufacturing process of the transistor in accordance with the second embodiment of the present invention;

FIG. 20 is a partial vertical cross-sectional view of a transistor configuration in accordance with a third embodiment of the present invention;

FIG. 21 is a partial vertical cross-sectional view showing the electric field in the vicinity of a gate of the transistor shown in FIG. 20;

FIGS. 22A to 22D are partial vertical cross-sectional views showing a step of a manufacturing process of the transistor in accordance with the third embodiment of the present invention;

FIGS. 23A to 23D are partial vertical cross-sectional views showing a step of a manufacturing process of the transistor in accordance with the third embodiment of the present invention;

FIGS. 24A to 24D are partial vertical cross-sectional views showing a step of a manufacturing process of the transistor in accordance with the third embodiment of the present invention;

FIGS. 25A to 25D are partial vertical cross-sectional views showing a step of a manufacturing process of the transistor in accordance with the third embodiment of the present invention;

FIGS. 26A to 26D are partial vertical cross-sectional views showing a step of a manufacturing process of the transistor in accordance with the third embodiment of the present invention;

FIGS. 27A to 27D are partial vertical cross-sectional views showing a step of a manufacturing process of the transistor in accordance with the third embodiment of the present invention;

FIG. 28 is a partial vertical cross-sectional view showing a step of a manufacturing process of the transistor in accordance with the third embodiment of the present invention;

FIG. 29 is a partial vertical cross-sectional view of a transistor configuration in accordance with a fourth embodiment of the present invention;

FIG. 30 is a partial vertical cross-sectional view showing the electric field in the vicinity of a gate of the transistor shown in FIG. 29;

FIGS. 31A to 31D are partial vertical cross-sectional views showing a step of a manufacturing process of the transistor in accordance with the fourth embodiment of the present invention;

FIGS. 32A to 32D are partial vertical cross-sectional views showing a step of a manufacturing process of the transistor in accordance with the fourth embodiment of the present invention;

FIGS. 33A to 33D are partial vertical cross-sectional views showing a step of a manufacturing process of the transistor in accordance with the fourth embodiment of the present invention;

FIGS. 34A to 34D are partial vertical cross-sectional views showing a step of a manufacturing process of the transistor in accordance with the fourth embodiment of the present invention;

FIGS. 35A to 35C are partial vertical cross-sectional views showing a step of a manufacturing process of the transistor in accordance with the fourth embodiment of the present invention;

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

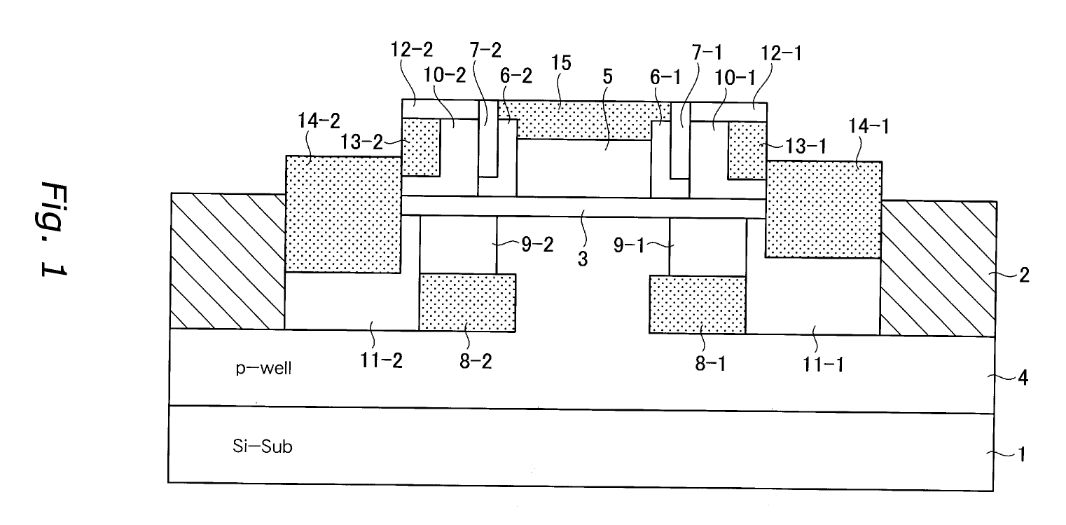

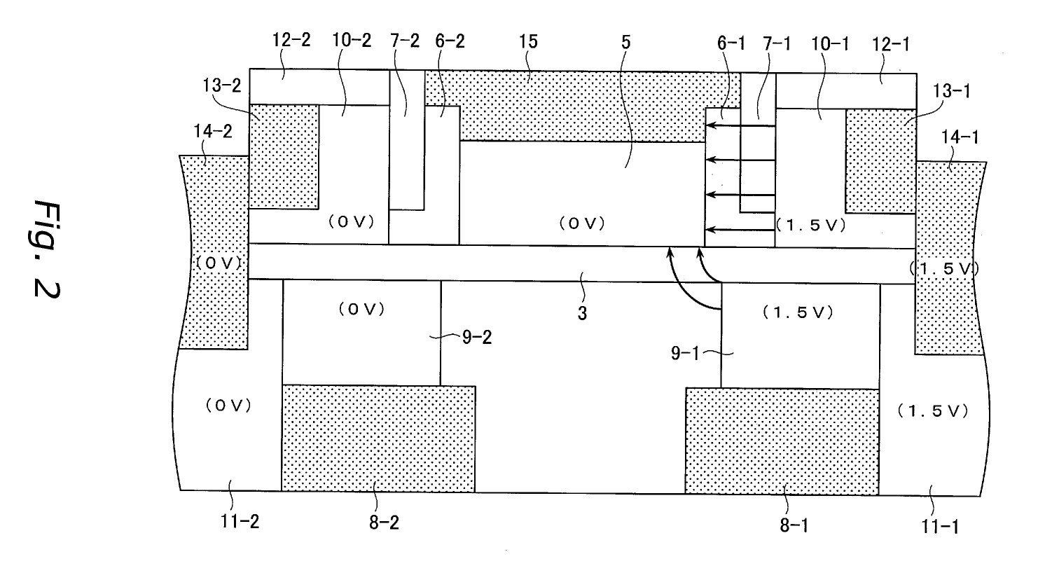

The first embodiment of the present invention provides a field effect transistor (hereinafter referred to as FET). FIG. 1 is a partial vertical cross-sectional view of a transistor configuration in accordance with the first embodiment of the present invention. FIG. 2 is a partial vertical cross-sectional view showing the electric field in the vicinity of a gate of the transistor shown in FIG. 1.

Configuration

As shown in FIG. 1, a FET in accordance with the first embodiment of the present invention is disposed on a silicon substrate 1. More specifically, a field oxide film 2 is selectively disposed on the silicon substrate 1. The field oxide film 2 delimits an active region of the silicon substrate 1. A p-well 4 is disposed in the active region. The FET is disposed in the p-well 4. The FET comprises a gate insulation film 3, a gate structure that is disposed on the gate insulation film 3, first and second sidewall structures that are disposed adjacent to the both sidewalls of the gate structure, a source region, a drain region, and a channel region that is delimited between the source region and the drain region.

The drain region (i.e., a first region or a second region of the present invention) can comprise a drain 11-1, a first extension 9-1 that is disposed adjacent to the inner lateral side of the drain 11-1 and immediately below the gate insulation film 3, a first pocket region 8-1 that is disposed adjacent to the inner lateral side of the drain 11-1 and immediately below the first extension 9-1, and a third silicide layer 14-1 that is disposed immediately above the drain 11-1 and adjacent to the outer lateral side of the gate insulation film 3. The outer lateral edge of the drain 11-1 is delimited by the field oxide film 2. The inner lateral edge of the drain 11-1 contacts the outer lateral edges of the first extension 9-1 and the first pocket region 8-1. The inner lateral edge of the first pocket region 8-1 is located further inside than that of the first extension 9-1. The boundary between the drain 11-1 and the first extension 9-1 (i.e., the boundary between the drain 11-1 and the first pocket region 8-1) is located slightly inside the outer lateral edge of the first sidewall structure. The upper inside region of the drain 11-1 is located immediately below the lateral side portion of the gate insulation film 3. The inner lateral edge of the third silicide layer 14-1 is delimited by the outer lateral edge of the gate insulation film 3. The bottom of the third silicide layer 14-1 is vertically located at a lower level than the level at which the gate insulation film 3 is located, and the top thereof is vertically located at a higher level than the level at which the upper surface of the gate insulation film 3 is located. The inner lateral edge of the upper region of the third silicide layer 14-1 contacts the outer lateral edge of the lower region of the first sidewall structure. Electric potentials of the drain 11-1, the first extension 9-1, and the third silicide layer 14-1, which comprise the drain region, are substantially the same. In other words, the drain 11-1, the first extension 9-1, and the third silicide layer 14-1 have the same potential as the drain potential.

The source region (i.e., a first region or a second region of the present invention) can comprise a source 11-2, a second extension 9-2 that is disposed adjacent to the inner lateral side of the source 11-2 and immediately below the gate insulation film 3, a second pocket region 8-2 that is disposed adjacent to the inner lateral side of the source 11-2 and immediately below the second extension 9-2, and a fourth silicide layer 14-2 that is disposed immediately above the source 11-2 and adjacent to the outer lateral side of the gate insulation film 3. The outer lateral edge of the source 11-2 is delimited by the field oxide film 2. The inner lateral edge of the source 11-2 contacts the outer lateral edges of the second extension 9-2 and the second pocket region 8-2. The inner lateral edge of the second pocket region 8-2 is located further inside than that of the second extension 9-2. The boundary between the source 11-2 and the second extension 9-2 (i.e., the boundary between the source 11-2 and the second pocket region 8-2) is located slightly inside the outer lateral edge of the second sidewall structure. The upper inside region of the source 11-2 is located immediately below the lateral side portion of the gate insulation film 3. The inner lateral edge of the fourth silicide layer 14-2 is delimited by the outer lateral edge of the gate insulation film 3. The bottom of the fourth silicide layer 14-2 is vertically located at a lower level than the level at which the gate insulation film 3 is located, and the top thereof is vertically located at a higher level than the level at which the upper surface of the gate insulation film 3 is located. The inner lateral edge of the upper region of the fourth silicide layer 14-2 contacts the outer lateral edge of the lower region of the second sidewall structure. Electric potentials of the source 11-2, the second extension 9-2, and the fourth silicide layer 14-2, which comprise the source region, are substantially the same. In other words, the source 11-2, the second extension 9-2, and the fourth silicide layer 14-2 have the same potential as the source potential.

The above described gate structure can comprise a gate 5 that is disposed on the gate insulation film 3 and a fifth silicide layer 15 that is disposed on the gate 5. Electric potentials of the gate 5 and the fifth silicide layer 15, which comprise the gate structure, are substantially the same. In other words, the gate 5 and the silicide layer 15 have the same potential as the gate potential.

The above described first sidewall structure is disposed on the gate insulation film 3. In this case, the gate insulation film 3 is configured to be disposed immediately below the gate 5 and extends horizontally outside therefrom. In addition, instead of this configuration, the gate insulation film 3 may be disposed only immediately below the gate 5, and an insulator comprised of a material that is different from that comprising the gate insulation film 3 may be disposed immediately below the first sidewall structure. This insulator, which is comprised of a different material from that comprising the gate insulation film 3, may be disposed under the vicinity region of a first sidewall of the gate 5 so that a portion of the insulator overlaps with the gate 5. In other words, the first sidewall structure is only required to be disposed on a first insulating layer structure. Here, the first insulating layer structure may be comprised of a portion of the gate insulation film 3 that extends horizontally outward from the gate 5. In addition, instead of this, it may be comprised of an insulator comprised of a material that is different from that comprising the gate insulation film 3. Furthermore, it may be comprised of a combination of these. If the first insulating layer structure is comprised of the combination of these, it may be comprised of a multi-layer structure. In addition, it may be configured by extending the insulation film 3 to the vicinity region of the gate 5 and disposing an insulator comprised of a material that is different from that comprising the gate insulation film 3 on a region remote from the gate 5. A typical example of a FET configuration is hereinafter explained in detail. Here, the FET has a configuration in which the gate insulation film 3 is configured to be disposed immediately below the gate 5 and extends horizontally outward therefrom and the above described first sidewall structure is disposed on the gate insulation film 3. However, as described above, it is not necessary to limit the FET configuration to the following configuration.

The first sidewall structure can comprise a first insulating sidewall structure that contacts the first sidewall of the gate structure, and a first conductive sidewall structure that is separated from and electrically isolated from the gate structure through the first insulating sidewall structure and contacts the inner lateral edge of the upper region of the third silicide layer 14-1.

The first conductive sidewall structure is electrically isolated from the gate structure through the first insulating sidewall structure, and at the same time as this, contacts a portion of the above described drain region. Therefore, electric potentials of the drain 11-1, the first extension 9-1, and the third silicide layer 14-1, which comprise the drain region, are substantially the same. In other words, the drain 11-1, the first extension 9-1, and the third silicide layer 14-1 have substantially the same potential as the drain potential. Furthermore, the first conductive sidewall structure can comprise a first gate sidewall conductive film 10-1 and a first silicide layer 13-1. The first gate sidewall conductive film 10-1 is disposed on the gate insulation film 3 and contacts the first insulating sidewall structure. In addition, it is separated from and electrically isolated from the gate structure through the first insulating sidewall structure. Furthermore, it contacts the inner lateral edge of the upper region of the third silicide layer 14-1. On the other hand, the first silicide layer 13-1 is separated from the gate insulation film 3 through the first gate sidewall conductive film 10-1. In addition, it is separated from and electrically isolated from the gate structure through the first gate sidewall conductive film 10-1 and the first insulating sidewall structure. Furthermore, it contacts the inner lateral edge of the upper region of the third silicide layer 14-1.

The first insulating sidewall structure can comprise a first gate sidewall insulation film 6-1, a third gate sidewall insulation film 7-1, and a first insulating cover film 12-1. The first gate sidewall insulation film 6-1 is disposed on the gate insulation film 3 and contacts the first sidewall of the gate structure. Furthermore, the first gate sidewall insulation film 6-1 comprises an outer bottom portion that contacts an inner bottom portion of the first gate sidewall conductive film 10-1. The third gate sidewall insulation film 7-1 is separated from the gate structure through the first gate sidewall insulation film 6-1 and contacts the inner lateral side portion of the first gate sidewall conductive film 10-1. A combination of the first gate sidewall insulation film 6-1 and the third gate sidewall insulation film 7-1 separates and electrically isolates the first conductive sidewall structure from the gate structure. The first insulating cover film 12-1 contacts the outer upper portion of the combination of the first gate sidewall insulation film 6-1 and the third gate sidewall insulation film 7-1, and is disposed on the first conductive sidewall structure.

The above described second sidewall structure is disposed on the gate insulation film 3. In this case, the gate insulation film 3 is configured to be disposed immediately below the gate 5 and extends horizontally outward therefrom. In addition, instead of this configuration, the gate insulation film 3 may be disposed only immediately below the gate 5, and an insulator comprised of a material that is different from that comprising the gate insulation film 3 may be disposed immediately below the second sidewall structure. This insulator, which is comprised of a different material from that comprising the gate insulation film 3, may be disposed under the vicinity region of a second sidewall of the gate 5 so that a portion of the insulator overlaps with the gate 5. In other words, the second sidewall structure is only required to be disposed on a second insulating layer structure. Here, the second insulating layer structure may be comprised of a portion of the gate insulation film 3 that extends horizontally outward from the gate 5. In addition, instead of this, it may be comprised of an insulator comprised of a material that is different from that comprising the gate insulation film 3. Furthermore, it may be comprised of a combination of these. If the second insulating layer structure is comprised of the combination of these, it may be comprised of a multi-layer structure. In addition, it may be configured by extending the insulation film 3 to the vicinity region of the gate 5 and disposing an insulator comprised of a material that is different from that comprising the gate insulation film 3 on a region remote from the gate 5. A typical example of a FET configuration is hereinafter explained in detail. Here, the FET has a configuration in which the gate insulation film 3 is configured to be disposed immediately below the gate 5 and extends horizontally outward therefrom and the above described second sidewall structure is disposed on the gate insulation film 3. However, as described above, it is not necessary to limit the FET configuration to the following configuration.

The second sidewall structure can comprise a second insulating sidewall structure that contacts the second sidewall of the gate structure, and a second conductive sidewall structure that is separated from and electrically isolated from the gate structure through the second insulating sidewall structure and contacts the inner lateral edge of the upper region of the fourth silicide layer 14-2.

The second conductive sidewall structure is electrically isolated from the gate structure through the second insulating sidewall structure, and at the same time as this, contacts a portion of the above described source region. Therefore, electric potentials of the source 11-2, the second extension 9-2, and the fourth silicide layer 14-2, which comprise the source region, are substantially the same. In other words, the source 11-2, the second extension 9-2, and the fourth silicide layer 14-2 have substantially the same potential as the source potential. Furthermore, the second conductive sidewall structure can comprise a second source sidewall conductive film 10-2 and a second silicide layer 13-2. The second gate sidewall conductive film 10-2 is disposed on the gate insulation film 3 and contacts the second insulating sidewall structure. In addition, it is separated from and electrically isolated from the gate structure through the second insulating sidewall structure. Furthermore, it contacts the inner lateral edge of the upper region of the fourth silicide layer 14-2. On the other hand, the second silicide layer 13-2 is separated from the gate insulation film 3 through the second gate sidewall conductive film 10-2. In addition, it is separated from and electrically isolated from the gate structure through the second gate sidewall conductive film 10-2 and the second insulating sidewall structure. Furthermore, it contacts the inner lateral edge of the upper region of the fourth silicide layer 14-2.

The second insulating sidewall structure can comprise a second gate sidewall insulation film 6-2, a fourth gate sidewall insulation film 7-2, and a second insulating cover film 12-2. The second gate sidewall insulation film 6-2 is disposed on the gate insulation film 3 and contacts the second sidewall of the gate structure. Furthermore, the second gate sidewall insulation film 6-2 comprises an outer bottom portion that contacts an inner bottom portion of the second gate sidewall conductive film 10-2. The fourth gate sidewall insulation film 7-2 is separated from the gate structure through the second gate sidewall insulation film 6-2 and contacts the inner lateral side portion of the second gate sidewall conductive film 10-2. A combination of the second gate sidewall insulation film 6-2 and the fourth gate sidewall insulation film 7-2 separates and electrically isolates the second conductive sidewall structure from the gate structure. The second insulating cover film 12-2 contacts the outer upper portion of the combination of the second gate sidewall insulation film 6-2 and the fourth gate sidewall insulation film 7-2, and is disposed on the second conductive sidewall structure.

FIG. 2 is a partial vertical cross-sectional view showing the electric field in the vicinity of the gate of the transistor shown in FIG. 1. Here, the electric field in the vicinity of the gate is based on a case in which potentials of the source, the gate, and the drain are set to be 0V, 0V, and 1.5V, respectively. As shown in FIG. 2, not only an electric field that runs from the first extension 9-1 to the gate 5 through the gate insulation film 3, but also an electric field that runs from the first conductive sidewall structure to the first sidewall of the gate structure through the first insulating sidewall structure is produced. In other words, an electric field that runs from the first conductive sidewall structure to the first sidewall of the gate structure through the first insulating sidewall structure is produced, and accordingly the concentration of the electric field that runs from the first extension 9-1 to the gate 5 through the gate insulation film 3 is reduced. In other words, the concentration of the electric field between the gate and the drain is reduced by the existence of the first sidewall structure that includes the first conductive sidewall structure.

The band-to-band tunneling current is generated due to the steep band bending that is produced in the first extension 9-1 by concentration of the electric field between the gate and the drain. However, the above described first sidewall structure includes the first conductive sidewall structure whose electric potential is substantially the same as that of the drain. Therefore, the above described steep band bending will not be caused. Because of this, the above described first sidewall structure makes it possible to inhibit the band-to-band tunneling current.

In addition, the inner lateral edge of the above described first extension 9-1 may be aligned with, or slightly overlap with or offset from the first sidewall of the gate structure. The amount of overlap or offset is not particularly limited to a specific amount. However, it is preferable for the amount to not exceed the range of plus or minus 10 nm. In other words, a substantially large overlap or offset is not formed between the above described first extension 9-1 and the above described gate 5. However, the above described first sidewall structure includes the first conductive sidewall structure whose electric potential is substantially the same as that of the drain. Therefore, if the electric potential of the gate 5 is high, an accumulation layer is formed in an upper region of the first extension 9-1 and an inversion layer is formed in the channel region below the gate 5. Because of this, even if a substantially large overlap structure is not included in the transistor, resistance in the channel region and the first extension 9-1 is not increased.

Therefore, the above described first sidewall structure that includes the first conductive sidewall structure whose electric potential is substantially the same as that of the drain makes it possible to inhibit the band-to-band tunneling current without reducing the driving force of the transistor.

A method for realizing the above described structure is hereinafter specifically explained.

The above described gate structure can comprise the gate 5 and the fifth silicide layer 15. However, the gate structure is not limited to have this configuration. The above described gate structure may have any configuration as long as it can function as a gate. If the above described gate structure is comprised of the gate 5 and the fifth silicide layer 15, it can be typically configured as follows. The gate 5 can be comprised of a polysilicon film into which impurities are implanted. The concentration of the impurities is not particularly limited to a specific concentration. However, it may be typically set to be 2E20 [atoms/cm³]. The thickness of the polysilicon film is not particularly limited to a specific thickness. However, it may be typically set to be 150 nm. The gate length is not particularly limited to a specific length. However, it may be typically set to be 130 nm. The gate width is not particularly limited to a specific width. The fifth silicide layer 15 can be formed by metal silicidation reactions. A metal with which the silicidation reactions with silicon atoms in the polysilicon film is performed is typically a refractory metal, and may be cobalt (Co), for instance. If the cobalt silicide layer is formed on the polysilicon layer, the thickness thereof is not particularly limited to a specific thickness. However, it may be set to be 150 nm, for instance. The dimensions of the fifth silicide layer 15 in the gate length and gate width directions are the same as those of the gate 5.

The above described gate insulation film 3 can be comprised of an insulator, and the material thereof is not particularly limited to a specific material. However, it can be comprised of silicon oxynitride (SiON), for instance. The thickness of the gate insulation film 3 is not particularly limited to a specific thickness. However, it may be set to be 20 Å, for instance.

The first sidewall structure is comprised of the first insulating sidewall structure and the first conductive sidewall structure. The film structure of the first insulating sidewall structure is not limited to a specific structure. It may be any structure as long as it is configured so that the first conductive sidewall structure is separated and electrically isolated from the gate structure. The first insulating sidewall structure can be comprised of a single-layer structure, but it can be comprised of a multi-layer structure as described above. For example, the first insulating sidewall structure can be comprised of the first gate sidewall insulation film 6-1, the third gate sidewall insulation film 7-1, and the first insulating cover film 12-1. A combination of the first gate sidewall insulation film 6-1 and the third gate sidewall insulation film 7-1 functions as an offset spacer.

The material comprising the first insulating sidewall structure is not particularly limited to a specific material as long as it is comprised of an insulator. However, it can be typically comprised of silicon nitride. The thickness of the first insulating sidewall structure, that is, the dimension thereof in the gate length direction is not particularly limited to a specific dimension as long as the first insulating sidewall structure can separate and electrically isolate the first conductive sidewall structure from the gate structure. However, it may be typically set to be 20 nm. In addition, the width of the first insulating sidewall structure, that is, the dimension thereof in the gate width direction can be set to be the same as the dimension of the gate width of the above described gate structure. The first insulating cover film 12-1 can be comprised of an insulator, and the material thereof is not particularly limited to a specific material. However, it can be comprised of silicon nitride (SiN), for instance. The thickness of the first insulating cover film 12-1 is not particularly limited to a specific thickness. However, it may be set to be 30 nm, for instance. The width of the first insulating cover film 12-1, that is, the dimension thereof in the gate length is preferably set to be the same as the dimension of the first sidewall structure in the gate length direction.

The first conductive sidewall structure can be comprised of a single-layer structure, but it can be comprised of a multi-layer structure as described above. For example, the first conductive sidewall structure can be comprised of the first gate sidewall conductive film 10-1 and the first silicide layer 13-1. The first gate sidewall conductive film 10-1 can be comprised of a conductive material, and the material thereof is not particularly limited to a specific material. However, it can be typically comprised of a polysilicon film into which impurities are implanted. The concentration of the impurities is not particularly limited to a specific concentration. However, it may be typically set to be 2E20 [atoms/cm³]. The thickness of the first gate sidewall conductive film 10-1, that is, the dimension thereof in the gate length direction is not particularly limited to a specific length. However, it may be typically set to be 50 nm. The width of the first gate sidewall conductive film 10-1, that is, the dimension thereof in the gate width direction is preferably set to be the same as the gate width of the above described gate structure. The first silicide layer 13-1 can be formed by metal silicidation reactions. A metal with which the silicidation reactions with silicon atoms in the polysilicon film is performed is typically a refractory metal, and may be cobalt (Co), for instance. If the cobalt silicide layer is formed on the polysilicon layer, the thickness thereof is not particularly limited to a specific thickness. However, it may be set to be 20 nm, for instance. The width of the first silicide layer 13-1, that is, the dimension thereof in the gate width direction may be set to be the same as the gate width of the gate structure.

The electric potential of the first conductive sidewall structure is only required to follow the drain potential not the gate potential. However, the electric potential of the first conductive sidewall structure is not necessarily the same as the drain potential. The first conductive sidewall structure can be typically configured to have the same electric potential as the electric potential of the drain 11-1. Because of this, the first conductive sidewall structure is configured to contact the third silicide layer 14-1.

The second sidewall structure in accordance with the present embodiment of the present invention has the same structure as the structure of the above described first sidewall structure. Therefore, the portion of explanation of the second sidewall structure that overlaps with that of the first sidewall structure is hereinafter omitted. However, the second sidewall structure can be configured to be different from the first sidewall structure. As described above, it is important for the transistor in accordance with the present invention to reduce the concentration of the electric field between the gate and the drain. Therefore, the first sidewall structure that is disposed on the drain side is only required to include the first insulating sidewall structure. In addition, the electric potential of the first conductive sidewall structure is only required to follow the drain potential not the gate potential by configuring the first conductive sidewall structure to be electrically isolated from the gate, and at the same time as this, electrically coupled to the drain. Therefore, if there is no demand like this with regard to the second sidewall structure that is disposed on the source side, the second sidewall structure is not necessarily configured to have the same structure as the above described first conductive sidewall structure. For example, the second sidewall structure can be comprised of a heretofore known sidewall structure. In addition, the second sidewall structure can be configured to have the similar structure to the above described first sidewall structure, that is, the structure in which the layer structure thereof is the same as that of the first sidewall structure but the thickness of each layer therein and material comprising each layer therein are different from those in the first sidewall structure. However, if the second sidewall structure has the same structure as the first sidewall structure, it will be easy to reduce the number of steps required for the manufacturing process of the transistor.

As described above, the drain region can be comprised of the drain 11-1, the first extension 9-1, the first pocket region 8-1, and the third silicide layer 14-1. The drain 11-1 can be comprised of silicon into which impurities are implanted. If the drain 11-1 is formed in the p-well 4, the above described impurities can be comprised of n-type impurities. In other words, the drain 11-1 can be comprised of silicon into which the n-type impurities are implanted. The concentration of the impurities is not particularly limited to a specific concentration. However, it may be typically set to be 2E20 [atoms/cm³]. The depth of the drain 11-1 is not particularly limited to a specific depth. However, it may be typically set to be 200 nm. The third silicide layer 14-1 that is disposed on the drain 11-1 can be formed by metal silicidation reactions. The metal with which the silicidation reactions with silicon atoms in the polysilicon film is performed is typically a refractory metal, and may be cobalt (Co), for instance. The upper inner lateral side portion of the third silicide layer 14-1 is required to contact the lower outer lateral side portion of the first conductive sidewall structure. Therefore, the thickness of the third silicide layer 14-1 is required to be set so that the upper region thereof is vertically located at a higher level than the gate insulation film 3. The thickness of the third silicide layer 14-1 may be set to be 100 nm, for instance.

The first extension 9-1 can be comprised of silicon into which impurities are implanted. If the first extension 9-1 is formed in the p-well 4, the above described impurities can be comprised of n-type impurities. In other words, the first extension 9-1 can be comprised of silicon into which n-type impurities are implanted. The concentration of the impurities is not particularly limited to a specific concentration as long as it is lower than that of the impurities implanted into the drain 11-1. However, it may be typically set to be 1E20 [atoms/cm³]. The depth of the first extension 9-1 is not particularly limited to a specific depth as long as it is shallower than that of the drain 11-1. However, it may be typically set to be 50 nm. The outer lateral edge of the first extension 9-1 is delimited by the inner lateral edge of the drain 11-1. The inner lateral edge of the first extension 9-1 is preferably approximately aligned with the first sidewall of the gate structure. In addition, the first extension 9-1 preferably neither greatly overlaps with nor is offset from the gate 5. Specifically, the inner lateral edge of the first extension 9-1 is preferably aligned with the first sidewall of the gate structure within an error of plus or minus 10 nm.

The first pocket region 8-1 can be comprised of silicon into which impurities are implanted. If the first pocket region 8-1 is formed in the p-well 4, the above described impurities can be comprised of p-type impurities. In other words, the first extension 8-1 can be comprised of silicon into which the p-type impurities are implanted. The concentration of the impurities is not particularly limited to a specific concentration as long as it is lower than that of the impurities implanted into the first extension 9-1. However, it may be typically set to be 1E18 [atoms/cm³]. The thickness of the first pocket region 8-1 is not particularly limited to a specific thickness. However, it may be typically set to be 200 nm. The outer lateral edge of the first pocket region 8-1 is delimited by the inner lateral edge of the drain 11-1. The inner lateral edge of the first pocket region 8-1 is preferably located inside that of the first extension 9-1, and inside the first sidewall of the gate structure. However, it is not necessarily required to be located like this.

The source region in accordance with the present embodiment of the present invention has the same structure as that of the above described drain region. Therefore, the portion of the explanation of the source region that overlaps with that of the drain region is hereinafter omitted. However, the source region may have a structure that is different from that of the drain region. As described above, it is important for the transistor in accordance with the present invention to inhibit the band-to-band tunneling current between the gate and the drain. Therefore, if there is no demand like this with regard to the source region, the source region is not necessarily configured to have the same structure as the above described drain region. For example, the source region can be configured to have a heretofore known structure. In addition, the source region can be configured to have a similar structure to the above described drain structure, that is, the structure in which the layer structure thereof is the same as that of the drain structure, but the thickness of each layer therein, the concentration of the impurities implanted in each layer therein, and the like, are different from those in the drain region. However, if the source region has the same structure as the drain region, it will be easy to reduce the number of steps required for the manufacturing process of the transistor.

The p-well 4 formed in the silicon substrate 1 can be comprised of a silicon into which p-type impurities are implanted. The concentration of the impurities is not particularly limited to a specific concentration. However, it may be typically set to be 5E17 [atoms/cm³].

Next, advantageous effects of the transistor in accordance with the present embodiment are hereinafter explained.

The band-to-band tunneling current is generated due to the steep band bending that is produced in the first extension 9-1 by the electric field between the gate and the drain. However, the above described first sidewall structure includes the first conductive sidewall structure whose electric potential is substantially the same as that of the drain. Therefore, the above described steep band bending will not be caused. Because of this, the above described first sidewall structure makes it possible to inhibit the band-to-band tunneling current.

In addition, the inner edge of the above described first extension 9-1 may be aligned with, or slightly overlap with or be offset from the first sidewall of the gate structure. The amount of overlap or offset is not particularly limited to a specific amount. However, it is preferable for the amount not to exceed the range of plus or minus 10 nm. In other words, a substantially large overlap or offset is not formed between the above described first extension 9-1 and the above described gate 5. However, the above described first sidewall structure includes the first conductive sidewall structure whose electric potential is substantially the same as that of the drain. Therefore, if the electric potential of the gate 5 is high, an accumulation layer is formed in an upper region of the first extension 9-1 and an inversion layer is formed in the channel region below the gate 5. Because of this, even if substantially the large overlap structure is not included in the transistor, resistance in the channel region and the first extension 9-1 is not increased.

Therefore, the above described first sidewall structure that includes the first conductive sidewall structure whose electric potential is substantially the same as that of the drain makes it possible to inhibit the band-to-band tunneling current without reducing the driving force of the transistor.

Manufacturing Method

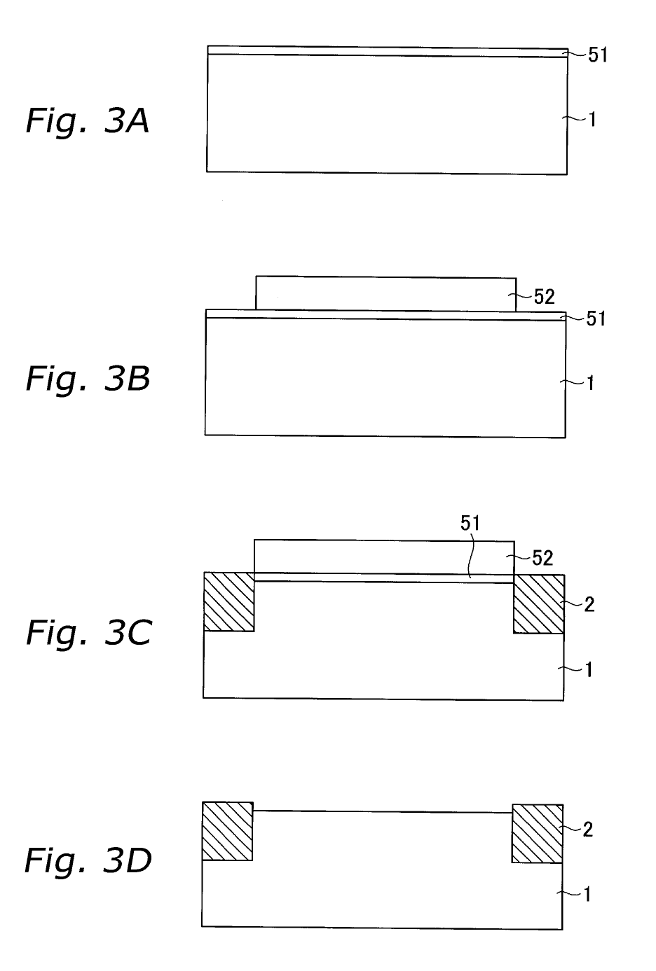

FIGS. 3A to 3D, 4A to 4D, 5A to 5D, 6A to 6D, 7A to 7D, and 8A to 8B are partial vertical cross-sectional views showing steps of a manufacturing process of a transistor in accordance with the first embodiment of the present invention. In reference to these figures, a manufacturing method of the transistor shown in FIGS. 1 and 2 is hereinafter explained in detail.

As shown in FIG. 3A, the surface of a silicon substrate 1 is oxidized, and a pad oxide film 51 with a thickness of 10 nm is formed on the surface of the silicon substrate 1.

As shown in FIG. 3B, a nitride film is deposited on the pad oxide film 51 with a heretofore known deposition method, and then the nitride film is patterned with a heretofore known method. Thus, a nitride film pattern 52 is selectively formed on the pad oxide film 51.

As shown in FIG. 3C, heretofore known local oxidation of silicon (LOCOS) is performed with use of the nitride film pattern 52 as a mask. Thus, a field oxide film 2 is selectively formed on the surface of the silicon substrate 1.

As shown in FIG. 3D, the nitride film pattern 52 and the pad oxide film 51 are removed by heretofore known dry etching. Thus, the surface of the silicon substrate 1 that is not covered with the field oxide film 2 is exposed.

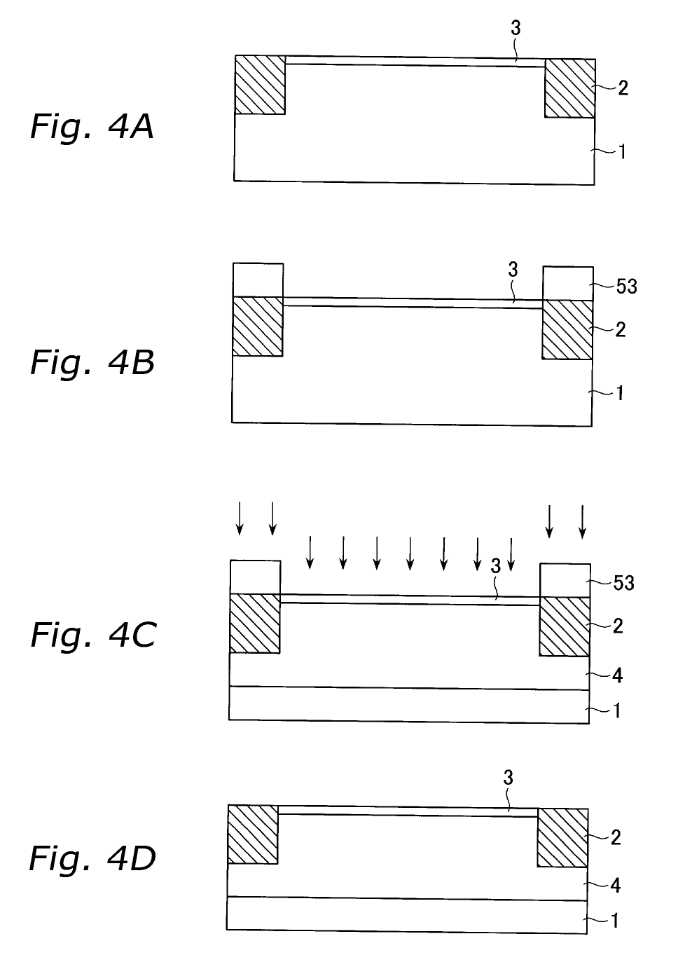

As shown in FIG. 4A, the exposed surface of the silicon substrate 1 is thermally oxidized. Thus, a gate oxide film 3 with a thickness of 2 nm is formed on the exposed surface.

As shown in FIG. 4B, a resist pattern 53 that covers the field oxide film 2 and includes a window immediately above the gate oxide film 3 is formed with a heretofore known lithography technique.

As shown in FIG. 4C, ion implantation is selectively performed with use of the resist pattern 53 as a mask. Thus, a p-well 4 is selectively formed in an upper region of the silicon substrate 1. The ion implantation can be performed in the vertical direction with respect to the substrate surface with the use of boron difluoride (BF₂) as the p-type ion species under conditions in which the acceleration energy is 80 keV and the dose amount is 5E12 [atoms/cm²]. The ion species BF₂ is implanted into the upper region of the silicon substrate 1 through the gate oxide film 3. In this case, the depth of the p-well 4 is formed to be 200 nm.

As shown in FIG. 4D, the resist pattern 53 is removed with a heretofore known method.

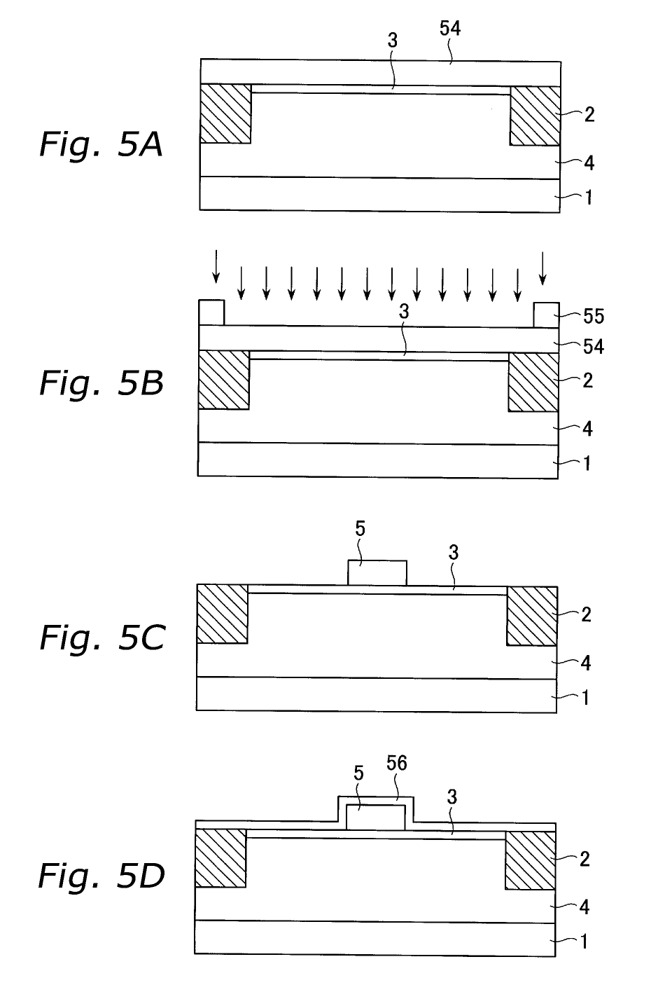

As shown in FIG. 5A, a polysilicon film 54 with a thickness of 1500 Å is deposited to overlie the gate oxide film 3 and the field oxide film 2 with a heretofore known thermal chemical vapor deposition (thermal CVD) method.

As shown in FIG. 5B, a resist pattern 55 that covers the polysilicon film 54 and includes a window above the gate oxide film 3 is formed with a heretofore known lithography technique. Phosphorus (P) is selectively implanted as the n-type ion species with use of the resist pattern 55 as a mask. The ion implantation can be performed in the vertical direction with respect to the substrate surface under conditions in which the acceleration energy is 15 keV and the dose amount is 2E15 [atoms/cm²]. As a result, the n-type impurities are implanted in the polysilicon film 54 that is disposed on the gate oxide film 3.

As shown in FIG. 5C, the resist pattern 55 is removed, and then a new resist pattern is formed to overlie the polysilicon film 54 with a lithography technique. Then, the polysilicon film 54 is patterned with use of the new resist pattern as a mask. Thus, a gate 5 comprised of polysilicon into which impurities are implanted is selectively formed on the gate oxide film 3. Patterning of the polysilicon film 54 can be performed with dry etching. The gate length and the gate width are set as described above. Specifically, the gate length is not particularly limited to a specific length. However, it may be typically set to be 100 nm. In addition, the gate width is not particularly limited to a specific width.

As shown in FIG. 5D, an oxide film 56 with a thickness of 20 nm is formed to cover the upper surface and the sidewalls of the gate 5, the upper surface of the gate insulation film 3, and the upper surface of the field oxide film 2 with a heretofore known thermal CVD method.

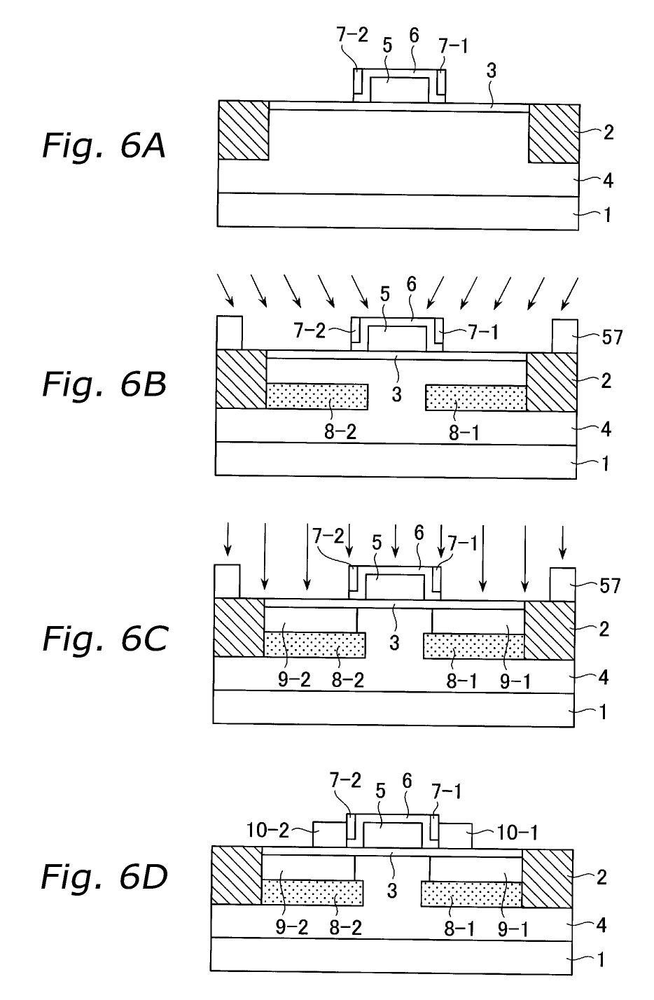

As shown in FIG. 6A, a nitride film with a thickness of 10 nm is deposited to overlie the oxide film 56 with a heretofore known thermal CVD method. Then, dry etching is performed with respect to the nitride film and the oxide film 56, and portions thereof that are disposed on the upper surface and the sidewalls of the gate 5 are left unetched. Thus, a gate sidewall insulation film 6 that is disposed on the upper surface and the sidewalls of the gate 5, a third gate sidewall insulation film 7-1 that is disposed only on one of the sidewalls of the gate 5, and a fourth gate sidewall insulation film 7-2 that is disposed only on the other of the sidewalls of the gate 5, are selectively formed. Here, a combination of the gate sidewall insulation film 6, and the third and fourth gate sidewall insulation films 7-1 and 7-2, all of which are disposed on the sidewalls of the gate 5, functions as a sidewall spacer.

As shown in FIG. 6B, a resist pattern 57 is selectively formed on the field oxide film 2 with a heretofore known lithography technique. Here, the distance between the lateral edge of the resist pattern 57 and the sidewall spacer is set to be 0.5 μm. Then, boron difluoride (BF₂) is selectively implanted into the p-well 4 as the p-type ion species in an oblique direction with respect to the substrate surface with use of the resist pattern 57, the gate 5, the gate sidewall insulation film 6, and the third and the fourth gate sidewall insulation films 7-1 and 7-2 as masks. Specifically, the ion implantation can be performed in an oblique direction at an angle of 30 degrees with respect to the substrate surface under conditions in which the acceleration energy is 80 keV and the dose amount is 2E13 [atoms/cm²], while the silicon substrate 1 is rotated. As a result, first and second pocket regions 8-1 and 8-2 with a depth of 200 nm and an impurity concentration of 1E18 [atoms/cm³] are selectively formed in the p-well 4. In this phase, thermal treatment is not performed in order to activate the impurities ion-implanted therein. The first and second pocket regions 8-1 and 8-2 are disposed in a deep region that is vertically remote from the gate insulation film 3 and extend inward from the inner lateral side of the field oxide film 2. The inner lateral edges of the first and second pocket regions 8-1 and 8-2 are disposed further inside than the third and fourth gate sidewall insulation films 7-1 and 7-2, respectively, because they are formed by the ion-implantation in the oblique direction.

As shown in FIG. 6C, arsenic (As) is selectively implanted into the p-well 4 as the n-type ion species in the vertical direction with respect to the substrate surface with the reuse of the above described resist pattern 57, the gate 5, the gate sidewall insulation film 6, and the third and the fourth gate sidewall insulation films 7-1 and 7-2 as masks. Specifically, the ion implantation can be performed in the vertical direction with respect to the substrate surface under conditions in which the acceleration energy is 5 keV and the dose amount is 1E15 [atoms/cm²]. As a result, first and second extensions 9-1 and 9-2 with a depth of 50 nm and an impurity concentration of 2E20 [atoms/cm³] are selectively formed in the p-well 4. The first and second extensions 9-1 and 9-2 are disposed immediately above the first and second pocket regions 8-1 and 8-2, respectively. In addition, they are disposed immediately below the gate oxide film 3. The first and second extensions 9-1 and 9-2 are formed by ion implantation in the vertical direction. Therefore, the inner edges of the first and second extensions 9-1 and 9-2 are approximately self-aligned with the gate 5. Specifically, the inner edges of the first and second extensions 9-1 and 9-2 are aligned with the gate 5 within an error of plus or minus 10 nm. In other words, the inner lateral edges of the first and second extensions 9-1 and 9-2 are aligned with the gate 5, overlap with the gate 5 within 10 nm, or are offset from the gate 5 within 10 nm. In this phase, thermal treatment is not performed in order to activate the impurities ion-implanted therein. Then, the resist pattern 57 is removed with a heretofore known method.

As shown in FIG. 6D, a polysilicon film with a thickness of 50 nm is deposited to overlie the field oxide film 2, the gate insulation film 3, the gate sidewall insulation film 6, and the third and fourth gate sidewall insulation films 7-1 and 7-2 with a heretofore known thermal CVD method. Then, the polysilicon film is selectively removed by dry etching, and portions thereof that are disposed on both sides of the sidewalls of the gate 5 and contact the gate sidewall insulation film 6 and the third and fourth gate sidewall insulation films 7-1 and 7-2 are left unetched. Furthermore, the unetched portions are over-etched, and thus first and second gate sidewall conductive films 10-1 and 10-2 are formed. The first and second gate sidewall conductive films 10-1 and 10-2 are disposed immediately above the gate oxide film 3 and in the vicinity of the sidewalls of the gate 5, and contact the gate sidewall insulation film 6 and the third and fourth gate sidewall insulation films 7-1 and 7-2. The dimensions of the first and second gate sidewall conductive films 10-1 and 10-2 in the gate length direction are 50 nm. The vertical levels of the upper surfaces of the first and second gate sidewall conductive films 10-1 and 10-2 are slightly lower than those of the gate sidewall insulation film 6 and the third and fourth gate sidewall insulation films 7-1 and 7-2. At this time, the first and second gate sidewall conductive films 10-1 and 10-2 are comprised of polysilicon into which impurities have not been implanted yet.

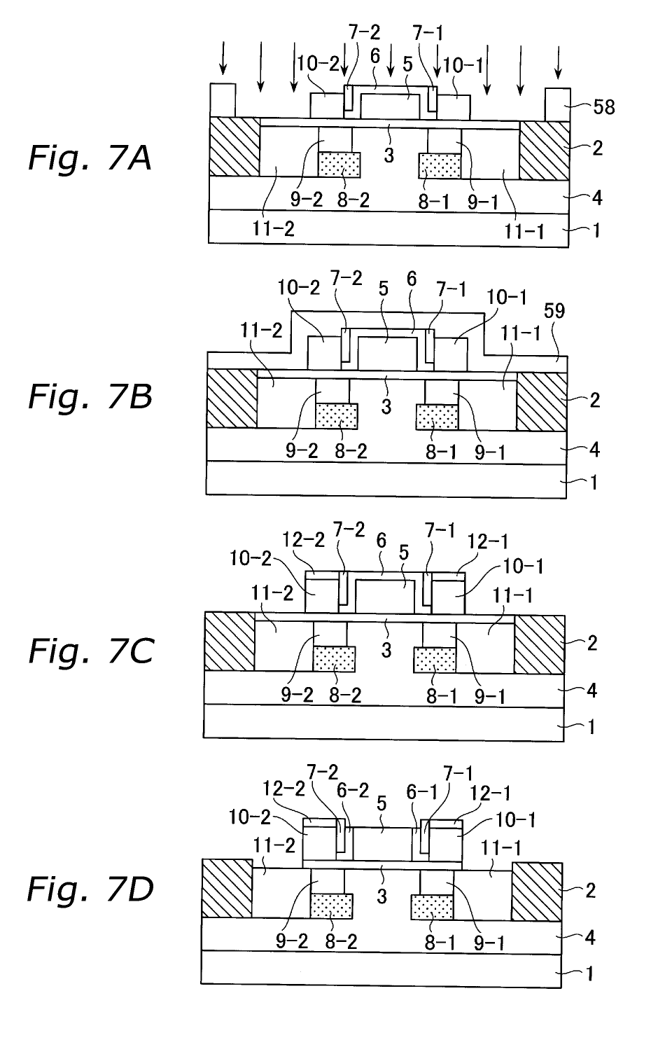

As shown in FIG. 7A, a resist pattern 58 is selectively formed on the field oxide film 2 with a heretofore known lithography technique. Then, phosphorus (P) is selectively implanted into the gate 5, the first and second gate sidewall conductive films 10-1 and 10-2, the first and second extensions 9-1 and 9-2, and the first and second pocket regions 8-1 and 8-2 as the n-type ion species with use of the resist pattern 58, the gate 5, the gate sidewall insulation film 6, the third and fourth gate sidewall insulation films 7-1 and 7-2, and the first and second gate sidewall conductive films 10-1 and 10-2 as masks. Specifically, the ion implantation can be performed in the vertical direction with respect to the substrate surface under conditions in which the acceleration energy is 20 keV and the dose amount is 5E15 [atoms/cm²]. As a result, the gate 5 comprised of polysilicon into which the impurities are implanted, and the first and second gate sidewall conductive films 10-1 and 10-2 comprised of polysilicon into which the impurities are implanted, are formed, and a drain 11-1 and a source 11-2 are selectively formed in the p-well 4.

The n-type impurities do not reach the bottom of the first and second gate sidewall conductive films 10-1 and 10-2. Therefore, portions of the gate oxide film 3 that are disposed immediately below the first and second gate sidewall conductive films 10-1 and 10-2 are not damaged by the ion implantation. In addition, the n-type impurities do not reach the bottom of the gate 5. Therefore, a portion of the gate oxide film 3 that is disposed immediately below the gate 5 is not damaged by the ion implantation.

The outer lateral edges of the drain 11-1 and the source 11-2 are delimited by the field oxide film 2. The inner lateral edge of the drain 11-1 contacts the outer lateral edges of the first extension 9-1 and the first pocket region 8-1. The inner lateral edge of the drain 11-2 contacts the outer lateral edges of the second extension 9-2 and the second pocket region 8-2. As described above, the impurity concentrations of the drain 11-1 and the source 11-2 are higher than those of the first and second extensions 9-1 and 9-2, respectively. In addition, the drain 11-1 and the source 11-2 are formed by selectively implanting the n-type impurities into the horizontally outer regions of the first pocket region 8-1 into which the p-type impurities are implanted and the first extension 9-1 into which the n-type impurities are implanted, and the horizontally outer regions of the second pocket region 8-2 into which the p-type impurities are implanted and the second extension 9-2 into which the n-type impurities are implanted. Therefore, the concentrations of the upper regions in the drain 11-1 and the source 11-2 will be higher and those of the lower regions therein will be lower. After the ion implantation, the resist pattern 58 is removed with a heretofore known method.

Then, a thermal treatment is performed in order to activate the implanted ions in the above described ion implantation process, that is, the p-type impurities that are implanted into the first and second pocket regions 8-1 and 8-2, and the n-type impurities that are implanted into the gate 5, the first and second extensions 9-1 and 9-2, the first and second gate sidewall conductive films 10-1 and 10-2, the drain 11-1, and the source 11-2. The thermal treatment can be performed with rapid thermal anneal (RTA). Specifically, RTA is performed at 1000 degrees Celsius for 10 seconds.

As shown in FIG. 7B, a silicon nitride film 59 is deposited to overlie the gate sidewall insulation film 6, the third and fourth gate sidewall insulation films 7-1 and 7-2, the first and second gate sidewall conductive films 10-1 and 10-2, the gate oxide film 3, and the field oxide film 2 with a heretofore known method.

As shown in FIG. 7C, the silicon nitride film 59 is selectively removed with a heretofore known etching method, and portions thereof that are disposed on the first and second gate sidewall conductive films 10-1 and 10-2 are left unetched. Thus, a first insulating cover film 12-1 comprised of a silicon nitride film that is disposed on the first gate sidewall conductive film 10-1 and a second insulating cover film 12-2 comprised of a silicon nitride film that is disposed on the second gate sidewall conductive film 10-2 are formed.

As shown in FIG. 7D, a portion of the gate sidewall insulation film 6 that is disposed on the upper surface of the gate 5 and the exposed portions of the gate oxide film 3 are removed by wet etching, with use of the first and second insulating cover films 12-1 and 12-2, both of which are comprised of a silicon nitride film as masks. As a result, the upper surfaces of the gate 5, the drain 11-1, and the source 11-2 are exposed. Both of the lateral edges of the gate oxide film 3 are aligned with the outer lateral edges of the first and second gate sidewall conductive films 10-1 and 10-2. In addition, a sidewall spacer comprised of the first gate sidewall insulation film 6-1 and the gate sidewall insulation film 7-1 and a sidewall spacer comprised of the second gate sidewall insulation film 6-2 and the fourth gate sidewall insulation film 7-2 are formed adjacent to the sidewalls of the gate 5, that is, between the gate 5 and the first and second gate sidewall conductive films 10-1 and 10-2.

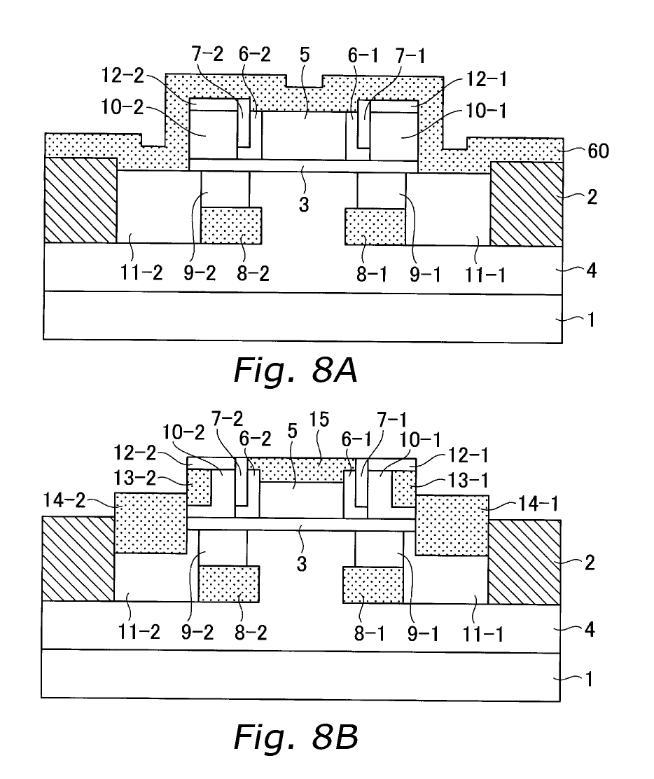

As shown in FIG. 8A, a cobalt (Co) film 60 is deposited with a heretofore known method such as sputtering so as to overlie the exposed upper surface of the gate 5, the upper surfaces of the first and second gate sidewall insulation films 6-1 and 6-2, the upper surfaces and portions of the inner lateral sides of the third and fourth gate sidewall insulation films 7-1 and 7-2, the upper surfaces and the outer lateral sides of the first and second insulating cover films 12-1 and 12-2, the lateral sides of the first and second gate sidewall conductive films 10-1 and 10-2, the exposed upper surfaces of the drain 11-1 and the source 11-2, and the upper surface and a portion of the inner lateral side of the field oxide film 2.

As shown in FIG. 8B, thermal treatment is performed, and thus the silicidation reactions are generated. For example, the thermal treatment is performed at 600 degrees Celsius for 30 seconds, and thus the cobalt silicidation reactions are generated in the interface between the Co film 60 and the upper surface of the gate 5 comprised of polysilicon, the interfaces between the Co film 60 and the lateral sides of the first and second gate sidewall conductive films 10-1 and 10-2, both of which are comprised of polysilicon, the interface between the Co film 60 and the upper surface of the drain 11-1 comprised of polysilicon, and the interface between the Co film 60 and the upper surface of the source 11-2 comprised of polysilicon. As a result, portions of the Co film 60 which are disposed on the upper surface of the gate 5, the sidewalls of the first and second gate sidewall conductive films 10-1 and 10-2, and the upper surfaces of the drain 11-1 and the source 11-2 are selectively silicided. After the thermal treatment, only the unreacted portions of the Co film 60 are removed by wet etching, and only the silicided portions thereof remain. Thus, a fifth silicide layer 15 is formed on the upper surface of the gate 5 in a self-aligned fashion. In addition, first and second silicide layers 13-1 and 13-2 are formed on the sidewalls of the first and second gate sidewall conductive films 10-1 and 10-2, respectively. Furthermore, third and fourth silicide layers 14-1 and 14-2 are formed on the upper surfaces of the drain 11-1 and the source 11-2 in a self-aligned fashion, respectively. Here, the gate 5 has an ohmic contact with the fifth silicide layer 15. In addition, the sidewalls of the first and second gate sidewall conductive films 10-1 and 10-2, have ohmic contacts with the first and second silicide layers 13-1 and 13-2, respectively. Furthermore, the upper surfaces of the drain 11-1 and the source 11-2 have ohmic contacts with the third and fourth silicide layers 14-1 and 14-2, respectively.

The FET shown in FIG. 1 can be produced through the above described series of steps of the manufacturing process.

Note that the above described conductive type of the impurities, the above described thickness of each layer, and the above described impurity concentration, all of which are described in the above described embodiment, are only examples and are not necessarily limited to these descriptions.

First Alternative

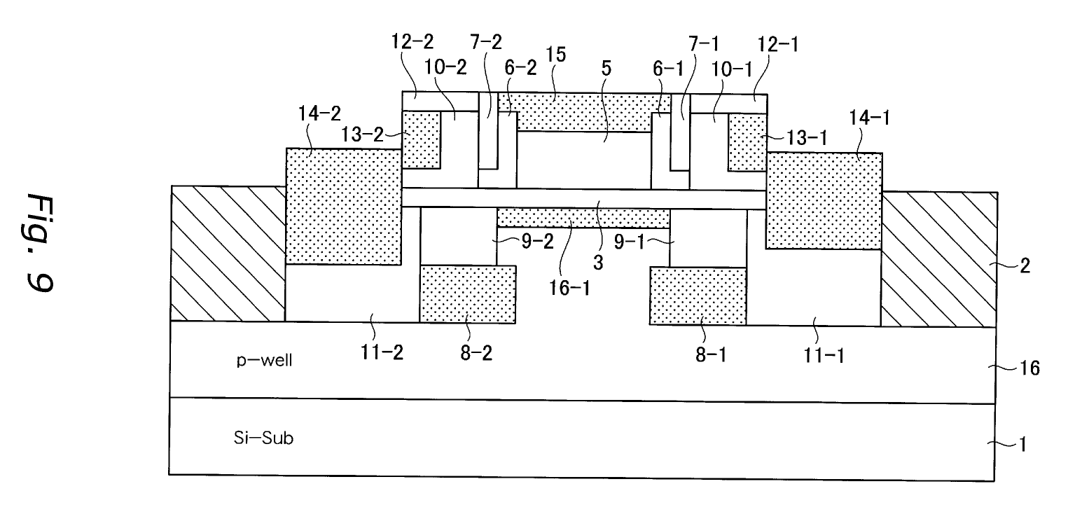

The above described FET is formed in the p-well 4 that is selectively formed to overlie the silicon substrate 1. However, it can be formed in a super steep retrograde well that is selectively formed to overlie the silicon substrate 1, for instance. FIG. 9 is a partial vertical cross-sectional view showing the configuration of a transistor in accordance with a first alternative with respect to the first embodiment of the present invention. In general, a normal well has a substantially uniform impurity concentration. However, when a super steep retrograde well 16 is formed, the impurity concentration of an interface region 16-1 between the super step retrograde well 16 and the gate insulation film 3 is steeply reduced to 1E17 [atoms/cm³], and that of the other regions is 1E18 [atoms/cm³]. With this structure, it is possible to reduce the on-resistance of the transistor and to enhance the driving force thereof. The manufacturing method of the super steep retrograde well 16 is a heretofore known method. Therefore, explanation thereof is hereinafter omitted.

Second Alternative

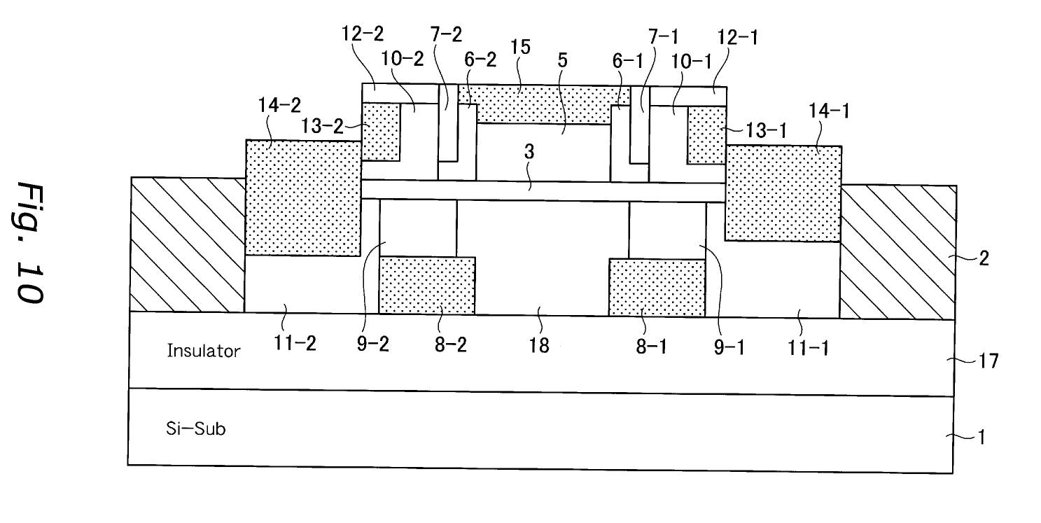

The above described FET is formed in the p-well 4 that is selectively formed to overlie the silicon substrate 1. However, it can be formed to overlie a silicon-on-insulator (SOI) substrate. FIG. 10 is a partial vertical cross-sectional view of a transistor in accordance with a second alternative with respect to the first embodiment of the present invention. A buried oxide film 17 is formed in the silicon substrate 1, and a SOI film 18 comprised of silicon is formed on the buried oxide film 17. The above described FET is formed in the SOI film 18. The manufacturing method of the SOI substrate is a heretofore known method. Therefore explanation thereof is hereinafter omitted.

Third Alternative

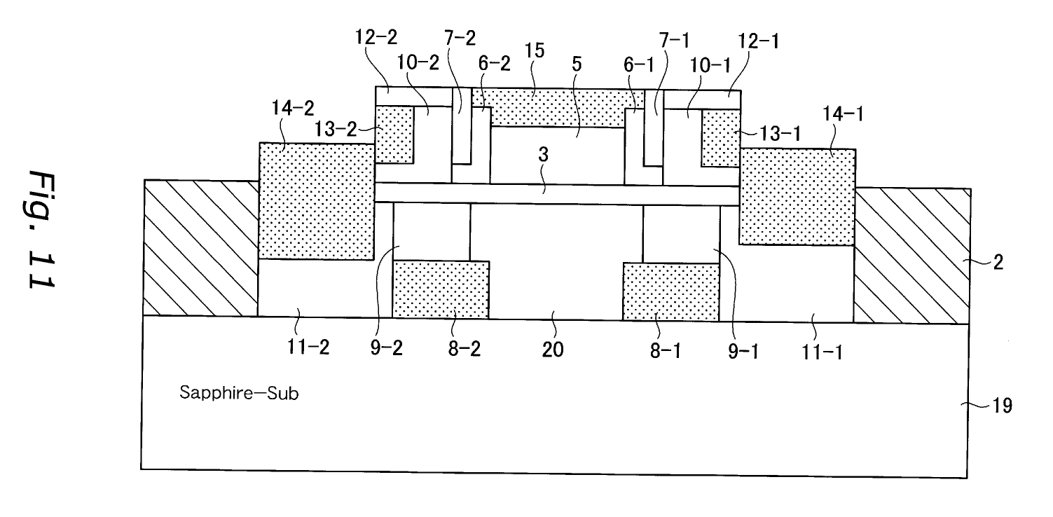

The above described FET is formed in the p-well 4 that is selectively formed to overlie the silicon substrate 1. However, it can be formed to overlie a silicon-on-sapphire (SOS) substrate. FIG. 11 is a partial vertical cross-sectional view of a transistor in accordance with a third alternative with respect to the first embodiment of the present invention. Here, a sapphire substrate 19 is used, and a SOS film 20 comprised of silicon is disposed on the sapphire substrate 19. The above described FET is formed in the SOS film 20. The manufacturing method of the SOS substrate is a heretofore known method. Therefore, explanation thereof is hereinafter omitted.

Fourth Alternative

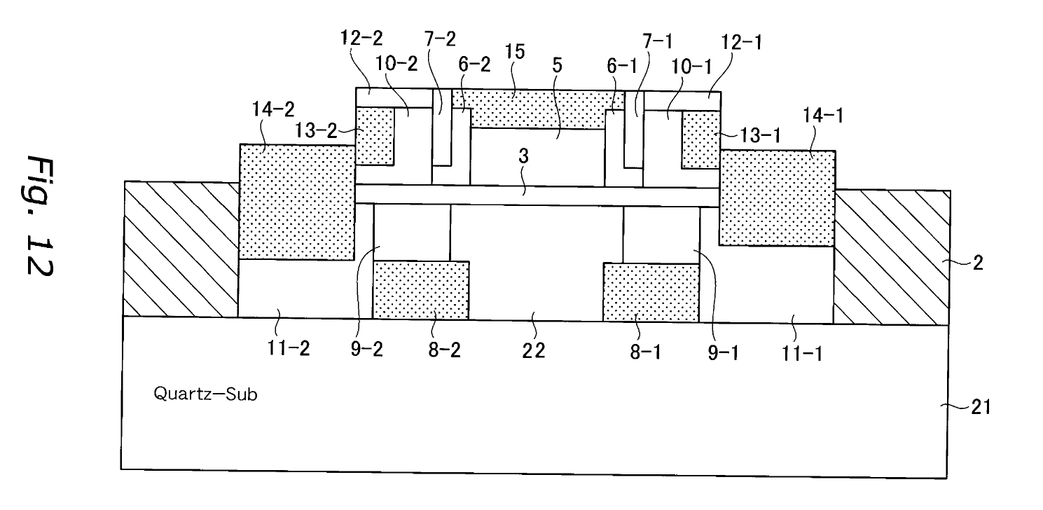

The above described FET is formed in the p-well 4 that is selectively formed to overlie the silicon substrate 1. However, it can be formed to overlie a silicon-on-quartz (SOQ) substrate. FIG. 12 is a partial vertical cross-sectional view of a transistor in accordance with a fourth alternative with respect to the first embodiment of the present invention. Here, a quartz substrate 21 is used, and a SOQ film 22 comprised of silicon is disposed on the quartz substrate 21. The above described FET is formed in the SOQ film 22. The manufacturing method of the SOQ substrate is a heretofore known method. Therefore explanation thereof is hereinafter omitted.

Second to fourth embodiments of the present invention will now be described by focusing on the differences with the above described first embodiment of the present invention. In view of the similarities between the first and second to fourth embodiments, the portions of the second to fourth embodiments that are identical to the portions of the first embodiment will be given the same reference numerals as the portions of the first embodiment. Moreover, the description of the portions of the second to fourth embodiments that are identical to the portions of the first embodiment may be omitted for the sake of brevity.

### Second Embodiment

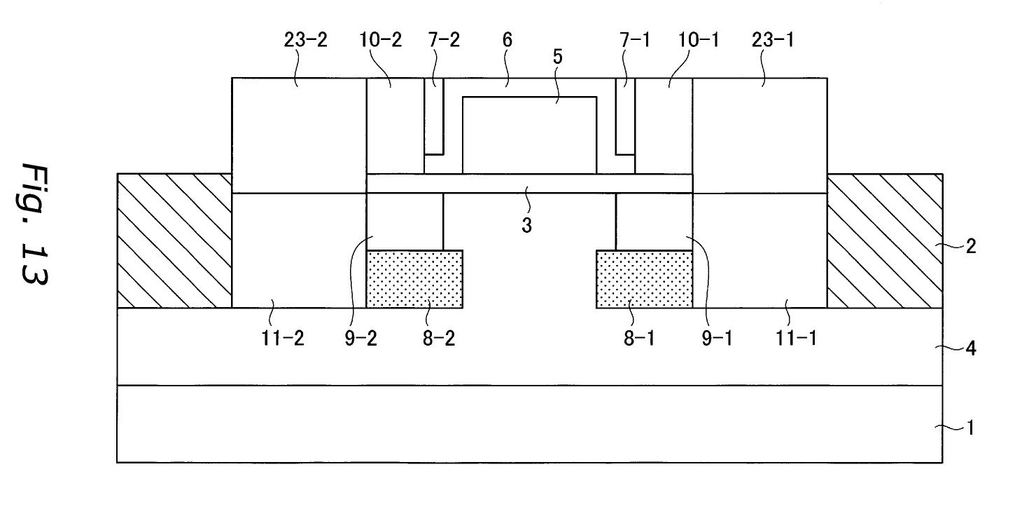

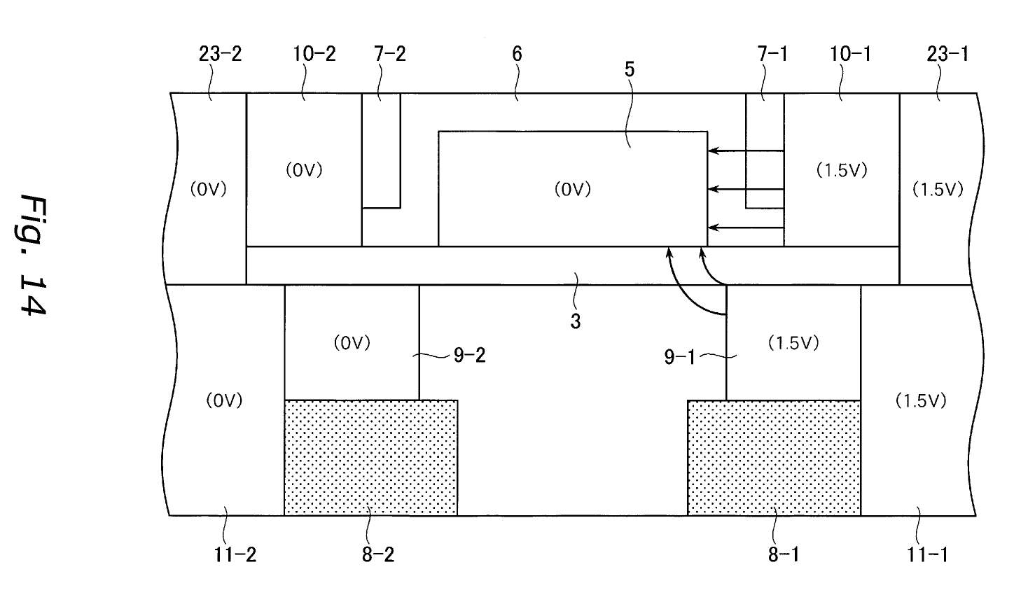

The second embodiment of the present invention provides a field effect transistor (hereinafter referred to as FET). FIG. 13 is a partial vertical cross-sectional view of a transistor configuration in accordance with the second embodiment of the present invention. FIG. 14 is a partial vertical cross-sectional view showing the electric field in the vicinity of the gate of the transistor shown in FIG. 13. The main difference between the second embodiment and the above described first embodiment is in that no silicide layer is formed on a gate, a drain, and a source, and a conductive sidewall structure included in the sidewall structure directly contacts the upper surfaces of the drain and the source.

Differences between the first and second embodiments are hereinafter explained in detail. In the following explanation, components/members of the FET in accordance with the second embodiment, which correspond to those of the FET in accordance with the first embodiment, are given the same numerals used in the first embodiment, and explanations of these components/members are hereinafter omitted.

Configuration

As described in FIG. 13, no silicide layer (which corresponds to the third silicide layer 14-1 in the FET in accordance with the first embodiment) is included in a drain region in the FET in accordance with the second embodiment. Also, no silicide layer (which corresponds to the fourth silicide layer 14-2 in the FET in accordance with the first embodiment) is included in a source region in the FET in accordance with the second embodiment. Furthermore, no silicide layer (which corresponds to the fifth silicide layer 15 in the FET in accordance with the first embodiment) is included in a gate structure in the FET in accordance with the second embodiment.

The first sidewall structure can comprise a first insulating sidewall structure that contacts the first sidewall of the gate structure, and a first conductive sidewall structure that is separated from and electrically isolated from the gate structure through the first insulating sidewall structure and contacts the upper surface of a drain 11-1.

The first conductive sidewall structure is electrically isolated from the gate structure through the first insulating sidewall structure, and at the same time as this, contacts a portion of the above described drain region. Therefore, electric potentials of the drain 11-1 and the first extension 9-1, which comprise the drain region, are substantially the same. In other words, the drain 11-1 and the first extension 9-1 have substantially the same potential as the drain potential. Furthermore, the first conductive sidewall structure can comprise a first gate sidewall conductive film 10-1 and a third gate sidewall conductive film 23-1. The first gate sidewall conductive film 10-1 is disposed on the gate insulation film 3 and contacts the first insulating sidewall structure. In addition, it is separated from and electrically isolated from the gate structure through the first insulating sidewall structure. Furthermore, it contacts the inner lateral edge of the third gate sidewall conductive film 23-1. The third gate sidewall insulation film 23-1 is disposed on the drain 11-1, and the bottom thereof contacts the upper surface of the drain 11-1.

The first insulating sidewall structure can comprise a gate sidewall insulation film 6 and a third gate sidewall insulation film 7-1. The gate sidewall insulation film 6 is disposed on the upper surface of the gate 5 and adjacent to the sidewalls of the gate 5, and also disposed on the gate insulation film 3. Furthermore, the gate sidewall insulation film 6 comprises an outer bottom portion that contacts an inner bottom portion of the first gate sidewall conductive film 10-1. The third gate sidewall insulation film 7-1 is separated from the gate structure through the gate sidewall insulation film 6 and contacts the inner lateral side portion of the first gate sidewall conductive film 10-1. A combination of the gate sidewall insulation film 6 and the third gate sidewall insulation film 7-1 separates and electrically isolates the first conductive sidewall structure from the gate structure.

The second sidewall structure comprises a second insulating sidewall structure that contacts a second sidewall of the gate structure, and a second conductive sidewall structure that is separated from and electrically isolated from the gate structure through the second insulating sidewall structure and contacts the upper surface of a source 11-2.

The second conductive sidewall structure is electrically isolated from the gate structure through the second insulating sidewall structure, and at the same time as this, contacts a portion of the above described source region. Therefore, electric potentials of the source 11-2 and the second extension 9-2, which comprise the source region, are substantially the same. In other words, the source 11-2 and the second extension 9-2 have substantially the same potential as the source potential. Furthermore, the second conductive sidewall structure can comprise a second gate sidewall conductive film 10-2 and a fourth gate sidewall conductive film 23-2. The second gate sidewall conductive film 10-2 is disposed on the gate insulation film 3 and contacts the second insulating sidewall structure. In addition, it is separated from and electrically isolated from the gate structure through the second insulating sidewall structure. Furthermore, it contacts the inner lateral edge of the fourth gate sidewall conductive film 23-2. The fourth gate sidewall conductive film 23-2 is disposed on the source 11-2, and the bottom thereof contacts the upper surface of the source 11-2.

The second insulating sidewall structure can comprise a gate sidewall insulation film 6 and a fourth gate sidewall insulation film 7-2. The gate sidewall insulation film 6 is disposed on the upper surface of the gate 5 and adjacent to the sidewalls of the gate 5, and also disposed on the gate insulation film 3. Furthermore, the gate sidewall insulation film 6 comprises an outer bottom portion that contacts an inner bottom portion of the second gate sidewall conductive film 10-2. The fourth gate sidewall insulation film 7-2 is separated from the gate structure through the gate sidewall insulation film 6 and contacts the inner lateral side portion of the second gate sidewall conductive film 10-2. A combination of the gate sidewall insulation film 6 and the fourth gate sidewall insulation film 7-2 separates and electrically isolates the second conductive sidewall structure from the gate structure.

FIG. 14 is a partial vertical cross-sectional view showing the electric field in the vicinity of the gate of the transistor shown in FIG. 13. Here, the electric field in the vicinity of the gate is based on a case in which potentials of the source, the gate, and the drain are set to be 0 V, 0 V, and 1.5 V, respectively. As shown in FIG. 14, the electric fields are indicated with arrows. In the FET in accordance with the present embodiment, concentration of the electric field that runs from the first extension 9-1 to the gate 5 through the gate insulation film 3 is reduced as described in the first embodiment of the present invention.

Note that a method for realizing the above described structure has already been explained in the first embodiment of the present invention. Therefore, an explanation thereof in this embodiment is hereinafter omitted.

Manufacturing Method

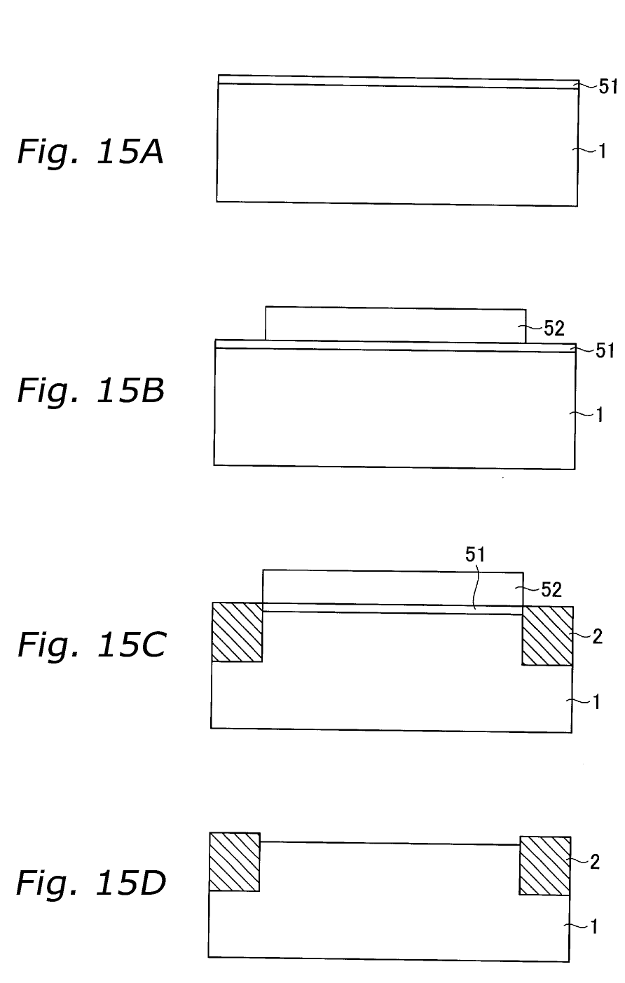

FIGS. 15A to 15D, 16A to 16D, 17A to 17D, 18A to 18D, and 19A to 19D are partial vertical cross-sectional views showing steps of a manufacturing process of a transistor in accordance with the second embodiment of the present invention. In reference to these figures, a manufacturing method of the transistor shown in FIGS. 13 and 14 is hereinafter explained in detail.

As shown in FIG. 15A, the surface of a silicon substrate 1 is oxidized, and a pad oxide film 51 with a thickness of 10 nm is formed on the surface of the silicon substrate 1.

As shown in FIG. 15B, a nitride film is deposited on the pad oxide film 51 with a heretofore known deposition method, and then the nitride film is patterned with a heretofore known method. Thus, a nitride film pattern 52 is selectively formed on the pad oxide film 51.

As shown in FIG. 15C, heretofore known local oxidation of silicon (LOCOS) is performed with use of the nitride film pattern 52 as a mask. Thus, a field oxide film 2 is selectively formed on the surface of the silicon substrate 1.

As shown in FIG. 15D, the nitride film pattern 52 and the pad oxide film 51 are removed by heretofore known dry etching. Thus, the surface of the silicon substrate 1 that is not covered with the field oxide film 2 is exposed.

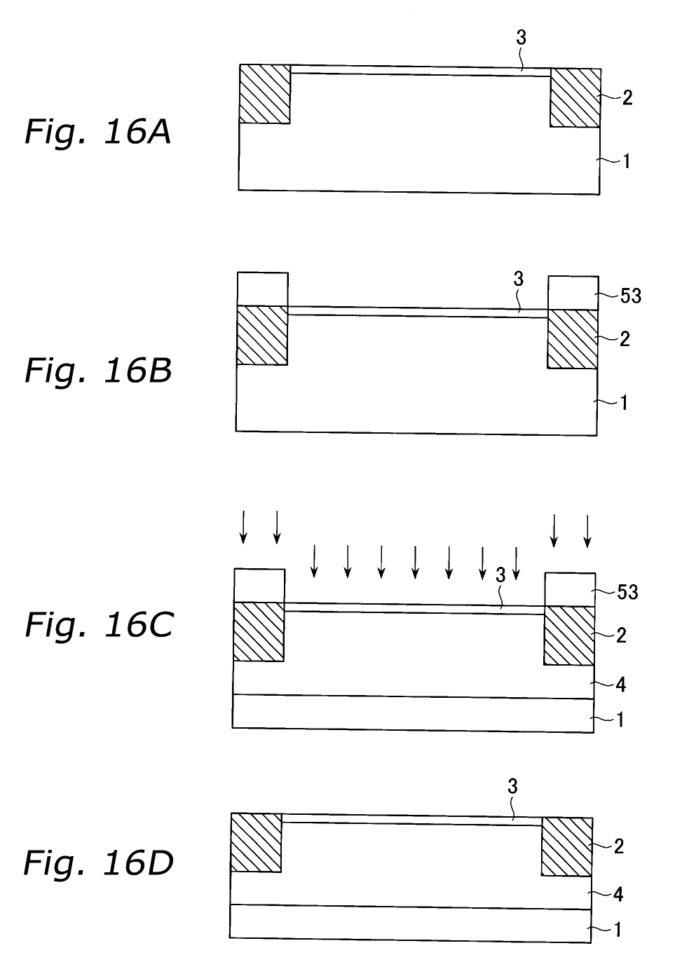

As shown in FIG. 16A, the exposed surface of the silicon substrate 1 is thermally oxidized. Thus, a gate oxide film 3 with a thickness of 2 nm is formed on the exposed surface.

As shown in FIG. 16B, a resist pattern 53 that covers the field oxide film 2 and includes a window immediately above the gate oxide film 3 is formed with a heretofore known lithography technique.

As shown in FIG. 16C, ion implantation is selectively performed with use of the resist pattern 53 as a mask. Thus, a p-well 4 is selectively formed in an upper region of the silicon substrate 1. The ion implantation can be performed in the vertical direction with respect to the substrate surface with use of boron difluoride (BF₂) as the p-type ion species under conditions in which the acceleration energy is 80 keV and the dose amount is 5E12 [atoms/cm²]. The ion species BF₂ is implanted into the upper region of the silicon substrate 1 through the gate oxide film 3. In this case, the depth of the p-well 4 is formed to be 200 nm.

As shown in FIG. 16D, the resist pattern 53 is removed with a heretofore known method.

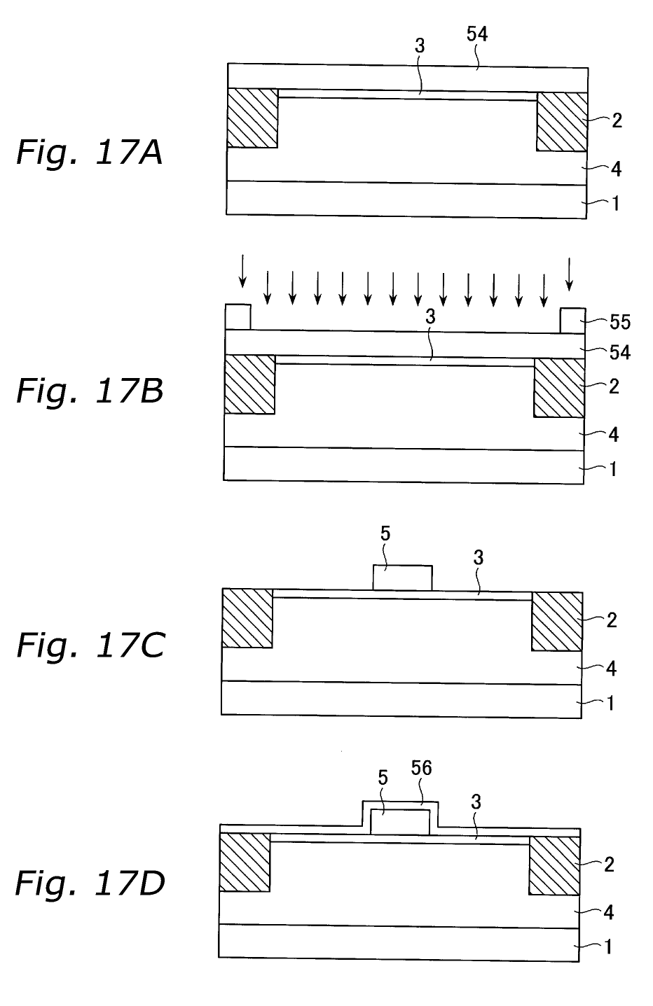

As shown in FIG. 17A, a polysilicon film 54 with a thickness of 1500 Å is deposited to overlie the gate oxide film 3 and the field oxide film 2 with a heretofore known thermal chemical vapor deposition (thermal CVD) method.

As shown in FIG. 17B, a resist pattern 55 that covers the polysilicon film 54 and includes a window above the gate oxide film 3 is formed with a heretofore known lithography technique. Phosphorus (P) is selectively implanted as the n-type ion species with use of the resist pattern 55 as a mask. The ion implantation can be performed in the vertical direction with respect to the substrate surface under conditions in which the acceleration energy is 15 keV and the dose amount is 2E15 [atoms/cm²]. As a result, the n-type impurities are implanted in the polysilicon film 54 that is disposed on the gate oxide film 3.

As described in FIG. 17C, the resist pattern 55 is removed, and then a new resist pattern is formed to overlie the polysilicon film 54 with a lithography technique. Then, the polysilicon film 54 is patterned with use of a new resist pattern as a mask. Thus, a gate 5 comprised of polysilicon into which impurities are implanted is selectively formed on the gate oxide film 3. Patterning of the polysilicon film 54 can be performed with dry etching. The gate length and the gate width are set as described above. Specifically, the gate length is not particularly limited to a specific length. However, it may be typically set to be 100 nm. In addition, the gate width is not particularly limited to a specific width.

As shown in FIG. 17D, an oxide film 56 with a thickness of 70 nm is formed to cover the upper surface and the sidewalls of the gate 5, the upper surface of the gate insulation film 3, and the upper surface of the field oxide film 2 with a heretofore known thermal CVD method.

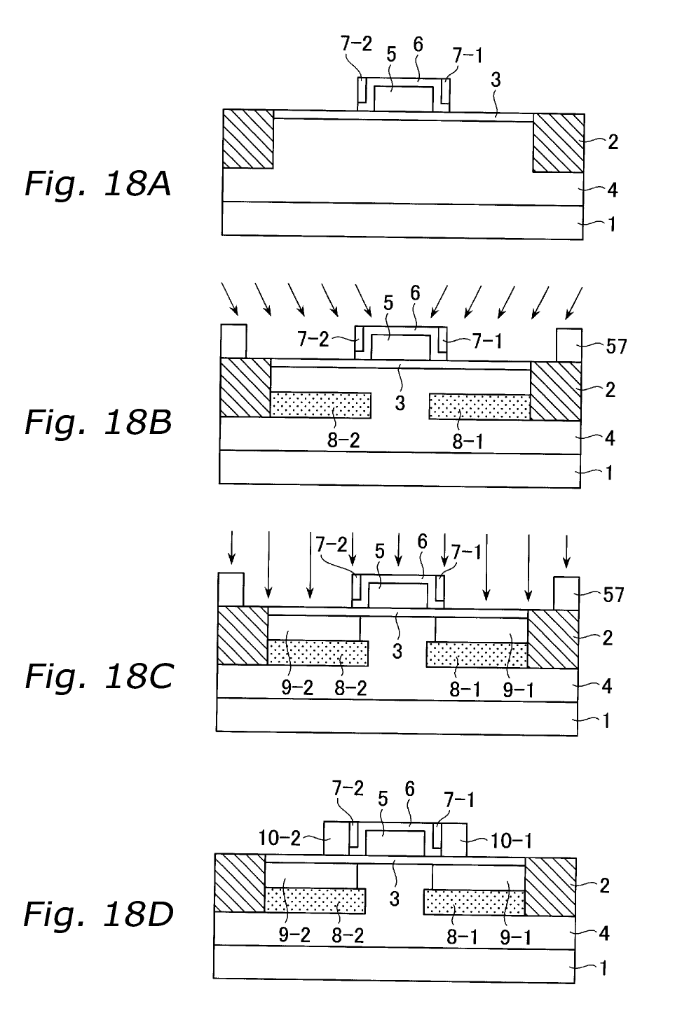

As shown in FIG. 18A, a nitride film with a thickness of 10 nm is deposited to overlie the oxide film 56 with a heretofore known thermal CVD method. Then, dry etching is performed with respect to the nitride film and the oxide film 56, and the portions thereof that are disposed on the upper surface and the sidewalls of the gate 5 are left unetched. Thus, a gate sidewall insulation film 6 that is disposed on the upper surface and the sidewalls of the gate 5, a third gate sidewall insulation films 7-1 that is disposed only on one of the sidewalls of the gate 5, and a fourth gate sidewall insulation film 7-2 that is disposed only on the other of the sidewalls of the gate 5, are selectively formed. Here, a combination of the gate sidewall insulation film 6, and the third and fourth gate sidewall insulation films 7-1 and 7-2, all of which are disposed on the sidewalls of the gate 5, functions as a sidewall spacer.

As shown in FIG. 18B, a resist pattern 57 is selectively formed on the field oxide film 2 with a heretofore known lithography technique. Here, the distance between the lateral edge of the resist pattern 57 and the sidewall spacer is set to be 0.5 μm. Then, boron difluoride (BF₂) is selectively implanted into the p-well 4 as the p-type ion species in an oblique direction with respect to the substrate surface with use of the resist pattern 57, the gate 5, the gate sidewall insulation film 6, and the third and the fourth gate sidewall insulation films 7-1 and 7-2 as masks. Specifically, the ion implantation can be performed in an oblique direction at an angle of 30 degrees with respect to the substrate surface under conditions in which the acceleration energy is 80 keV and the dose amount is 2E13 [atoms/cm²], while the silicon substrate 1 is rotated. As a result, first and second pocket regions 8-1 and 8-2 with a depth of 200 nm and an impurity concentration of 1E18 [atoms/cm³] are selectively formed in the p-well 4. In this phase, thermal treatment is not performed in order to activate the impurities ion-implanted therein. The first and second pocket regions 8-1 and 8-2 are disposed in a deep region that is vertically remote from the gate insulation film 3 and extend inward from the inner lateral side of the field oxide film 2. The inner lateral edges of the first and second pocket regions 8-1 and 8-2 are disposed further inside than the third and fourth gate sidewall insulation films 7-1 and 7-2, respectively, because they are formed by the ion-implantation in the oblique direction.

As shown in FIG. 18C, arsenic (As) is selectively implanted into the p-well 4 as the n-type ion species in the vertical direction with respect to the substrate surface with the reuse of the above described resist pattern 57, the gate 5, the gate sidewall insulation film 6, and the third and the fourth gate sidewall insulation films 7-1 and 7-2 as masks. Specifically, the ion implantation can be performed in the vertical direction with respect to the substrate surface under conditions in which the acceleration energy is 5 keV and the dose amount is 1E15 [atoms/cm²]. As a result, first and second extensions 9-1 and 9-2 with a depth of 50 nm and an impurity concentration of 2E20 [atoms/cm³] are selectively formed in the p-well 4. The first and second extensions 9-1 and 9-2 are disposed immediately above the first and second pocket regions 8-1 and 8-2, respectively. In addition, they are disposed immediately below the gate oxide film 3. The first and second extensions 9-1 and 9-2 are formed by ion implantation in the vertical direction. Therefore, the inner edges of the first and second extensions 9-1 and 9-2 are approximately self-aligned with the gate 5. Specifically, the inner edges of the first and second extensions 9-1 and 9-2 are aligned with the gate 5 within an error of plus or minus 10 nm. In other words, the inner lateral edges of the first and second extensions 9-1 and 9-2 are aligned with the gate 5, overlaps with the gate 5 within 10 nm, or are offset from the gate 5 within 10 nm. In this phase, thermal treatment is not performed in order to activate the impurities ion-implanted therein. Then, the resist pattern 57 is removed with a heretofore known method.

As shown in FIG. 18D, a polysilicon film with a thickness of 50 nm is deposited to overlie the field oxide film 2, the gate insulation film 3, the gate sidewall insulation film 6, and the third and fourth gate sidewall insulation films 7-1 and 7-2 with a heretofore known thermal CVD method. Then, the polysilicon film is selectively removed by dry etching, and portions thereof that are disposed on both sides of the sidewalls of the gate 5 and contact the gate sidewall insulation film 6 and the third and fourth gate sidewall insulation films 7-1 and 7-2 are left unetched. Furthermore, the unetched portions are over-etched, and thus first and second gate sidewall conductive films 10-1 and 10-2 are formed. The first and second gate sidewall conductive films 10-1 and 10-2 are disposed immediately above the gate oxide film 3 and in the vicinity of the sidewalls of the gate 5, and contact the gate sidewall insulation film 6 and the third and fourth gate sidewall insulation films 7-1 and 7-2. The dimensions of the first and second gate sidewall conductive films 10-1 and 10-2 in the gate length direction are 50 nm. The vertical levels of the upper surfaces of the first and second gate sidewall conductive films 10-1 and 10-2 are approximately the same as those of the gate sidewall insulation film 6 and the third and fourth gate sidewall insulation films 7-1 and 7-2. At this time, the first and second gate sidewall conductive films 10-1 and 10-2 are comprised of polysilicon into which impurities have not been implanted yet.

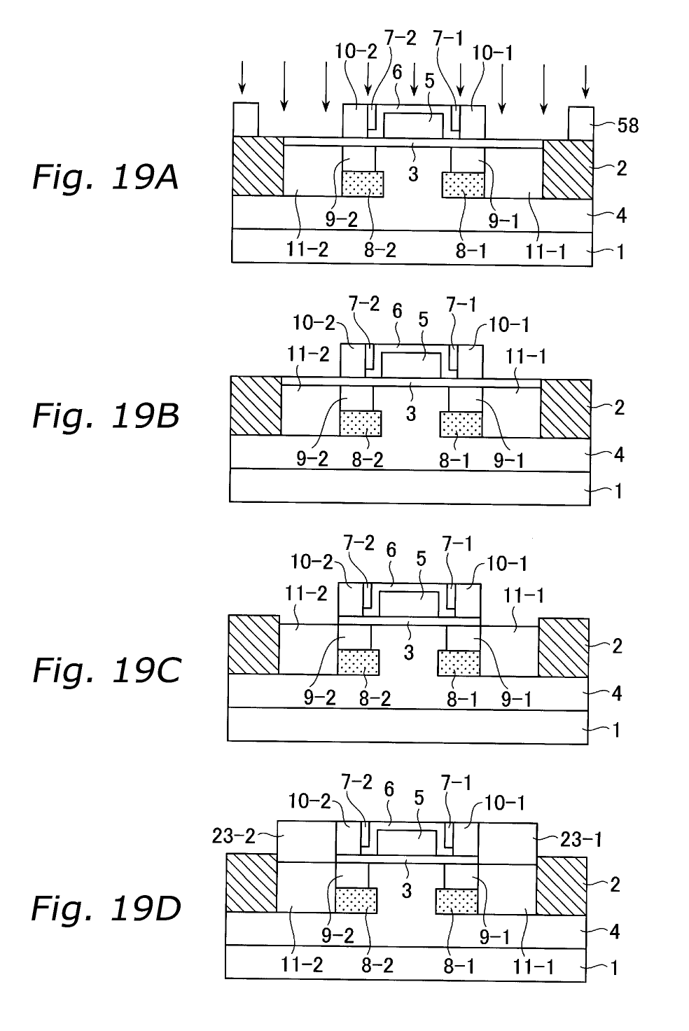

As shown in FIG. 19A, a resist pattern 58 is selectively formed on the field oxide film 2 with a heretofore known lithography technique. Then, phosphorus (P) is selectively implanted into the gate 5, the first and second gate sidewall conductive films 10-1 and 10-2, the first and second extensions 9-1 and 9-2, and the first and second pocket regions 8-1 and 8-2 as the n-type ion species with use of the resist pattern 58, the gate 5, the gate sidewall insulation film 6, the third and fourth gate sidewall insulation films 7-1 and 7-2, and the first and second gate sidewall conductive films 10-1 and 10-2 as masks. Specifically, the ion implantation can be performed in the vertical direction with respect to the substrate surface under conditions in which the acceleration energy is 20 keV and the dose amount is 5E15 [atoms/cm²]. As a result, the gate 5 comprised of polysilicon into which the impurities are implanted, and the first and second gate sidewall conductive films 10-1 and 10-2 comprised of polysilicon into which the impurities are implanted, are formed, and a drain 11-1 and a source 11-2 are selectively formed in the p-well 4.

The n-type impurities do not reach the bottom of the first and second gate sidewall conductive films 10-1 and 10-2. Therefore, portions of the gate oxide film 3 that are disposed immediately below the first and second gate sidewall conductive films 10-1 and 10-2 are not damaged by the ion implantation. In addition, the n-type impurities do not reach the bottom of the gate 5. Therefore, the portion of the gate oxide film 3 that is disposed immediately below the gate 5 is not damaged by the ion implantation.

The outer lateral edges of the drain 11-1 and the source 11-2 are delimited by the field oxide film 2. The inner lateral edge of the drain 11-1 contacts the outer lateral edges of the first extension 9-1 and the first pocket region 8-1. The inner lateral edge of the source 11-2 contacts the outer lateral edges of the second extension 9-2 and the second pocket region 8-2. As described above, the impurity concentrations of the drain 11-1 and the source 11-2 are higher than those of the first and second extensions 9-1 and 9-2, respectively. In addition, the drain 11-1 and the source 11-2 are formed by selectively implanting the n-type impurities into the horizontally outer regions of the first pocket region 8-1 into which the p-type impurities are implanted and the first extension 9-1 into which the n-type impurities are implanted, and the horizontally outer regions of the second pocket region 8-2 into which the p-type impurities are implanted and the second extension 9-2 into which the n-type impurities are implanted. Therefore, the concentrations of the upper regions in the drain 11-1 and the source 11-2 will be higher and those of the lower regions therein will be lower.

Then, a thermal treatment is performed in order to activate the implanted ions in the above described ion implantation process, that is, the p-type impurities that are implanted into the first and second pocket regions 8-1 and 8-2, and the n-type impurities that are implanted into the gate 5, the first and second extensions 9-1 and 9-2, the first and second gate sidewall conductive films 10-1 and 10-2, the drain 11-1, and the source 11-2. The thermal treatment can be performed with rapid thermal anneal (RTA). Specifically, RTA is performed at 1000 degrees Celsius for 10 seconds.

As shown in FIG. 19B, after the ion implantation, the resist pattern 58 is removed with a heretofore known method.

As shown in FIG. 19C, portions of the gate oxide film 3 that contact the upper surfaces of the drain 11-1 and the source 11-2 are selectively removed by a heretofore known selective etching method. Thus, the upper surfaces of the drain 11-1 and the source 11-2 are exposed.

As shown in FIG. 19D, a polysilicon film is deposited to overlie the field oxide film 2, the exposed upper surfaces of the drain 11-1 and the source 11-2, the upper surfaces and the lateral sides of the first and the second gate sidewall conductive films 10-1 and 10-2, the upper surfaces of the third and fourth gate sidewall insulation films 7-1 and 7-2, and the upper surface of the gate sidewall insulation film 6 with a heretofore known thermal CVD method. Then, the polysilicon film is selectively removed by dry etching, and portions thereof that contact the sidewalls of the first and second gate sidewall conductive films 10-1 and 10-2, and the upper surfaces of the drain 11-1 and the source 11-2, are left unetched. Thus, third and fourth gate sidewall conductive films 23-1 and 23-2 are formed. The third and fourth gate sidewall conductive films 23-1 and 23-2 are disposed adjacent to the sidewalls of the first and second gate sidewall conductive films 10-1 and 10-2, and on the upper surfaces of the drain 11-1 and the source 11-2. The dimensions of the third and fourth gate sidewall conductive films 23-1 and 23-2 in the gate length direction are substantially the same as those of the drain 11-1 and the source 11-2. The vertical levels of the upper surfaces of the third and fourth gate sidewall conductive films 23-1 and 23-2 are approximately the same as those of the gate sidewall insulation film 6, the third and fourth gate sidewall insulation films 7-1 and 7-2, and the first and second gate sidewall conductive films 10-1 and 10-2. Then, phosphorus (P) may be ion-implanted into the gate 5, the first and second gate sidewall conductive films 10-1 and 10-2, and the third and fourth gate sidewall conductive films 23-1 and 23-2 as the n-type ion species, and accordingly the third and fourth gate sidewall conductive films 23-1 and 23-2 into which n-type impurities are implanted may be formed.

The FET shown in FIG. 13 can be produced through the above described series of steps of the manufacturing process.

Note that the above described conductive type of the impurities, the above described thickness of each layer, and the above described impurity concentration, all of which are described in the above described embodiment, are only examples and are not necessarily limited to these descriptions. Furthermore, as described in the first embodiment, the above described FET can be formed in a super steep retrograde well. In addition, the above described FET can be formed on a SOI substrate, a SOS substrate, or a SOQ substrate.

### Third Embodiment

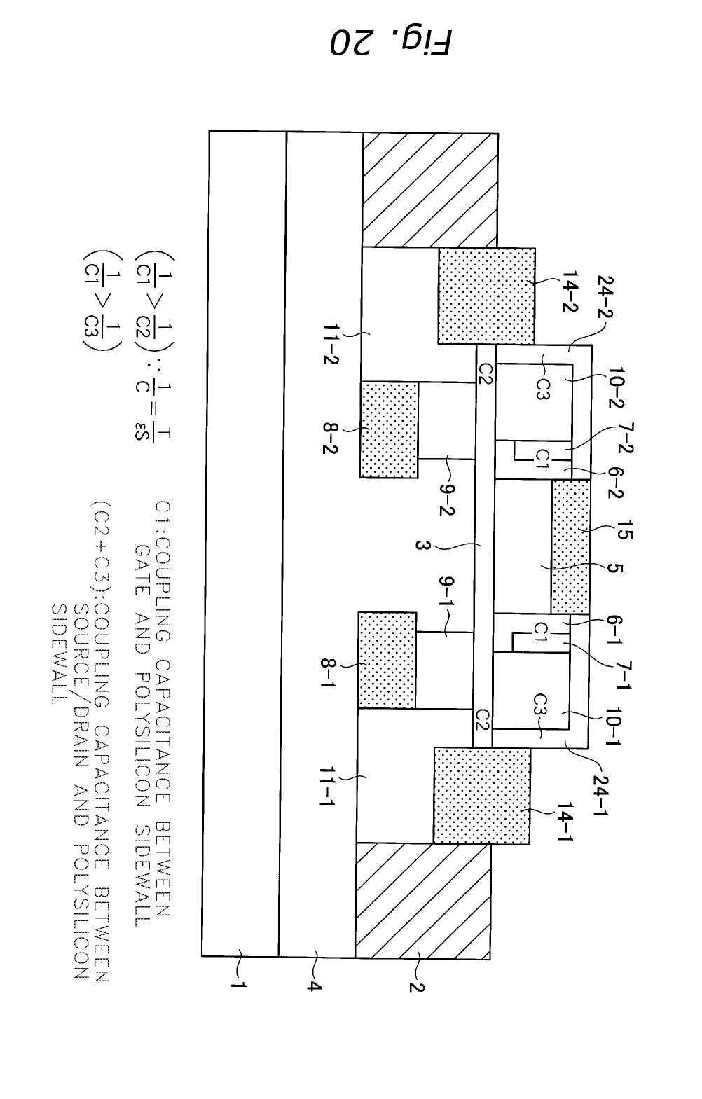

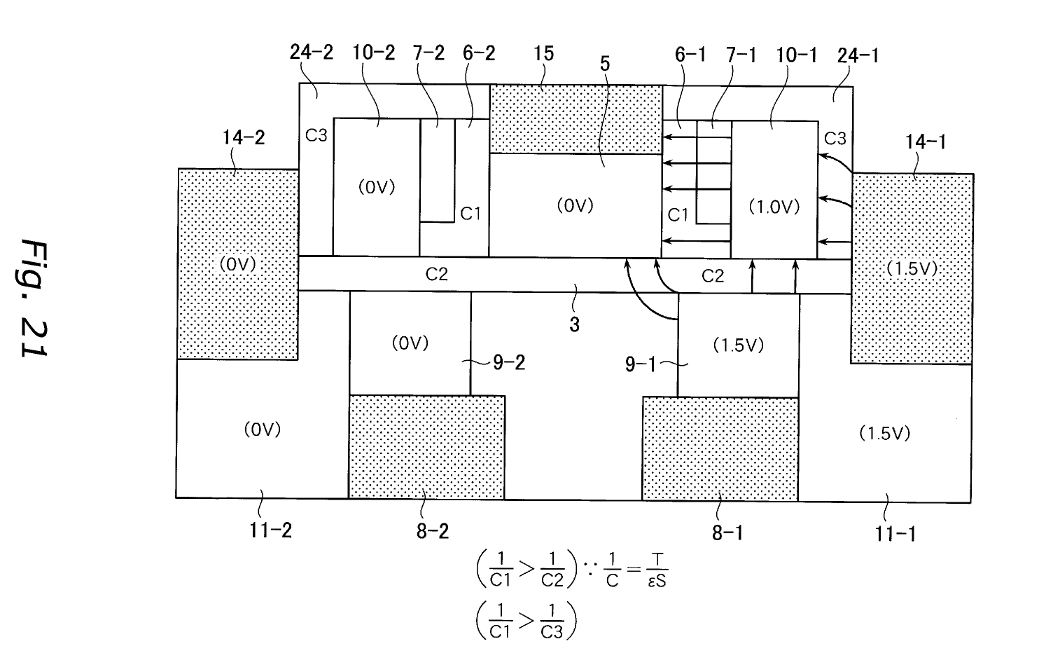

The third embodiment of the present invention provides a field effect transistor (hereinafter referred to as FET). FIG. 20 is a partial vertical cross-sectional view of a transistor configuration in accordance with the third embodiment of the present invention. FIG. 21 is a partial vertical cross-sectional view showing the electric field in the vicinity of the gate of the transistor shown in FIG. 20. The main difference between the third embodiment and the above described first embodiment is in that a conductive sidewall structure included in a sidewall structure is electrically isolated from a gate, a drain, and a source, and has a potential following the drain potential and the source potential more strongly than the gate potential.

Differences between the first and third embodiments are hereinafter explained in detail. In the following explanation, components/members of a field effect transistor in accordance with the third embodiment, which correspond to those of the FET in accordance with the first embodiment, are given the same numerals used in the first embodiment, and explanations of these components/members are hereinafter omitted.

Configuration

Structures of the drain region and the source region in accordance with the third embodiment of the present invention are the same as those in accordance with the above described first embodiment.

The above described gate structure can comprise a gate 5 that is disposed on the gate insulation film 3 and a fifth silicide layer 15 that is disposed on the gate 5. Electric potentials of the gate 5 and the fifth silicide layer 15, which comprise the gate structure, are substantially the same. In other words, the gate 5 and the silicide layer 15 have the same potential as the gate potential.

The above described first sidewall structure is disposed on the gate insulation film 3. In this case, the gate insulation film 3 is configured to be disposed immediately below the gate 5 and extends horizontally outward therefrom. In addition, instead of this configuration, the gate insulation film 3 may be disposed only immediately below the gate 5, and an insulator comprised of a material that is different from that comprising the gate insulation film 3 may be disposed immediately below the first sidewall structure. This insulator, which is comprised of a different material from that comprising the gate insulation film 3, may be disposed under the vicinity of a first sidewall of the gate 5 so that a portion of the insulator overlaps with the gate 5. In other words, the first sidewall structure is only required to be disposed on a first insulating layer structure. Here, the first insulating layer structure may be comprised of a portion of the gate insulation film 3 that extends horizontally outward from the gate 5. In addition, instead of this, it may be comprised of an insulator comprised of a material that is different from that comprising the gate insulation film 3. Furthermore, it may be comprised of a combination of these. If the first insulating layer structure is comprised of the combination of these, it may be comprised of a multi-layer structure. In addition, it may be configured by extending the insulation film 3 to the vicinity of the gate 5 and disposing an insulator comprised of a material that is different from that comprising the gate insulation film 3 on a region remote from the gate 5. A typical example of a FET configuration is hereinafter explained in detail. Here, the FET has a configuration in which the gate insulation film 3 is configured to be disposed immediately below the gate 5 and extend horizontally outward therefrom, and the above described first sidewall structure is disposed on the gate insulation film 3. However, as described above, it is not necessary to limit the FET configuration to the following configuration.

In the third embodiment, the first sidewall structure can comprise a first insulating sidewall structure that contacts the first sidewall of the gate structure, a third insulating sidewall structure that contacts the inner lateral edge of the upper region of a third silicide layer 14-1, and a first conductive sidewall structure that is separated from and electrically isolated from the gate structure through the first insulating sidewall structure, and at the same time as this, separated and electrically isolated from the third silicide layer 14-1 through the third insulating sidewall structure. In other words, the first conductive sidewall structure is electrically isolated from the gate structure and the drain region, and electrically floated.

The first insulating sidewall structure provides a first capacitance C1 between the gate 5 and the first conductive sidewall structure. The gate insulation film 3 provides a second capacitance C2 between the first conductive sidewall structure, and a first extension 9-1 and the drain 11-1. The third insulating sidewall structure provides a third capacitance C3 between the first conductive sidewall structure and the third silicide layer 14-1. Here, the inverse of the first capacitance C1 is larger than that of the second capacitance C2. In addition, the inverse of the first capacitance C1 is larger than that of the third capacitance C3. Based on these relationships, the electric potential of the first conductive sidewall structure is different from that of the gate structure and also different from that of the drain region. However, it follows the potential of the drain region more strongly than that of the gate structure. The inverse of the capacitance C is derived by dividing the thickness of a dielectric (T) by the product of the permittivity of a dielectric (ε) and the area of a dielectric (S). In other words, the following relationship is established: 1/C=T/(εS) Therefore, it is generally possible to configure the thickness of the first insulating sidewall structure, that is, the distance between the gate structure and the first conductive sidewall structure, to be larger than that of the gate insulating film 3. In addition, it is possible to configure the thickness of the first insulating sidewall structure, that is, the distance between the gate structure and the first conductive sidewall structure, to be larger than the thickness of the third insulating sidewall structure, that is, the distance between the third silicide layer 14-1 and the first conductive sidewall structure. Whatever the case, if the above described relationships are satisfied, that is, if the inverse of the first capacitance C1 is larger than that of the second capacitance C2, and at the same time as this, it is larger than the inverse of the third capacitance C3, the potential of the first conductive sidewall structure is different from that of the gate structure, and at the same time as this, it is different from the potential of the drain region, and furthermore, it follows the potential of the drain region more strongly than that of the gate structure.

Furthermore, the first conductive sidewall structure can comprise a first gate sidewall conductive film 10-1. The first gate sidewall conductive film 10-1 is disposed on the gate insulation film 3 and contacts the first insulating sidewall structure. In addition, it is separated from and electrically isolated from the gate structure through the first insulating sidewall structure. Furthermore, it contacts the third insulating sidewall structure, and is separated from and electrically isolated from the third silicide layer 14-1 through the third insulating sidewall structure.

The first insulating sidewall structure can comprise a first gate sidewall insulation film 6-1 and a third gate sidewall insulation film 7-1. The first gate sidewall insulation film 6-1 is disposed on the gate insulation film 3 and contacts the first sidewall of the gate structure. Furthermore, the first gate sidewall insulation film 6-1 comprises an outer bottom portion that contacts an inner bottom portion of the first gate sidewall conductive film 10-1. The third gate sidewall insulation film 7-1 is separated from the gate structure through the first gate sidewall insulation film 6-1 and contacts the inner lateral side portion of the first gate sidewall conductive film 10-1. A combination of the first gate sidewall insulation film 6-1 and the third gate sidewall insulation film 7-1 separates and electrically isolates the first conductive sidewall structure from the gate structure.

Furthermore, the third insulating sidewall structure can comprise a fifth gate sidewall insulation film 24-1. The fifth gate sidewall insulation film 24-1 is disposed on a combination of the first gate insulation film 6-1 and the third gate sidewall insulation film 7-1, and also disposed on the upper portion of the first conductive sidewall structure and adjacent to the outer sidewall of the first conductive sidewall structure. The fifth gate sidewall insulation film 24-1 separates and electrically isolates the first conductive sidewall structure from the drain region.

The second sidewall structure can comprise a second insulating sidewall structure that contacts the second sidewall of the gate structure, a fourth insulating sidewall structure that contacts the inner lateral edge of the upper region of a fourth silicide layer 14-2, and a second conductive sidewall structure that is separated from and electrically isolated from the gate structure through the second insulating sidewall structure, and at the same time as this, separated from and electrically isolated from the fourth silicide layer 14-2 through the fourth insulating sidewall structure. In other words, the second conductive sidewall structure is electrically isolated from the gate structure and the source region, and electrically floated.

The second insulating sidewall structure provides a first capacitance C1 between the gate 5 and the second conductive sidewall structure. The gate insulation film 3 provides a second capacitance C2 between the second conductive sidewall structure, and a second extension 9-2 and the source 11-2. The third insulating sidewall structure provides a third capacitance C3 between the second conductive sidewall structure and the fourth silicide layer 14-2. Here, the inverse of the first capacitance C1 is larger than that of the second capacitance C2. In addition, the inverse of the first capacitance C1 is larger than that of the third capacitance C3. Based on these relationships, the electric potential of the second conductive sidewall structure is different from that of the gate structure and also different from that of the source region. However, it follows the potential of the source region more strongly than that of the gate structure. The inverse of the capacitance C is derived by dividing the thickness of a dielectric (T) by the product of the permittivity of a dielectric (ε) and the area of a dielectric (S). In other words, the following relationship is established: 1/C=T/(εS). Therefore, it is generally possible to configure the thickness of the second insulating sidewall structure, that is, the distance between the gate structure and the second conductive sidewall structure, to be larger than that of the gate insulating film 3. In addition, it is possible to configure the thickness of the second insulating sidewall structure, that is, the distance between the gate structure and the second conductive sidewall structure, to be larger than the thickness of the fourth insulating sidewall structure, that is, the distance between the fourth silicide layer 14-2 and the second conductive sidewall structure. Whatever the case, if the above described relationships are satisfied, that is, if the inverse of the first capacitance C1 is larger than that of the second capacitance C2, and at the same time as this, it is larger than the inverse of the third capacitance C3, the potential of the second conductive sidewall structure will be different from that of the gate structure, and at the same time as this, will be different from the potential of the source region, and furthermore, it will follow the potential of the source region more strongly than that of the gate structure.

Furthermore, the second conductive sidewall structure can comprise a second gate sidewall conductive film 10-2. The second gate sidewall conductive film 10-2 is disposed on the gate insulation film 3 and contacts the second insulating sidewall structure. In addition, it is separated from and electrically isolated from the gate structure through the second insulating sidewall structure. Furthermore, it contacts the fourth insulating sidewall structure, and is separated from and electrically isolated from the fourth silicide layer 14-2 through the fourth insulating sidewall structure.

The second insulating sidewall structure can comprise a second gate sidewall insulation film 6-2 and a fourth gate sidewall insulation film 7-2. The second gate sidewall insulation film 6-2 is disposed on the gate insulation film 3 and contacts the second sidewall of the gate structure. Furthermore, the second gate sidewall insulation film 6-2 comprises an outer bottom portion that contacts an inner bottom portion of the second gate sidewall conductive film 10-2. The fourth gate sidewall insulation film 7-2 is separated from the gate structure through the second gate sidewall insulation film 6-2 and contacts the inner lateral side portion of the second gate sidewall conductive film 10-2. A combination of the second gate sidewall insulation film 6-2 and the fourth gate sidewall insulation film 7-2 separates and electrically isolates the second conductive sidewall structure from the gate structure.

Furthermore, the fourth insulating sidewall structure can comprise a sixth gate sidewall insulation film 24-2. The sixth gate sidewall insulation film 24-2 is disposed on a combination of the second gate insulation film 6-2 and the fourth gate sidewall insulation film 7-2, and also disposed on the upper portion of the second conductive sidewall structure and adjacent to the outer sidewall of the second conductive sidewall structure. The sixth gate sidewall insulation film 24-2 separates and electrically isolates the second conductive sidewall structure from the source region.

FIG. 21 is a partial vertical cross-sectional view showing the electric field in the vicinity of the gate of the transistor shown in FIG. 20. Here, the electric field in the vicinity of the gate is based on a case in which the potentials of the source, the gate, and the drain are set to be 0 V, 0 V, and 1.5 V, respectively. As described above, the electric potential of the first conductive sidewall structure is different from that of the gate structure and also different from that of the drain region. However, it follows the potential of the drain region more strongly than that of the gate structure. Specifically, the first gate sidewall conductive film 10-1 follows the drain potential 1.5 V more strongly than the gate potential 0 V. Therefore, there is a possibility that it has the potential of 1.0 V. Therefore, even if the first conductive sidewall structure comprised of the first gate sidewall conductive film 10-1 is electrically floated, as shown in FIG. 21, not only an electric field that runs from the first extension 9-1 to the gate 5 through the gate insulation film 3, but also an electric field that runs from the first conductive sidewall structure to the first sidewall of the gate structure through the first insulating sidewall structure is produced. In addition, an electric field that runs from the first extension 9-1 and the third silicide layer 14-1 to the first gate sidewall conductive film 10-1 is generated. In other words, the electric field that runs from the first conductive sidewall structure to the first sidewall of the gate structure through the first insulating sidewall structure is produced, and accordingly the concentration of the electric field that runs from the first extension 9-1 to the gate 5 through the gate insulation film 3 is reduced. In other words, the concentration of the electric field between the gate and the drain is reduced by the existence of the first sidewall structure that includes the first conductive sidewall structure.

As described in the aforementioned embodiments, the first sidewall structure that includes the first conductive sidewall structure whose electric potential is similar to the drain potential compared to the gate potential makes it possible to inhibit the band-to-band tunneling current without reducing the driving force of the transistor.

A method for realizing the above described structure is hereinafter explained.

The film structure of the first insulating sidewall structure is not limited to a specific structure. It may be any structure as long as it is configured so that the first conductive sidewall structure is separated and electrically isolated from the drain region, specifically, the third silicide layer 14-1. The third insulating sidewall structure can be comprised of a multi-layer structure, but it can be comprised of a single-layer structure as described above. Furthermore, the third insulating sidewall structure can be comprised of a fifth gate sidewall insulation film 24-1, for instance.

The material comprising the third insulating sidewall structure is not particularly limited to a specific material as long as it is comprised of an insulator. However, it can be typically comprised of silicon nitride or silicon oxide. The thickness of the third insulating sidewall structure, that is, the dimension thereof in the gate length direction is not particularly limited to a specific dimension as long as the third insulating sidewall structure can separate and electrically isolate the first conductive sidewall structure from the gate structure. However, it is preferable for the thickness of the third insulating sidewall structure to be formed more thinly than that of the above described first insulating sidewall structure. In addition, the width of the third insulating sidewall structure, that is, the dimension thereof in the gate width direction can be set to be the same as the dimension of the gate width of the above described gate structure.

The electric potential of the first conductive sidewall structure is only required to follow the drain potential not the gate potential. However, the electric potential of the first conductive sidewall structure is not necessarily the same as the drain potential. Accordingly, the first conductive sidewall structure can configured to have an electric potential that is similar to the drain potential compared to the gate potential. Because of this, the first insulating sidewall structure and the third insulting sidewall structure is configured so that the above described relationships are satisfied, that is, so that the inverse of the first capacitance C1 is larger than that of the third capacitance C3.

The second sidewall structure can be configured to be the same as or different from the first sidewall structure. As described above, it is important for the transistor in accordance with the present invention to reduce the concentration of the electric field between the gate and the drain. Therefore, the first sidewall structure that is disposed on the drain side is only required to include the first insulating sidewall structure. In addition, the electric potential of the first conductive sidewall structure is only required to follow the drain potential compared to the gate potential by configuring the first conductive sidewall structure to be electrically isolated from the gate and the drain, and configuring the inverse of the first capacitance C1 to be larger than that of the third capacitance C3. Therefore, if there is no demand for this with regard to the second sidewall structure that is disposed on the source side, the second sidewall structure is not necessarily configured to have the same structure as the above described first conductive sidewall structure. For example, the second sidewall structure can be comprised of a heretofore known sidewall structure. In addition, the second sidewall structure can be configured to have a similar structure to the above described first sidewall structure, that is, the structure in which the layer structure thereof is the same as that of the first sidewall structure but the thickness of each layer therein and material comprising each layer therein are different from those in the first sidewall structure. However, if the second sidewall structure has the same structure as the first sidewall structure, it will be easy to reduce the number of steps required for the manufacturing process of the transistor.

The film structure of the fourth insulating sidewall structure is not limited to a specific structure. It may be any structure as long as it is configured so that the second conductive sidewall structure is separated and electrically isolated from the source region, specifically, the fourth silicide layer 14-2. The fourth insulating sidewall structure can be comprised of a multi-layer structure, but it can be comprised of a single-layer structure as described above. Furthermore, the fourth insulating sidewall structure can be comprised of a sixth gate sidewall insulation film 24-2, for instance.

The material comprising the fourth insulating sidewall structure is not particularly limited to a specific material as long as it is comprised of an insulator. However, it can be typically comprised of silicon nitride or silicon oxide. The thickness of the fourth insulating sidewall structure, that is, the dimension thereof in the gate length direction is not particularly limited to a specific dimension as long as the fourth insulating sidewall structure can separate and electrically isolate the second conductive sidewall structure from the gate structure. However, it is preferable for the thickness of the fourth insulating sidewall structure to be formed more thinly than that of the above described second insulating sidewall structure. In addition, the width of the fourth insulating sidewall structure, that is, the dimension thereof in the gate width direction can be set to be the same as the dimension of the gate width of the above described gate structure.

The electric potential of the second conductive sidewall structure is only required to follow the source potential not the gate potential. However, the electric potential of the second conductive sidewall structure is not necessarily the same as the source potential. Accordingly, the second conductive sidewall structure can be configured to have an electric potential that is similar to the source potential compared to the gate potential. Because of this, the first insulating sidewall structure and the third insulating sidewall structure are configured so that the above described relationships are satisfied, that is, so that the inverse of the first capacitance C1 is larger than that of the third capacitance C3.

Manufacturing Method

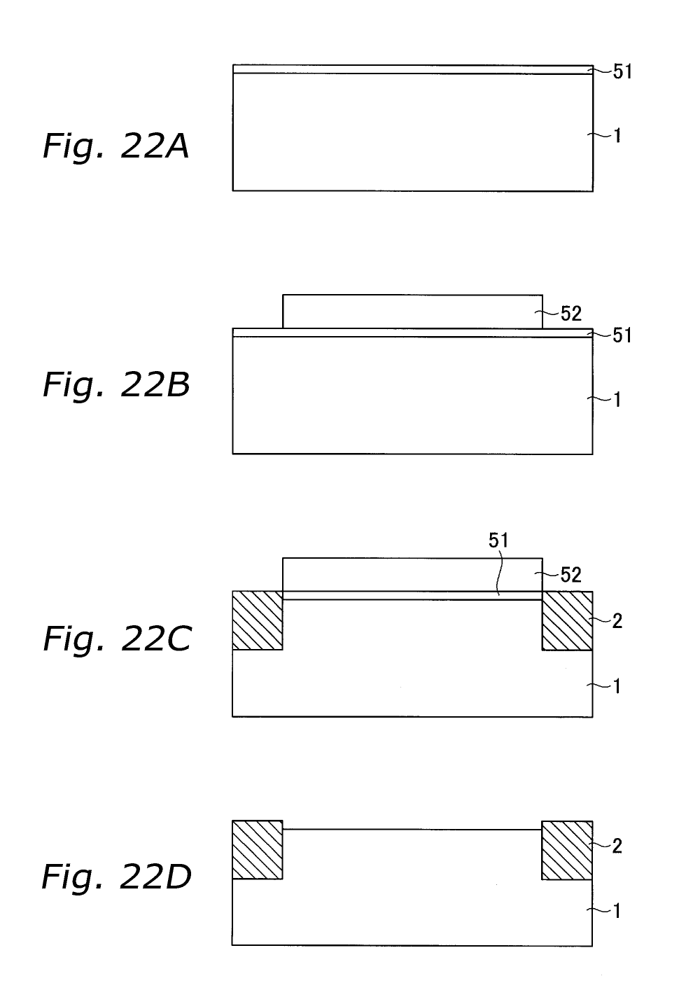

FIGS. 22A to 22D, 23A to 23D, 24A to 24D, 25A to 25D, 26A to 26D, 27A to 27D, and 28 are partial vertical cross-sectional views showing steps of a manufacturing process of a transistor in accordance with the third embodiment of the present invention. In reference to these figures, a manufacturing method of the transistor shown in FIGS. 20 and 21 is hereinafter explained in detail.

As shown in FIG. 22A, the surface of a silicon substrate 1 is oxidized, and a pad oxide film 51 with a thickness of 10 nm is formed on the surface of the silicon substrate 1.

As shown in FIG. 22B, a nitride film is deposited on the pad oxide film 51 with a heretofore known deposition method, and then the nitride film is patterned with a heretofore known method. Thus, a nitride film pattern 52 is selectively formed on the pad oxide film 51.

As shown in FIG. 22C, heretofore known local oxidation of silicon (LOCOS) is performed with use of the nitride film pattern 52 as a mask. Thus, a field oxide film 2 is selectively formed on the surface of the silicon substrate 1.

As shown in FIG. 22D, the nitride film pattern 52 and the pad oxide film 51 are removed by heretofore known dry etching. Thus, the surface of the silicon substrate 1 that is not covered with the field oxide film 2 is exposed.

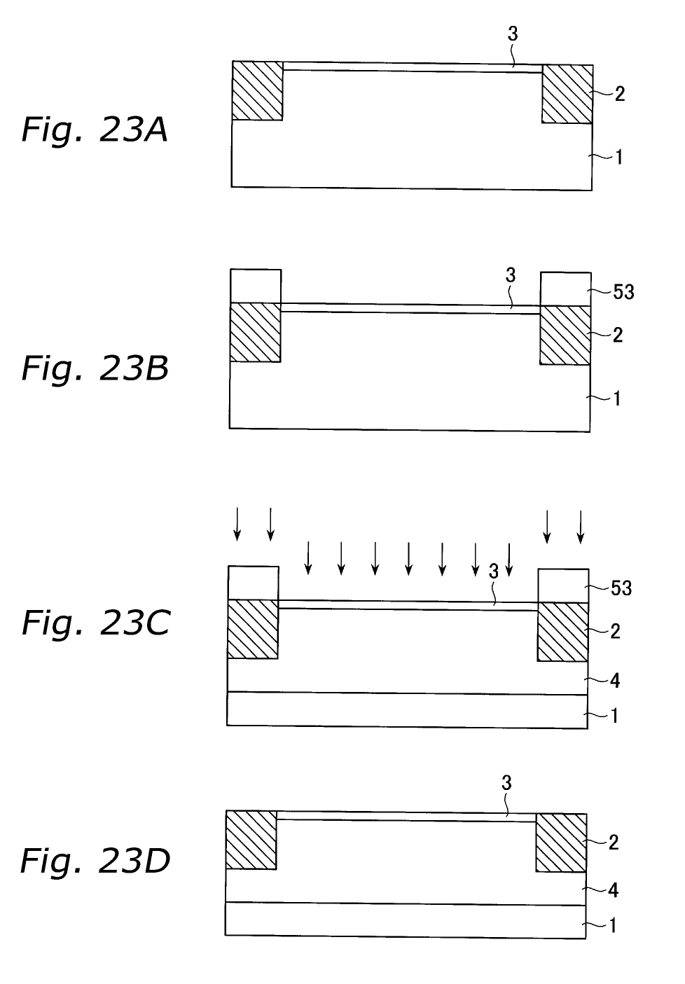

As shown in FIG. 23A, the exposed surface of the silicon substrate 1 is thermally oxidized. Thus, a gate oxide film 3 with a thickness of 2 nm is formed on the exposed surface.

As shown in FIG. 23B, a resist pattern 53 that covers the field oxide film 2 and includes a window immediately above the gate oxide film 3 is formed with a heretofore known lithography technique.

As shown in FIG. 23C, ion implantation is selectively performed with use of the resist pattern 53 as a mask. Thus, a p-well 4 is selectively formed in an upper region of the silicon substrate 1. The ion implantation can be performed in the vertical direction with respect to the substrate surface with use of boron difluoride (BF₂) as the p-type ion species under conditions in which the acceleration energy is 80 keV and the dose amount is 5E12 [atoms/cm²]. The ion species BF₂ is implanted into the upper region of the silicon substrate 1 through the gate oxide film 3. In this case, the depth of the p-well 4 is formed to be 200 nm.

As shown in FIG. 23D, the resist pattern 53 is removed with a heretofore known method.

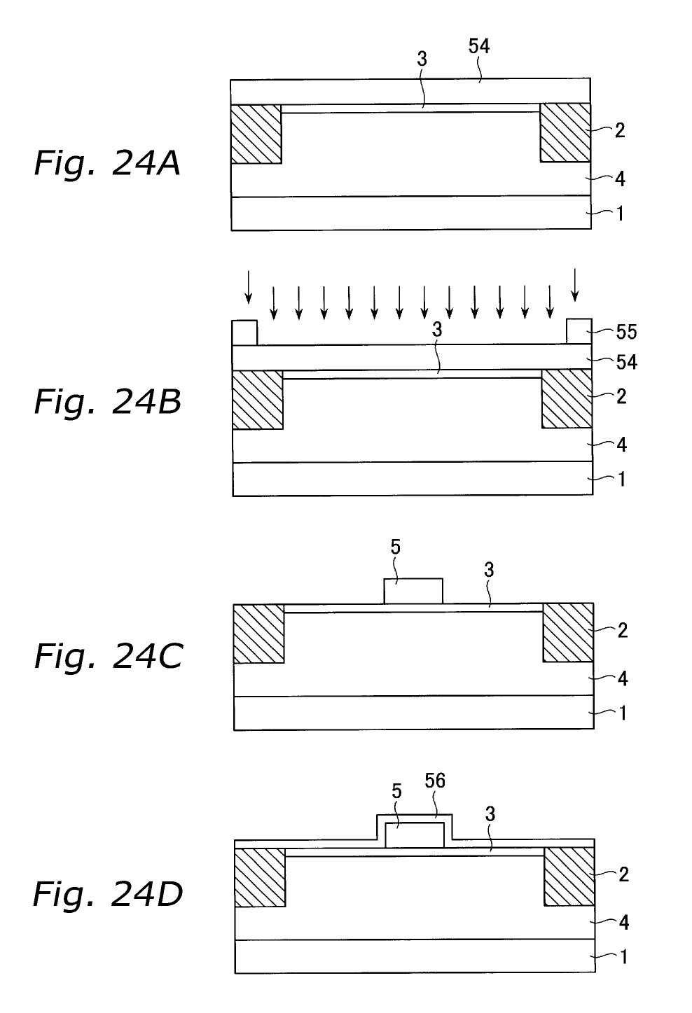

As shown in FIG. 24A, a polysilicon film 54 with a thickness of 1500 Å is deposited to overlie the gate oxide film 3 and the field oxide film 2 with a heretofore known thermal chemical vapor deposition (thermal CVD) method.

As shown in FIG. 24B, a resist pattern 55 that covers the polysilicon film 54 and includes a window above the gate oxide film 3 is formed with a heretofore known lithography technique. Phosphorus (P) is selectively implanted as the n-type ion species with use of the resist pattern 55 as a mask. The ion implantation can be performed in the vertical direction with respect to the substrate surface under conditions in which the acceleration energy is 15 keV and the dose amount is 2E15 [atoms/cm²]. As a result, the n-type impurities are implanted in the polysilicon film 54 that is disposed on the gate oxide film 3.

As described in FIG. 24C, the resist pattern 55 is removed, and then a new resist pattern is formed to overlie the polysilicon film 54 with a lithography technique. Then, the polysilicon film 54 is patterned with use of the new resist pattern as a mask. Thus, a gate 5 comprised of polysilicon into which impurities are implanted is selectively formed on the gate oxide film 3. Patterning of the polysilicon film 54 can be performed with dry etching. The gate length and the gate width are set as described above. Specifically, the gate length is not particularly limited to a specific length. However, it may be typically set to be 100 nm. In addition, the gate width is not particularly limited to a specific width.

As shown in FIG. 24D, an oxide film 56 with a thickness of 70 nm is formed to cover the upper surface and the sidewalls of the gate 5, the upper surface of the gate insulation film 3, and the upper surface of the field oxide film 2 with a heretofore known thermal CVD method.

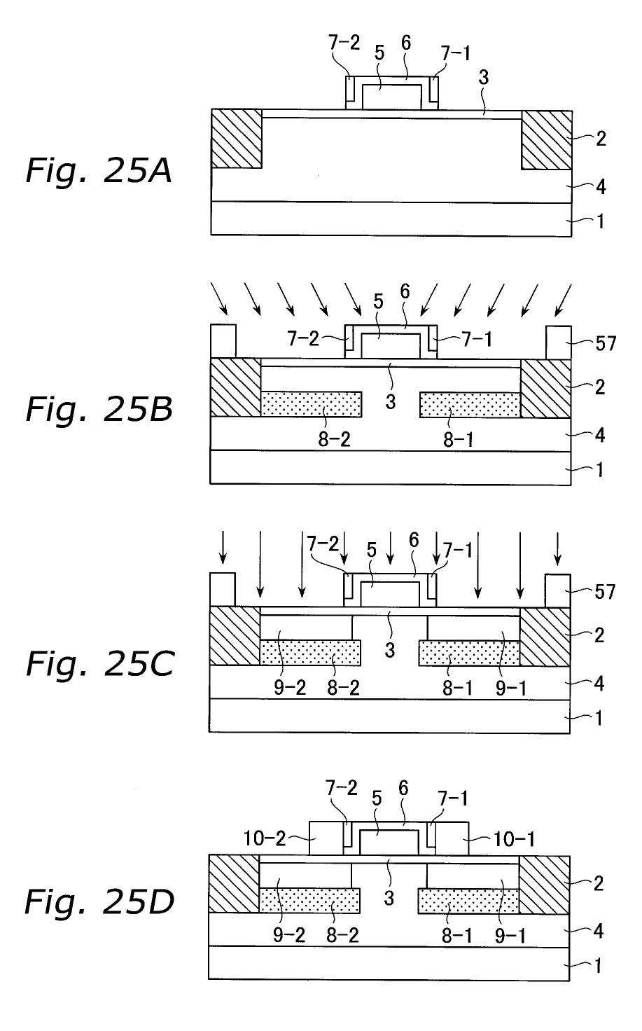

As shown in FIG. 25A, a nitride film with a thickness of 10 nm is deposited to overlie the oxide film 56 with a heretofore known thermal CVD method. Then, dry etching is performed with respect to the nitride film and the oxide film 56, and the portions thereof that are disposed on the upper surface and the sidewalls of the gate 5 are left unetched. Thus, a gate sidewall insulation film 6 that is disposed on the upper surface and the sidewalls of the gate 5, a third gate sidewall insulation films 7-1 that is disposed only on one of the sidewalls of the gate 5, and a fourth gate sidewall insulation film 7-2 that is disposed only on the other of the sidewalls of the gate 5, are selectively formed. Here, a combination of the gate sidewall insulation film 6, and the third and fourth gate sidewall insulation films 7-1 and 7-2, all of which are disposed on the sidewalls of the gate 5, functions as a sidewall spacer.

As shown in FIG. 25B, a resist pattern 57 is selectively formed on the field oxide film 2 with a heretofore known lithography technique. Here, the distance between the lateral edge of the resist pattern 57 and the sidewall spacer is set to be 0.5 μm. Then, boron difluoride (BF₂) is selectively implanted into the p-well 4 as the p-type ion species in an oblique direction with respect to the substrate surface with use of the resist pattern 57, the gate 5, the gate sidewall insulation film 6, and the third and the fourth gate sidewall insulation films 7-1 and 7-2 as masks. Specifically, the ion implantation can be performed in an oblique direction at an angle of 30 degrees with respect to the substrate surface under conditions in which the acceleration energy is 80 keV and the dose amount is 2E13 [atoms/cm²], while the silicon substrate 1 is rotated. As a result, first and second pocket regions 8-1 and 8-2 with a depth of 200 nm and an impurity concentration of 1E18 [atoms/cm³] are selectively formed in the p-well 4. In this phase, thermal treatment is not performed in order to activate the impurities ion-implanted therein. The first and second pocket regions 8-1 and 8-2 are disposed in a deep region that is vertically remote from the gate insulation film 3 and extend inward from the inner lateral side of the field oxide film 2. The inner lateral edges of the first and second pocket regions 8-1 and 8-2 are disposed further inside than the third and fourth gate sidewall insulation films 7-1 and 7-2, respectively, because they are formed by the ion-implantation in the oblique direction.

As shown in FIG. 25C, arsenic (As) is selectively implanted into the p-well 4 as the n-type ion species in the vertical direction with respect to the substrate surface with the reuse of the above described resist pattern 57, the gate 5, the gate sidewall insulation film 6, and the third and the fourth gate sidewall insulation films 7-1 and 7-2 as masks. Specifically, the ion implantation can be performed in the vertical direction with respect to the substrate surface under conditions in which the acceleration energy is 5 keV and the dose amount is 1E15 [atoms/cm²]. As a result, first and second extensions 9-1 and 9-2 with a depth of 50 nm and an impurity concentration of 2E20 [atoms/cm³] are selectively formed in the p-well 4. The first and second extensions 9-1 and 9-2 are disposed immediately above the first and second pocket regions 8-1 and 8-2, respectively. In addition, they are disposed immediately below the gate oxide film 3. The first and second extensions 9-1 and 9-2 are formed by the ion implantation in the vertical direction. Therefore, the inner edges of the first and second extensions 9-1 and 9-2 are approximately self-aligned with the gate 5. Specifically, the inner edges of the first and second extensions 9-1 and 9-2 are aligned with the gate 5 within an error of plus or minus 10 nm. In other words, the inner lateral edges of the first and second extensions 9-1 and 9-2 are aligned with the gate 5, overlaps with the gate 5 within 10 nm, or are offset from the gate 5 within 10 nm. In this phase, thermal treatment is not performed in order to activate the impurities ion-implanted therein. Then, the resist pattern 57 is removed with a heretofore known method.

As shown in FIG. 25D, a polysilicon film with a thickness of 50 nm is deposited to overlie the field oxide film 2, the gate insulation film 3, the gate sidewall insulation film 6, and the third and fourth gate sidewall insulation films 7-1 and 7-2 with a heretofore known thermal CVD method. Then, the polysilicon film is selectively removed by dry etching, and portions thereof that are disposed on both sides of the sidewalls of the gate 5 and contact the gate sidewall insulation film 6 and the third and fourth gate sidewall insulation films 7-1 and 7-2 are left unetched. Thus, first and second gate sidewall conductive films 10-1 and 10-2 are formed. The first and second gate sidewall conductive films 10-1 and 10-2 are disposed immediately above the gate oxide film 3 and in the vicinity of the sidewalls of the gate 5, and contact the gate sidewall insulation film 6 and the third and fourth gate sidewall insulation films 7-1 and 7-2. The dimensions of the first and second gate sidewall conductive films 10-1 and 10-2 in the gate length direction are 50 nm. The vertical levels of the upper surfaces of the first and second gate sidewall conductive films 10-1 and 10-2 are substantially the same as those of the gate sidewall insulation film 6 and the third and fourth gate sidewall insulation films 7-1 and 7-2. At this time, the first and second gate sidewall conductive films 10-1 and 10-2 are comprised of polysilicon into which impurities have not been implanted yet.

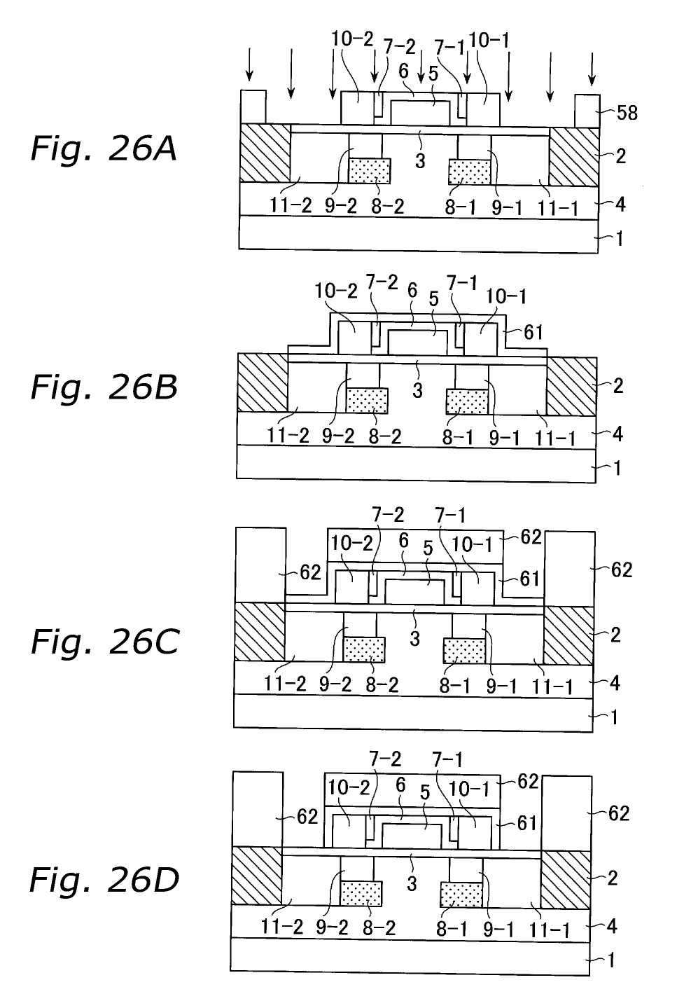

As shown in FIG. 26A, a resist pattern 58 is selectively formed on the field oxide film 2 with a heretofore known lithography technique. Then, phosphorus (P) is selectively implanted into the gate 5, the first and second gate sidewall conductive films 10-1 and 10-2, the first and second extensions 9-1 and 9-2, and the first and second pocket regions 8-1 and 8-2 as the n-type ion species with use of the resist pattern 58, the gate 5, the gate sidewall insulation film 6, the third and fourth gate sidewall insulation films 7-1 and 7-2, and the first and second gate sidewall conductive films 10-1 and 10-2 as masks. Specifically, the ion implantation can be performed in the vertical direction with respect to the substrate surface under conditions in which the acceleration energy is 20 keV and the dose amount is 5E15 [atoms/cm²]. As a result, the gate 5 comprised of polysilicon into which the impurities are implanted, and the first and second gate sidewall conductive films 10-1 and 10-2 comprised of polysilicon into which the impurities are implanted, are formed, and a drain 11-1 and a source 11-2 are selectively formed in the p-well 4.

The n-type impurities do not reach the bottom of the first and second gate sidewall conductive films 10-1 and 10-2. Therefore, portions of the gate oxide film 3 that are disposed immediately below the first and second gate sidewall conductive films 10-1 and 10-2 are not damaged by the ion implantation. In addition, the n-type impurities do not reach the bottom of the gate 5. Therefore, a portion of the gate oxide film 3 that is disposed immediately below the gate 5 is not damaged by the ion implantation.

The outer lateral edges of the drain 11-1 and the source 11-2 are delimited by the field oxide film 2. The inner lateral edge of the drain 11-1 contacts the outer lateral edges of the first extension 9-1 and the first pocket region 8-1. The inner lateral edge of the source 11-2 contacts the outer lateral edges of the second extension 9-2 and the second pocket region 8-2. As described above, the impurity concentrations of the drain 11-1 and the source 11-2 are higher than those of the first and second extensions 9-1 and 9-2, respectively. In addition, the drain 11-1 and the source 11-2 are formed by selectively implanting the n-type impurities into the horizontally outer regions of the first pocket region 8-1 into which the p-type impurities are implanted and the first extension 9-1 into which the n-type impurities are implanted, and the horizontally outer regions of the second pocket region 8-2 into which the p-type impurities are implanted and the second extension 9-2 into which the n-type impurities are implanted. Therefore, the concentrations of the upper regions in the drain 11-1 and the source 11-2 will be higher and those of the lower regions therein will be lower. After the ion implantation, the resist pattern 58 is removed with a heretofore known method.

Then, a thermal treatment is performed in order to activate the implanted ions in the above described ion implantation process, that is, the p-type impurities that are implanted into the first and second pocket regions 8-1 and 8-2, and the n-type impurities that are implanted into the gate 5, the first and second extensions 9-1 and 9-2, the first and second gate sidewall conductive films 10-1 and 10-2, the drain 11-1, and the source 11-2. The thermal treatment can be performed with rapid thermal anneal (RTA). Specifically, RTA is performed at 1000 degrees Celsius for 10 seconds.

As shown in FIG. 26B, a silicon oxide film 61 is deposited to overlie the gate sidewall insulation film 6, the third and fourth gate sidewall insulation films 7-1 and 7-2, the first and second gate sidewall conductive films 10-1 and 10-2, and the gate oxide film 3 with a heretofore known method.

As shown in FIG. 26C, a resist pattern 62 is formed with a heretofore known lithography technique.

The resist pattern 62 covers the field oxide film 2, and also covers a portion of the silicon oxide film 61 that is disposed on the gate sidewall insulation film 6, the third and fourth gate sidewall insulation films 7-1 and 7-2, the first and second gate sidewall conductive films 10-1 and 10-2. In addition, the resist pattern 62 has a window above the drain 11-1 and the source 11-2.

As shown in FIG. 26D, the silicon oxide film 61 is selectively removed with use of the resist pattern 62 as a mask, and thus portions of the gate oxide film 3 that are disposed on the upper surfaces of the drain 11-1 and the source 11-2 are selectively exposed. Then, the resist pattern 62 is removed with a heretofore known method.

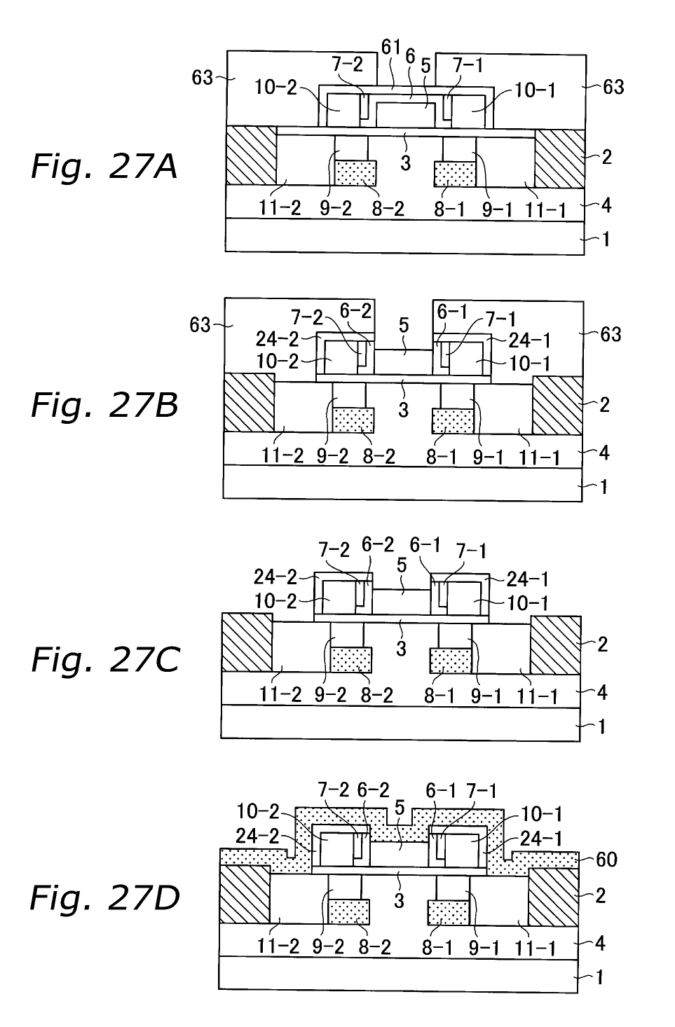

As shown in FIG. 27A, a resist pattern 63 is formed with a heretofore known lithography technique. The resist pattern 63 has a window above the gate 5.

As shown in FIG. 27B, portions of the gate sidewall insulation film 6 and the oxide film 61, both of which are disposed above the gate 5, are selectively removed with use of the resist pattern 63 as a mask. Thus, the upper portion of the gate 5 is exposed. As a result, first and second gate sidewall insulation films 6-1 and 6-2, and fifth and sixth gate sidewall insulation films 24-1 and 24-2 are formed.

As shown in FIG. 27C, the resist pattern 63 is removed with a heretofore known method.

As shown in FIG. 27D, a cobalt (Co) film 60 is deposited with a heretofore known method such as sputtering so as to cover the exposed upper surface of the gate 5, the upper portions of the inner lateral sides of the first and second gate sidewall insulation films 6-1 and 6-2, the upper surfaces and the inner and outer lateral sides of the fifth and sixth gate sidewall insulation films 24-1 and 24-2, the exposed upper surfaces and the drain 11-1 and the source 11-2, and the upper surface and a portion of the inner lateral side of the field oxide film 2.

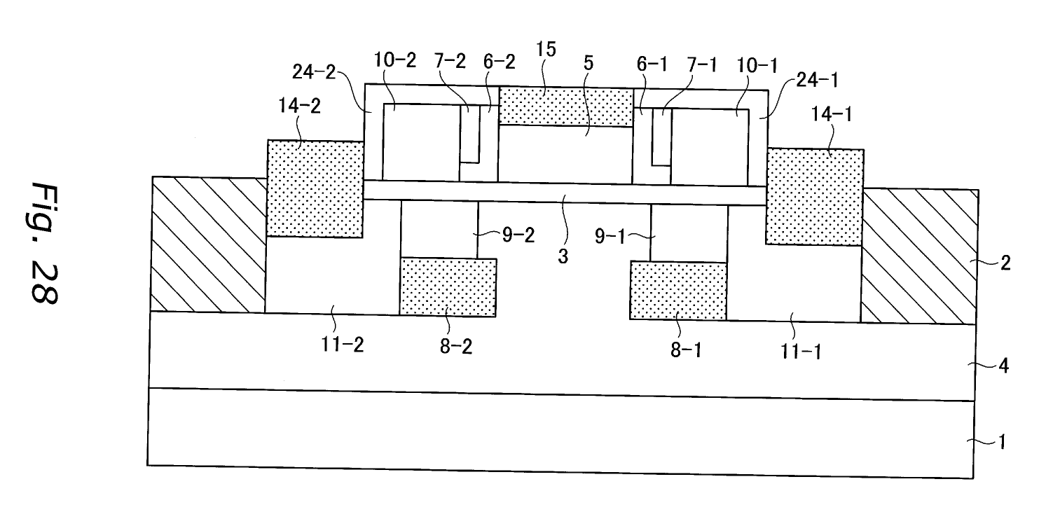

As shown in FIG. 28, thermal treatment is performed, and thus the silicidation reactions are generated. For example, the thermal treatment is performed at 600 degrees Celsius for 30 seconds, and thus the cobalt silicidation reactions are generated in the interface between the Co film 60 and the upper surface of the gate 5 comprised of polysilicon, the interface between the Co film 60 and the upper surface of the drain 11-1 comprised of polysilicon, and the interface between the Co film 60 and the upper surface of the source 11-2 comprised of polysilicon. As a result, portions of the Co film 60 which are disposed on the upper surface of the gate 5, and the upper surfaces of the drain 11-1 and the source 11-2 are selectively silicided. After the thermal treatment, only the unreacted portions of the Co film 60 are removed by wet etching, and only the silicided portions thereof remain. Thus, a silicide layer 15 is formed on the upper surface of the gate 5 in the self-aligned fashion. In addition, third and fourth silicide layers 14-1 and 14-2 are formed on the upper surfaces of the drain 11-1 and the source 11-2 in the self-aligned fashion, respectively. Here, the gate 5 has an ohmic contact to the fifth silicide layer 15. Furthermore, the upper surfaces of the drain 11-1 and the source 11-2 have ohmic contacts with the third and fourth silicide layers 14-1 and 14-2, respectively.

The FET shown in FIG. 21 can be produced through the above described series of steps of the manufacturing process.

### Fourth Embodiment

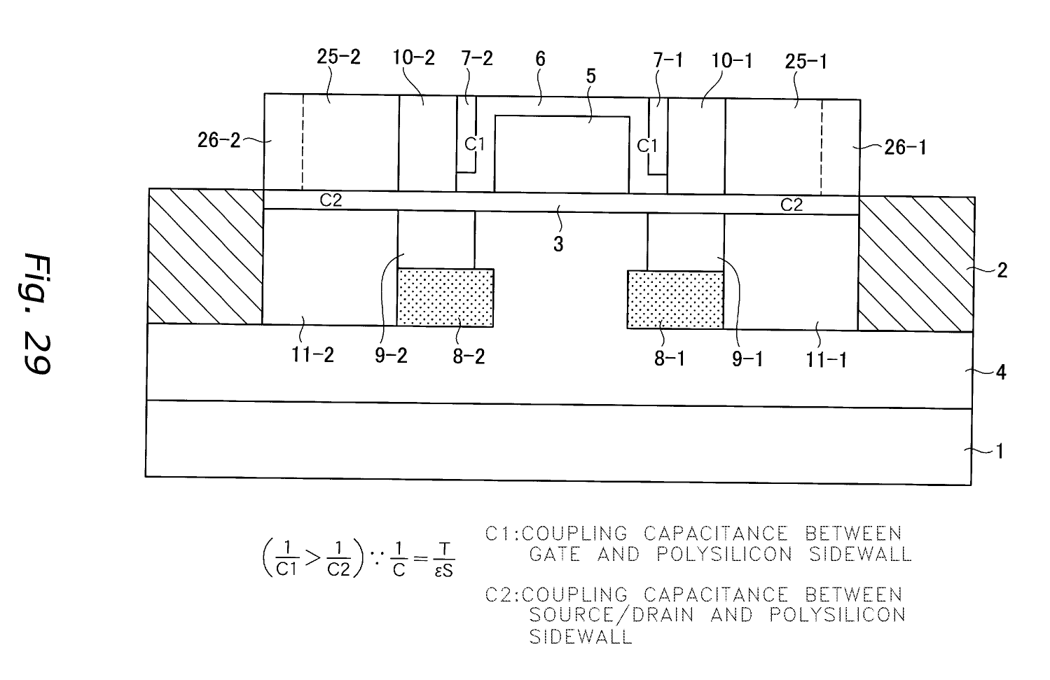

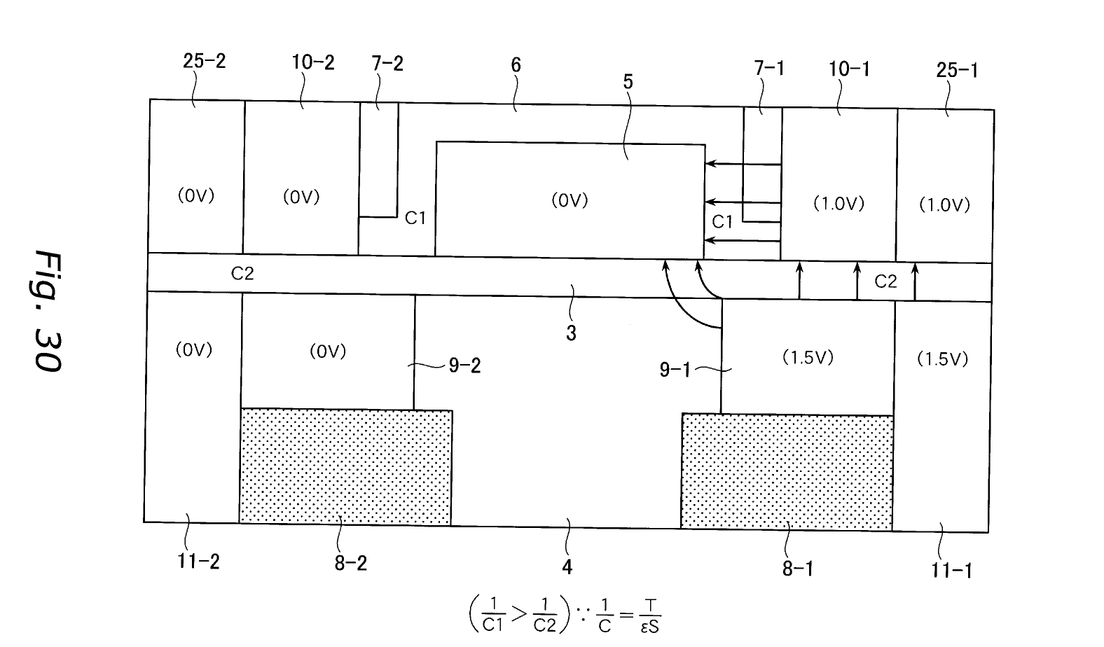

The fourth embodiment of the present invention provides a field effect transistor (hereinafter referred to as FET). FIG. 29 is a partial vertical cross-sectional view of a transistor configuration in accordance with the fourth embodiment of the present invention. FIG. 30 is a partial vertical cross-sectional view showing the electric field in the vicinity of the gate of the transistor shown in FIG. 29. The main difference between the fourth embodiment and the above described first embodiment is in that a conductive sidewall structure included in a sidewall structure is electrically isolated from a gate, a drain, and a source, and has a potential that follows the drain potential and the source potential more strongly than the gate potential.

Differences between the first and fourth embodiments are hereinafter explained in detail. In the following explanation, components/members of the FET in accordance with the fourth embodiment, which correspond to those of the FET in accordance with the first embodiment, are given the same numerals used in the first embodiment, and explanations of these components/members are hereinafter omitted.

Configuration

Structures of the drain region, the source region, and the gate structure in accordance with the fourth embodiment of the present invention are the same as those in accordance with the above described first embodiment.

The above described first sidewall structure is disposed on the gate insulation film 3. In this case, the gate insulation film 3 is configured to be disposed immediately below the gate 5 and extends horizontally outward therefrom. In addition, instead of this configuration, the gate insulation film 3 may be disposed only immediately below the gate 5, and an insulator comprised of a material that is different from that comprising the gate insulation film 3 may be disposed immediately below the first sidewall structure. This insulator, which is comprised of a different material from that comprising the gate insulation film 3, may be disposed under the vicinity region of a first sidewall of the gate 5 so that a portion of the insulator overlaps with the gate 5. In other words, the first sidewall structure is only required to be disposed on a first insulating layer structure. Here, the first insulating layer structure may be comprised of a portion of the gate insulation film 3 that extends horizontally outward from the gate 5. In addition, instead of this, it may be comprised of an insulator comprised of a material that is different from that comprising the gate insulation film 3. Furthermore, it may be comprised of a combination of these. If the first insulating layer structure is comprised of the combination of these, it may be comprised of a multi-layer structure. In addition, it may be configured by extending the insulation film 3 to the vicinity region of the gate 5 and disposing an insulator comprised of a material that is different from that comprising the gate insulation film 3 on a region remote from the gate 5. A typical example of a FET configuration is hereinafter explained in detail. Here, the FET has a configuration in which the gate insulation film 3 is configured to be disposed immediately below the gate 5 and extends horizontally outward therefrom and the above described first sidewall structure is disposed on the gate insulation film 3. However, as described above, it is not necessary to limit the FET configuration to the following configuration.

The first sidewall structure can comprise a first insulating sidewall structure that contacts the first sidewall of the gate structure and a first conductive sidewall structure that is separated from and electrically isolated from the gate structure through the first insulating sidewall structure and is also separated from and electrically isolated from the first extension 9-1 and the drain 11-1 through the gate insulation film 3. In other words, the first conductive sidewall structure is electrically isolated from the gate structure and the drain region, and electrically floated.

The first insulating sidewall structure provides a first capacitance C1 between the gate 5 and the first conductive sidewall structure. The gate insulation film 3 provides a second capacitance C2 between the first conductive sidewall structure, and a first extension 9-1 and the drain 11-1. Here, the inverse of the first capacitance C1 is larger than that of the second capacitance C2. Based on these relationships, the electric potential of the first conductive sidewall structure is different from that of the gate structure and also different from that of the drain region. However, it follows the potential of the drain region more strongly than that of the gate structure. The inverse of the capacitance C is derived by dividing the thickness of a dielectric (T) by the product of the permittivity of a dielectric (ε) and the area of a dielectric (S). In other words, the following relationship is established: 1/C=T/(εS) Therefore, it is generally possible to configure the thickness of the first insulating sidewall structure, that is, the distance between the gate structure and the first conductive sidewall structure, to be larger than that of the gate insulating film 3. Whatever the case, if the above described relationship is satisfied, that is, if the inverse of the first capacitance C1 is larger than that of the second capacitance C2, the potential of the first conductive sidewall structure will be different from that of the gate structure, and at the same time as this, will be different from the potential of the drain region, and furthermore, it will follow the potential of the drain region more strongly than that of the gate structure.

Furthermore, the first conductive sidewall structure can comprise a first gate sidewall conductive film 10-1 and a seventh gate sidewall conductive film 25-1. The first gate sidewall conductive film 10-1 is disposed on the gate insulation film 3 and contacts the first insulating sidewall structure. In addition, it is separated from and electrically isolated from the gate structure through the first insulating sidewall structure. The seventh gate sidewall conductive film 25-1 is disposed on the gate insulation film 3 and contacts the first gate sidewall conductive film 10-1. In addition, it is separated from the first insulating sidewall structure through the first gate sidewall conductive film 10-1. Also, it has electrical conduction with the first gate sidewall conductive film 10-1. Furthermore, it is separated from and electrically isolated from the first extension 9-1 and the drain 11-1, both of which comprise the above described drain region, through the gate insulation film 3.

The first insulating sidewall structure can comprise a gate sidewall insulation film 6 and a third gate sidewall insulation film 7-1. The gate sidewall insulation film 6 is disposed on the gate insulation film 3 and contacts the upper surface and the first and second sidewalls of the gate structure. Furthermore, the gate sidewall insulation film 6 comprises an outer bottom portion that contacts an inner bottom portion of the first gate sidewall conductive film 10-1. The third gate sidewall insulation film 7-1 is separated from the gate structure through the gate sidewall insulation film 6 and contacts the inner lateral side portion of the first gate sidewall conductive film 10-1. A combination of the gate sidewall insulation film 6 and the third gate sidewall insulation film 7-1 separates and electrically isolates the first conductive sidewall structure from the gate structure.

The second sidewall structure can comprise a second insulating sidewall structure that contacts the second sidewall of the gate structure, and a second conductive sidewall structure that is separated from and electrically isolated from the gate structure through the second insulating sidewall structure and is also separated from and electrically isolated from the second extension 9-2 and the source 11-2 through the gate insulation film 3. In other words, the second conductive sidewall structure is electrically isolated from the gate structure and the source region, and electrically floated.

The second insulating sidewall structure provides a first capacitance C1 between the gate 5 and the second conductive sidewall structure. The gate insulation film 3 provides a second capacitance C2 between the second conductive sidewall structure, and a second extension 9-1 and the source 11-2. Here, inverse of the first capacitance C1 is larger than that of the second capacitance C2. Based on these relationships, the electric potential of the second conductive sidewall structure is different from that of the gate structure and also different from that of the drain region. However, it follows the potential of the drain region more strongly than that of the gate structure. The inverse of the capacitance C is derived by dividing the thickness of a dielectric (T) by the product of the permittivity of a dielectric (ε) and the area of a dielectric (S). In other words, the following relationship is established: 1/C=T/(εS) Therefore, it is generally possible to configure the thickness of the second insulating sidewall structure, that is, the distance between the gate structure and the second conductive sidewall structure, to be larger than that of the gate insulating film 3. Whatever the case, if the above described relationship is satisfied, that is, if the inverse of the first capacitance C1 is larger than that of the second capacitance C2, the potential of the second conductive sidewall structure will be different from that of the gate structure, and at the same time as this, will be different from the potential of the source region, and furthermore, it follows the potential of the source region more strongly than that of the gate structure.

Furthermore, the second conductive sidewall structure can comprise a second gate sidewall conductive film 10-2 and an eighth gate sidewall conductive film 25-2. The second gate sidewall conductive film 10-2 is disposed on the gate insulation film 3 and contacts the second insulating sidewall structure. In addition, it is separated from and electrically isolated from the gate structure through the second insulating sidewall structure. The eighth gate sidewall conductive film 25-2 is disposed on the gate insulation film 3 and contacts the second gate sidewall conductive film 10-2. In addition, it is separated from the second insulating sidewall structure through the second gate sidewall conductive film 10-2. Also, it has electrical conduction with the second gate sidewall conductive film 10-2. Furthermore, it is separated from and electrically isolated from the second extension 9-2 and the source 11-2, both of which comprise the above described source region, through the gate insulation film 3.

The second insulating sidewall structure can comprise a gate sidewall insulation film 6 and a fourth gate sidewall insulation film 7-2. The gate sidewall insulation film 6 is disposed on the gate insulation film 3 and contacts the upper surface and the first and second sidewalls of the gate structure. Furthermore, the gate sidewall insulation film 6 comprises an outer bottom portion that contacts an inner bottom portion of the second gate sidewall conductive film 10-2. The fourth gate sidewall insulation film 7-2 is separated from the gate structure through the gate sidewall insulation film 6 and contacts the inner lateral side portion of the second gate sidewall conductive film 10-2. A combination of the gate sidewall insulation film 6 and the fourth gate sidewall insulation film 7-2 separates and electrically isolates the second conductive sidewall structure from the gate structure.

FIG. 30 is a partial vertical cross-sectional view showing the electric field in the vicinity of the gate of the transistor shown in FIG. 29. Here, the electric field in the vicinity of the gate is based on a case in which potentials of the source, the gate, and the drain are set to be 0 V, 0 V, and 1.5 V, respectively. As shown in FIG. 30 and as described in the third embodiment of the present invention, the electric field that runs from the first conductive sidewall structure to the first sidewall of the gate structure through the first insulating sidewall structure is produced, and accordingly concentration of the electric field that runs from the first extension 9-1 to the gate 5 through the gate insulation film 3 is reduced. In other words, concentration of the electric field between the gate and the drain is reduced by existence of the first sidewall structure that includes the first conductive sidewall structure.

As described in the aforementioned embodiments, the first sidewall structure that includes the first conductive sidewall structure whose electric potential is similar to the drain potential compared to the gate potential makes it possible to inhibit the band-to-band tunneling current without reducing the driving force of the transistor.

A method for realizing the above described structure is hereinafter explained.

The film structure of the first insulating sidewall structure is not limited to a specific structure. It may be any structure as long as it is configured so that the first conductive sidewall structure is separated and electrically isolated from the gate structure. The first insulating sidewall structure can be comprised of a single-layer structure, but it can be comprised of a multi-layer structure as described above. For example, the first insulating sidewall structure can comprise a gate sidewall insulation film 6 and a third gate sidewall insulation film 7-1. A combination of the gate sidewall insulation film 6 and the third gate sidewall insulation film 7-1 functions as an offset spacer.

The material comprising the first insulating sidewall structure is not particularly limited to a specific material as long as it is comprised of an insulator. However, it can be typically comprised of silicon nitride. The thickness of the first insulating sidewall structure, that is, the dimension thereof in the gate length direction is not particularly limited to a specific dimension as long as the first insulating sidewall structure can separate and electrically isolate the first conductive sidewall structure from the gate structure. However, it may be typically set to be 20 nm. In addition, the width of the first insulating sidewall structure, that is, the dimension thereof in the gate width direction can be set to be the same as the dimension of the gate width of the above described gate structure.

The first conductive sidewall structure can be comprised of a single-layer structure, but it can be comprised of a multi-layer structure as described above. For example, the first conductive sidewall structure can be comprised of the first gate sidewall conductive film 10-1 and the seventh gate sidewall conductive film 25-1 that contacts the first gate sidewall conductive film 10-1. The first gate sidewall conductive film 10-1 can be comprised of a conductive material, and the material thereof is not particularly limited to a specific material. However, it can be typically comprised of a polysilicon film into which impurities are implanted. The concentration of the impurities is not particularly limited to a specific concentration. However, it may be typically set to be 2E20 [atoms/cm³]. The thickness of the first gate sidewall conductive film 10-1, that is, the dimension thereof in the gate length direction is not particularly limited to a specific length. However, it may be typically set to be 50 nm. The width of the first gate sidewall conductive film 10-1, that is, the dimension thereof in the gate width direction is preferably set to be the same as the gate width of the above described gate structure. The seventh gate sidewall conductive film 25-1 can be comprised of a conductive material, and the material thereof is not particularly limited to a specific material. However, it can be typically comprised of a polysilicon film into which impurities are implanted. The concentration of the impurities is not particularly limited to a specific concentration. However, it may be typically set to be 2E20 [atoms/cm³], which is the same as the concentration of the impurities implanted into the above described first gate sidewall conductive film 10-1. The thickness of the seventh gate sidewall conductive film 25-1, that is, the dimension thereof in the gate length direction is not particularly limited to a specific length. However, it may be typically set to be the same as the dimension of the drain 11-1. The width of the seventh gate sidewall conductive film 25-1, that is, the dimension thereof in the gate width direction is preferably set to be the same as the gate width of the above described gate structure. In this case, a first contact hole 26-1 for forming a contact of the drain 11-1 is formed through the first gate sidewall conductive film 25-1 and the gate insulation film 3, respectively. If the dimension of the seventh gate sidewall conductive film 25-1 in the gate length direction is formed to be smaller than that of the drain 11-1, the drain contact may be formed further outside from the seventh gate sidewall conductive film 25-1. In this case, a first contact hole 26-1 may be formed in the gate insulation film 3. The vertical level of the upper surface of the seventh gate sidewall conductive film 25-1 is substantially the same as the vertical levels of the upper surfaces of the first gate sidewall conductive films 10-1 and 10-2, the gate sidewall insulation film 6, and the third and fourth gate sidewall insulation films 7-1 and 7-2. At this time, the seventh gate sidewall conductive film 25-1 is comprised of polysilicon into which impurities have not been implanted yet. Therefore, impurities whose conductive type is the same as that of impurities implanted into the first and second gate sidewall conductive films 10-1 and 10-2 can be implanted into the seventh and eighth gate sidewall conductive films 25-1 and 25-2 in approximately the same impurity concentration.

The electric potential of the first conductive sidewall structure is only required to follow the drain potential not the gate potential. However, the electric potential of the first conductive sidewall structure is not necessarily the same as the drain potential. Accordingly, the first conductive sidewall structure can be configured to have an electric potential that is similar to the drain potential compared to the gate potential. Because of this, the first insulating sidewall structure and the gate insulation film 3 is configured so that the above described relationship is satisfied, that is, so that the inverse of the first capacitance C1 is larger than that of the second capacitance C2.

The second sidewall structure in accordance with the present embodiment of the present invention has the same structure as the structure of the above described first sidewall structure. Therefore, the portions of explanation of the second sidewall structure that overlaps with that of the first sidewall structure is hereinafter omitted. However, the second sidewall structure can be configured to be different from the first sidewall structure. As described above, it is important for the transistor in accordance with the present invention to reduce the concentration of the electric field between the gate and the drain. Therefore, the first sidewall structure that is disposed on the drain side is only required to include the first insulating sidewall structure. In addition, the electric potential of the first conductive sidewall structure is only required to follow the drain potential compared to the gate potential by configuring the first conductive sidewall structure to be electrically isolated from the gate and the drain, and configuring the inverse of the first capacitance C1 to be larger than that of the second capacitance C2. Therefore, if there is no demand for this with regard to the second sidewall structure that is disposed on the source side, the second sidewall structure is not necessarily configured to have the same structure as the above described first conductive sidewall structure. For example, the second sidewall structure can be comprised of a heretofore known sidewall structure. In addition, the second sidewall structure can be configured to have a similar structure to the above described first sidewall structure, that is, a structure in which the layer structure thereof is the same as that of the first sidewall structure but the thickness of each layer therein and material comprising each layer therein are different from those in the first sidewall structure. However, if the second sidewall structure has the same structure as the first sidewall structure, it will be easy to reduce the number of steps required for the manufacturing process of the transistor.

Manufacturing Method

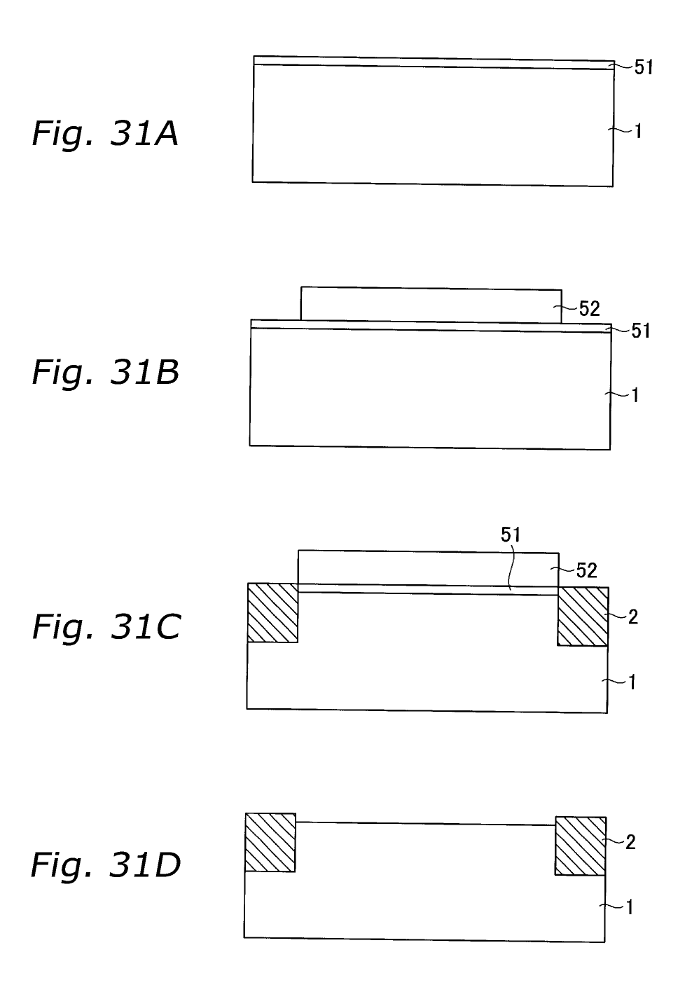

FIGS. 31A to 31D, 32A to 32D, 33A to 33D, 34A to 34D, and 35A to 35C are partial vertical cross-sectional views showing steps of a manufacturing process of a transistor in accordance with the fourth embodiment of the present invention. In reference to these figures, a manufacturing method of the transistor shown in FIGS. 29 and 30 is hereinafter explained in detail.

As shown in FIG. 31A, the surface of a silicon substrate 1 is oxidized, and a pad oxide film 51 with a thickness of 10 nm is formed on the surface of the silicon substrate 1.

As shown in FIG. 31B, a nitride film is deposited on the pad oxide film 51 with a heretofore known deposition method, and then the nitride film is patterned with a heretofore known method. Thus, a nitride film pattern 52 is selectively formed on the pad oxide film 51.

As shown in FIG. 31C, heretofore known local oxidation of silicon (LOCOS) is performed with use of the nitride film pattern 52 as a mask. Thus, a field oxide film 2 is selectively formed on the surface of the silicon substrate 1.

As shown in FIG. 31D, the nitride film pattern 52 and the pad oxide film 51 are removed by heretofore known dry etching. Thus, the surface of the silicon substrate 1 that is not covered with the field oxide film 2 is exposed.

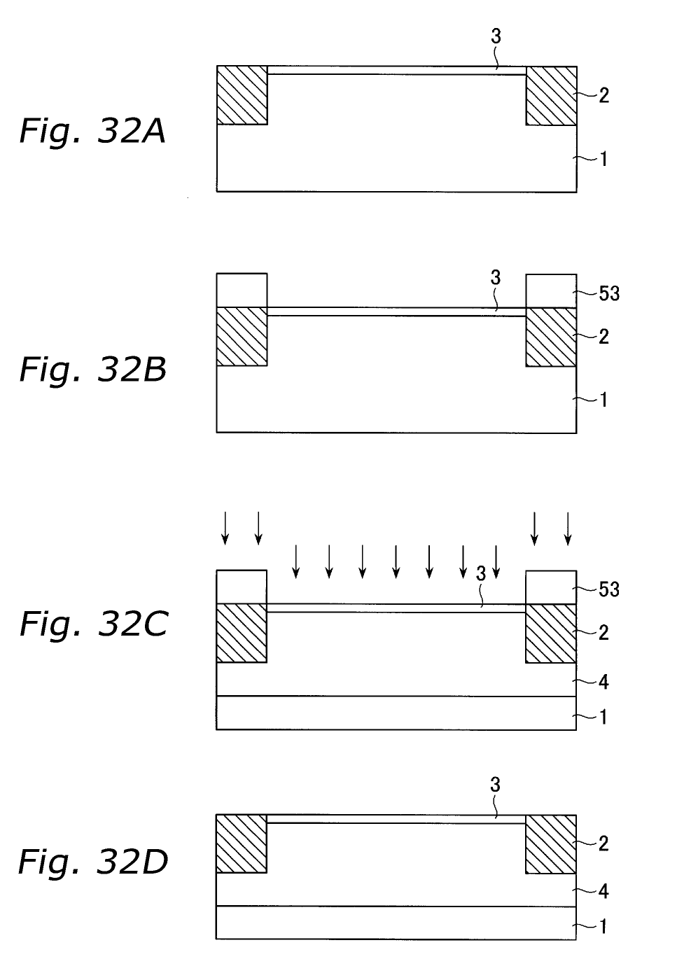

As shown in FIG. 32A, the exposed surface of the silicon substrate 1 is thermally oxidized. Thus, a gate oxide film 3 with a thickness of 2 nm is formed on the exposed surface.

As shown in FIG. 32B, a resist pattern 53 that covers the field oxide film 2 and includes a window immediately above the gate oxide film 3 is formed with a heretofore known lithography technique.

As shown in FIG. 32C, ion implantation is selectively performed with use of the resist pattern 53 as a mask. Thus, a p-well 4 is selectively formed in an upper region of the silicon substrate 1. The ion implantation can be performed in the vertical direction with respect to the substrate surface with use of boron difluoride (BF₂) as the p-type ion species under conditions in which the acceleration energy is 80 keV and the dose amount is 5E12 [atoms/cm²]. The ion species BF₂ is implanted into the upper region of the silicon substrate 1 through the gate oxide film 3. In this case, the depth of the p-well 4 is formed to be 200 nm.

As shown in FIG. 32D, the resist pattern 53 is removed with a heretofore known method.

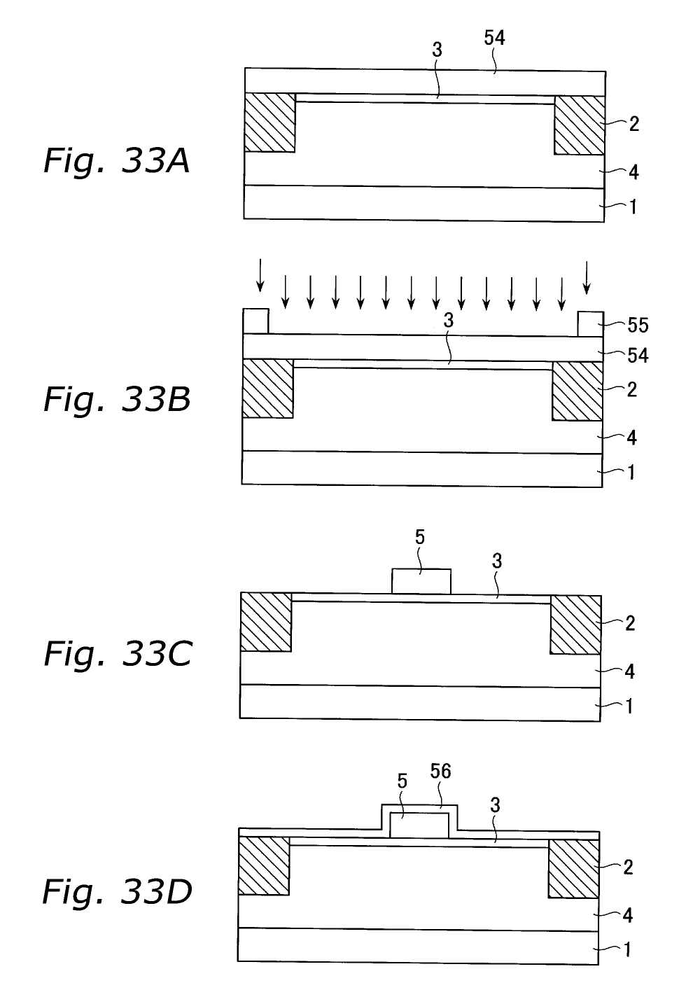

As shown in FIG. 33A, a polysilicon film 54 with a thickness of 1500 Å is deposited to overlie the gate oxide film 3 and the field oxide film 2 with a heretofore known thermal chemical vapor deposition (thermal CVD) method.

As shown in FIG. 33B, a resist pattern 55 that covers the polysilicon film 54 and includes a window above the gate oxide film 3 is formed with a heretofore known lithography technique. Phosphorus (P) is selectively implanted as the n-type ion species with use of the resist pattern 55 as a mask. The ion implantation can be performed in the vertical direction with respect to the substrate surface under conditions in which the acceleration energy is 15 keV and the dose amount is 2E15 [atoms/cm²]. As a result, the n-type impurities are implanted in the polysilicon film 54 that is disposed on the gate oxide film 3.

As described in FIG. 33C, the resist pattern 55 is removed, and then a new resist pattern is formed to overlie the polysilicon film 54 with a lithography technique. Then, the polysilicon film 54 is patterned with use of the new resist pattern as a mask. Thus, a gate 5 comprised of polysilicon into which impurities are implanted is selectively formed on the gate oxide film 3. Patterning of the polysilicon film 54 can be performed with dry etching. The gate length and the gate width are set as described above. Specifically, the gate length is not particularly limited to a specific length. However, it may be typically set to be 100 nm. In addition, the gate width is not particularly limited to a specific width.

As shown in FIG. 33D, an oxide film 56 with a thickness of 70 nm is formed to cover the upper surface and the sidewalls of the gate 5, the upper surface of the gate insulation film 3, and the upper surface of the field oxide film 2 with a heretofore known thermal CVD method.

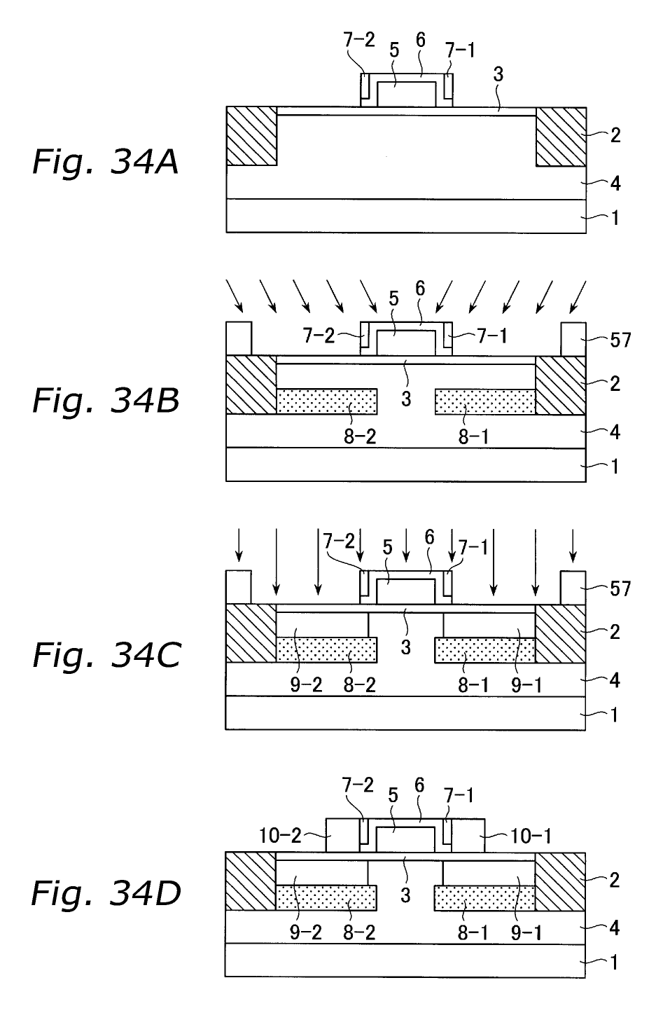

As shown in FIG. 34A, a nitride film with a thickness of 10 nm is deposited to overlie the oxide film 56 with a heretofore known thermal CVD method. Then, dry etching is performed with respect to the nitride film and the oxide film 56, and the portions thereof that are disposed on the upper surface and the sidewalls of the gate 5 are left unetched. Thus, a gate sidewall insulation film 6 that is disposed on the upper surface and the sidewalls of the gate 5, a third gate sidewall insulation films 7-1 that is disposed only on one of the sidewalls of the gate 5, and a fourth gate sidewall insulation film 7-2 that is disposed only on the other of the sidewalls of the gate 5, are selectively formed. Here, a combination of the gate sidewall insulation film 6, and the third and fourth gate sidewall insulation films 7-1 and 7-2, all of which are disposed on the sidewalls of the gate 5, function as a sidewall spacer.

As shown in FIG. 34B, a resist pattern 57 is selectively formed on the field oxide film 2 with a heretofore known lithography technique. Here, the distance between the lateral edge of the resist pattern 57 and the sidewall spacer is set to be 0.5 μm. Then, boron difluoride (BF₂) is selectively implanted into the p-well 4 as the p-type ion species in an oblique direction with respect to the substrate surface with use of the resist pattern 57, the gate 5, the gate sidewall insulation film 6, and the third and the fourth gate sidewall insulation films 7-1 and 7-2 as masks. Specifically, the ion implantation can be performed in an oblique direction at an angle of 30 degrees with respect to the substrate surface under conditions in which the acceleration energy is 80 keV and the dose amount is 2E13 [atoms/cm²], while the silicon substrate 1 is rotated. As a result, first and second pocket regions 8-1 and 8-2 with a depth of 200 nm and an impurity concentration of 1E18 [atoms/cm³] are selectively formed in the p-well 4. In this phase, thermal treatment is not performed in order to activate the impurities ion-implanted therein. The first and second pocket regions 8-1 and 8-2 are disposed in a deep region that is vertically remote from the gate insulation film 3 and extend inward from the inner lateral side of the field oxide film 2. The inner lateral edges of the first and second pocket regions 8-1 and 8-2 are disposed further inside than the third and fourth gate sidewall insulation films 7-1 and 7-2, respectively, because they are formed by the ion-implantation in the oblique direction.

As shown in FIG. 34C, arsenic (As) is selectively implanted into the p-well 4 as the n-type ion species in the vertical direction with respect to the substrate surface with the reuse of the above described resist pattern 57, the gate 5, the gate sidewall insulation film 6, and the third and the fourth gate sidewall insulation films 7-1 and 7-2 as masks. Specifically, the ion implantation can be performed in the vertical direction with respect to the substrate surface under conditions in which the acceleration energy is 5 keV and the dose amount is 1E15 [atoms/cm²]. As a result, first and second extensions 9-1 and 9-2 with a depth of 50 nm and an impurity concentration of 2E20 [atoms/cm³] are selectively formed in the p-well 4. The first and second extensions 9-1 and 9-2 are disposed immediately above the first and second pocket regions 8-1 and 8-2, respectively. In addition, they are disposed immediately below the gate oxide film 3. The first and second extensions 9-1 and 9-2 are formed by the ion implantation in the vertical direction. Therefore, the inner edges of the first and second extensions 9-1 and 9-2 are approximately self-aligned with the gate 5. Specifically, the inner edges of the first and second extensions 9-1 and 9-2 are aligned with the gate 5 within an error of plus or minus 10 nm. In other words, the inner lateral edges of the first and second extensions 9-1 and 9-2 are aligned with the gate 5, overlaps with the gate 5 within 10 nm, or are offset from the gate 5 within 10 nm. In this phase, thermal treatment is not performed in order to activate the impurities ion-implanted therein. Then, the resist pattern 57 is removed with a heretofore known method.

As shown in FIG. 34D, a polysilicon film with a thickness of 50 nm is deposited to overlie the field oxide film 2, the gate insulation film 3, the gate sidewall insulation film 6, and the third and fourth gate sidewall insulation films 7-1 and 7-2 with a heretofore known thermal CVD method. Then, the polysilicon film is selectively removed by dry etching, and portions thereof that are disposed on both sides of the sidewalls of the gate 5 and contact the gate sidewall insulation film 6 and the third and fourth gate sidewall insulation films 7-1 and 7-2 are left unetched. Thus, first and second gate sidewall conductive films 10-1 and 10-2 are formed. The first and second gate sidewall conductive films 10-1 and 10-2 are disposed immediately above the gate oxide film 3 and in the vicinity of the sidewalls of the gate 5, and contact the gate sidewall insulation film 6 and the third and fourth gate sidewall insulation films 7-1 and 7-2. The dimensions of the first and second gate sidewall conductive films 10-1 and 10-2 in the gate length direction are 50 nm. The vertical levels of the upper surfaces of the first and second gate sidewall conductive films 10-1 and 10-2 are substantially the same as those of the gate sidewall insulation film 6 and the third and fourth gate sidewall insulation films 7-1 and 7-2. At this time, the first and second gate sidewall conductive films 10-1 and 10-2 are comprised of polysilicon into which impurities have not been implanted yet.

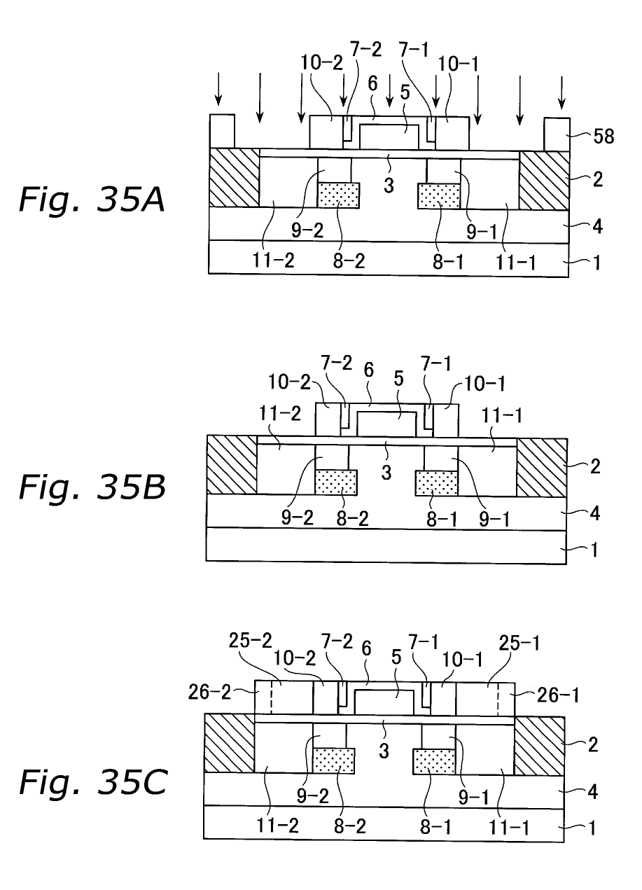

As shown in FIG. 35A, a resist pattern 58 is selectively formed on the field oxide film 2 with a heretofore known lithography technique. Then, phosphorus (P) is selectively implanted into the gate 5, the first and second gate sidewall conductive films 10-1 and 10-2, the first and second extensions 9-1 and 9-2, and the first and second pocket regions 8-1 and 8-2 as the n-type ion species with use of the resist pattern 58, the gate 5, the gate sidewall insulation film 6, the third and fourth gate sidewall insulation films 7-1 and 7-2, and the first and second gate sidewall conductive films 10-1 and 10-2 as masks. Specifically, the ion implantation can be performed in the vertical direction with respect to the substrate surface under conditions in which the acceleration energy is 20 keV and the dose amount is 5E15 [atoms/cm²]. As a result, the gate 5 comprised of polysilicon into which the impurities are implanted, and the first and second gate sidewall conductive films 10-1 and 10-2 comprised of polysilicon into which the impurities are implanted, are formed, and a drain 11-1 and a source 11-2 are selectively formed in the p-well 4.

The n-type impurities do not reach the bottom of the first and second gate sidewall conductive films 10-1 and 10-2. Therefore, portions of the gate oxide film 3 that are disposed immediately below the first and second gate sidewall conductive films 10-1 and 10-2 are not damaged by the ion implantation. In addition, the n-type impurities do not reach the bottom of the gate 5. Therefore, a portion of the gate oxide film 3 that is disposed immediately below the gate 5 is not damaged by the ion implantation.

The outer lateral edges of the drain 11-1 and the source 11-2 are delimited by the field oxide film 2. The inner lateral edge of the drain 11-1 contacts the outer lateral edges of the first extension 9-1 and the first pocket region 8-1. The inner lateral edge of the drain 11-2 contacts the outer lateral edges of the second extension 9-2 and the second pocket region 8-2. As described above, the impurity concentrations of the drain 11-1 and the source 11-2 are higher than those of the first and second extensions 9-1 and 9-2, respectively. In addition, the drain 11-1 and the source 11-2 are formed by selectively implanting the n-type impurities into the horizontally outer regions of the first pocket region 8-1 into which the p-type impurities are implanted and the first extension 9-1 into which the n-type impurities are implanted, and the horizontally outer regions of the second pocket region 8-2 into which the p-type impurities are implanted and the second extension 9-2 into which the n-type impurities are implanted. Therefore, the concentrations of the upper regions in the drain 11-1 and the source 11-2 will be higher and those of the lower regions therein will be lower.

Then, a thermal treatment is performed in order to activate the implanted ions in the above described ion implantation process, that is, the p-type impurities that are implanted into the first and second pocket regions 8-1 and 8-2, and the n-type impurities that are implanted into the gate 5, the first and second extensions 9-1 and 9-2, the first and second gate sidewall conductive films 10-1 and 10-2, the drain 11-1, and the source 11-2. The thermal treatment can be performed with rapid thermal anneal (RTA). Specifically, RTA is performed at 1000 degrees Celsius for 10 seconds.

As shown in FIG. 35B, after the ion implantation, the resist pattern 58 is removed with a heretofore known method.

As shown in FIG. 35C, a polysilicon film is deposited to overlie the field oxide film 2, the gate insulation film 3, the gate sidewall insulation film 6, the third and fourth gate sidewall insulation films 7-1 and 7-2, and the first and second gate sidewall conductive films 10-1 and 10-2 with a heretofore known thermal CVD method. Then, the polysilicon film is selectively removed by dry etching, and portions thereof that contacts the outer sidewalls of the first and second gate sidewall conductive films 10-1 and 10-2 and are disposed above the drain 11-1 and the source 11-2 and immediately above the gate oxide film 3 are only left unetched. Thus, seventh and eighth gate sidewall conductive films 25-1 and 25-2 are formed. Here, the above dry etching is performed so that a first contact holes 26-1 is formed in the seventh gate sidewall conductive film 25-1 and the gate insulation film 3, and a second contact hole 26-2 is formed in the eighth gate sidewall conductive film 25-2 and the gate insulation film 3. The seventh gate sidewall conductive film 25-1 is formed to be disposed immediately above the gate oxide film 3 and above the drain 11-1 and contacts the outer sidewall of the first gate sidewall conductive film 10-1. On the other hand, the eighth gate sidewall conductive film 25-2 is formed to be disposed immediately above the gate oxide film 3 and above the source 11-2 and contacts the outer sidewall of the second gate sidewall conductive film 10-2. The dimensions of the seventh and eighth gate sidewall conductive films 25-1 and 25-2 in the gate length direction are substantially the same as those of the drain 11-1 and the source 11-2. In this case, the first contact hole 26-1 for forming a contact of the drain 11-1 is formed through the seventh gate sidewall conductive film 25-1 and the gate insulation film 3, respectively. On the other hand, the second contact hole 26-2 for forming a contact of the source 11-2 is formed through the eighth gate sidewall conductive film 25-2 and the gate insulation film 3, respectively. If the dimensions of the seventh and eighth gate sidewall conductive films 25-1 and 25-2 in the gate length direction are formed to be smaller than those of the drain 11-1 and the source 11-2, the drain contact and the source contact may be formed further outside from the seventh gate sidewall conductive film 25-1 and the eighth gate sidewall conductive film 25-2, respectively. In this case, the first and second contact holes 26-1 and 26-2 may be formed in the gate insulation film 3. The vertical levels of the upper surfaces of the seventh and eighth gate sidewall conductive films 25-1 and 25-2 are approximately the same as those of the first and second gate sidewall conductive films 10-1 and 10-2, the gate sidewall insulation film 6, and the third and fourth gate sidewall insulation films 7-1 and 7-2. At this time, the seventh and eighth gate sidewall conductive films 25-1 and 25-2 are comprised of polysilicon into which impurities have not been implanted yet. Therefore, impurities whose conductive type is the same as that of impurities implanted into the first and second gate sidewall conductive films 10-1 and 10-2 can be implanted into the seventh and eighth gate sidewall conductive films 25-1 and 25-2 in approximately the same impurity concentration.

The FET shown in FIG. 29 can be produced through the above described series of steps of the manufacturing process.

### General Interpretation of Terms

In understanding the scope of the present invention, the term “configured” as used herein to describe a component, section or part of a device includes hardware and/or software that is constructed and/or programmed to carry out the desired function. In understanding the scope of the present invention, the term “comprising” and its derivatives, as used herein, are intended to be open ended terms that specify the presence of the stated features, elements, components, groups, integers, and/or steps, but do not exclude the presence of other unstated features, elements, components, groups, integers and/or steps. The foregoing also applied to words having similar meanings such as the terms, “including,” “having,” and their derivatives. Also, the term “part,” “section,” “portion,” “member,” or “element” when used in the singular can have the dual meaning of a single part or a plurality of parts. Finally, terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

What is claimed is:

1. A semiconductor device, comprising:
a source region;
a drain region;
a gate comprising a first sidewall;
a first insulating sidewall structure configured to contact the first sidewall of the gate; and
a first conductive sidewall structure configured to be electrically isolated from the gate through the first insulating sidewall structure and electrically coupled to a first region that is one of the source region or the drain region.

2. The semiconductor device according to claim 1, wherein the first conductive sidewall structure is configured to contact the first insulating sidewall structure and contact the first region.

3. The semiconductor device according to claim 1, wherein the first conductive sidewall structure comprises:
a first polysilicon region configured to contact the first insulating sidewall structure; and
a first metal silicide region configured to contact the first polysilicon region and the first region.

4. The semiconductor device according to claim 1, wherein the first conductive sidewall structure is configured to contact the first insulating sidewall structure and comprises a first polysilicon region that contacts the first region.

5. The semiconductor device according to claim 1, wherein the first region comprises:
a second metal silicide region configured to contact the first conductive sidewall structure; and
a first impurity diffusion region configured to contact the second metal silicide region and be separated from the first conductive sidewall structure.

6. The semiconductor device according to claim 1, wherein the first region is disposed below the first conductive sidewall structure and is comprised of a first impurity diffusion region configured to contact a bottom portion of the first conductive sidewall structure.

7. The semiconductor device according to claim 1, wherein the first conductive sidewall structure is configured to retain substantially the same electric potential as that of the first region.

8. The semiconductor device according to claim 1, further comprising a first insulating layer structure that is disposed below the first conductive sidewall structure.

9. A semiconductor device according to claim 1, further comprising:
a second insulating sidewall structure that is configured to contact a second sidewall of the gate that is positioned opposite from the first sidewall thereof, and
a second conductive sidewall structure that is configured to be electrically isolated from the gate through the second insulating sidewall structure and electrically coupled to a second region that is the other of the source region and the drain region.

10. A semiconductor device, comprising:
a source region;
a drain region;
a first insulating layer structure;
a gate comprising a first sidewall;
a first insulating sidewall structure configured to contact the first sidewall of the gate; and
a third insulating sidewall structure that is configured to contact a first region that is one of the source region or the drain region; and
a first conductive sidewall structure that is disposed above the first insulating layer structure and interposed between the first insulating sidewall structure and the third insulating sidewall structure, and configured to be electrically isolated from the gate through the first insulating sidewall structure, electrically isolated from the first region though the third insulating sidewall structure and the first insulating layer structure, and electrically floated.

11. The semiconductor device according to claim 10, wherein an electric potential of the first conductive sidewall structure follows that of the first region more strongly than that of the gate.

12. The semiconductor device according to claim 10,
wherein the first insulating sidewall structure comprises a first coupling capacitance between the gate and the first conductive sidewall structure;
the first insulating layer structure comprises a second coupling capacitance between the first region and the first conductive sidewall structure;
the third insulating sidewall structure comprises a third coupling capacitance between the first region and the first conductive sidewall structure; and
the inverse of the first coupling capacitance value is larger than that of the second coupling capacitance value, and also larger than that of the third coupling capacitance value.

13. The semiconductor device according to claim 10, wherein the first conductive sidewall structure is comprised of a first polysilicon region of the same conductive type as the conductive types of the source region and the drain region.

14. A semiconductor device according to claim 10, further comprising:
a second insulating layer structure;
a second insulating sidewall structure configured to contact a second sidewall of the gate that is positioned opposite from the first sidewall thereof, and
a fourth insulating sidewall structure configured to contact a second region that is the other of the source region and the drain region; and
a second conductive sidewall structure that is interposed between the second insulating sidewall structure and the fourth insulating sidewall structure, and configured to be electrically isolated from the gate through the second insulating sidewall structure, electrically isolated from the second region though the second insulating sidewall structure and the fourth insulating layer structure, and electrically floated.

15. The semiconductor device according to claim 14,
wherein the second insulating sidewall structure comprises a fourth coupling capacitance between the gate and the second conductive sidewall structure;
the second insulating layer structure comprises a fifth coupling capacitance between the second region and the second conductive sidewall structure;
the fourth insulating sidewall structure comprises a sixth coupling capacitance between the second region and the second conductive sidewall structure; and
the inverse of the fourth coupling capacitance value is larger than that of the fifth coupling capacitance value, and also larger than that of the sixth coupling capacitance value.

16. A semiconductor device, comprising:
a source region;
a drain region;
a first insulating layer structure;
a gate comprising a first sidewall;
a first insulating sidewall structure configured to contact the first sidewall of the gate; and
a first conductive sidewall structure that is configured to contact the first insulating sidewall structure and disposed above the first insulating layer structure, and configured to be electrically isolated from the gate through the first insulating sidewall structure, electrically isolated from a first region that is one of the source region or the drain region though the first insulating layer structure, and electrically floated.

17. The semiconductor device according to claim 16, wherein an electric potential of the first conductive sidewall structure follows that of the first region more strongly than that of the gate.

18. The semiconductor device according to claim 16,
wherein the first insulating sidewall structure comprises a first coupling capacitance between the gate and the first conductive sidewall structure;
the first insulating layer structure comprises a second coupling capacitance between the first region and the first conductive sidewall structure; and
the inverse of the first coupling capacitance value is larger than that of the second coupling capacitance value.

19. The semiconductor device according to claim 16, wherein the first conductive sidewall structure is comprised of a first polysilicon region of the same conductive type as the conductive types of the source region and the drain region.
